(19) United States
(12) Patent Application Publication
(10) Pub. No.: US 2025/0280528 A1
(43) Pub. Date: Sep. 4, 2025

(54) SEMICONDUCTOR DEVICE

(71) Applicant: Semiconductor Energy Laboratory Co., Ltd., Atsugi-shi (JP)

(72) Inventors: Motomu KURATA, Isehara (JP); Hiromi SAWAI, Atsugi (JP); Tsutomu MURAKAWA, Isehara (JP); Fumito ISAKA, Zama (JP); Yasuhiro JINBO, Isehara (JP)

(21) Appl. No.: 19/052,356

(22) Filed: Feb. 13, 2025

(30) Foreign Application Priority Data
Feb. 29, 2024 (JP) 2024-029904

(51) Int. Cl. H10B 12/00

(52) U.S. Cl. CPC H10B 12/34; H10B 12/33

(57) ABSTRACT

A semiconductor device that can be miniaturized or highly integrated is provided. In the semiconductor device, a first and second pillar capacitors over the same formation surface, a first interlayer film, a second interlayer film having an opening portion are stacked. Components of a first and second vertical transistors are partly provided in the opening portion. At least part of the opening portion overlaps with a region between the first capacitor and the second capacitor. An upper electrode of the first vertical transistor and an upper electrode of the second vertical transistor each include a cutout portion at a position overlapping with the opening portion. In a plan view, the outline of the cutout portion coincides or substantially coincides with part of the outline of the opening portion.

### BACKGROUND OF THE INVENTION

### 1. Field of the Invention

One embodiment of the present invention relates to a semiconductor device, a memory device, and an electronic device. One embodiment of the present invention also relates to a method for manufacturing a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, and an electronic device themselves are semiconductor devices and also include a semiconductor device.

### 2. Description of the Related Art

In recent years, semiconductor devices have been developed, and large scale integrations (LSIs), central processing unit (CPUs), memories (memory devices), and the like are mainly used in semiconductor devices. A CPU is an aggregation of semiconductor elements; the CPU includes an integrated circuit (including a transistor and a memory) formed into a chip by processing a semiconductor wafer, and is provided with an electrode that is a connection terminal.

An integrated circuit (IC) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. As semiconductor materials usable for the transistor, silicon-based semiconductor materials have been widely used, but oxide semiconductors have been attracting attention as alternative materials.

A transistor including an oxide semiconductor is known to have an extremely low leakage current in the off state. For example, Patent Document 1 discloses a low-power CPU utilizing a characteristic of a low leakage current of the transistor including an oxide semiconductor. For another example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1]M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

An object of one embodiment of the present invention is to provide a transistor, semiconductor device, or memory device which can be miniaturized or highly integrated. Another object of one embodiment of the present invention is to provide a highly reliable transistor, semiconductor device, or memory device. Another object of one embodiment of the present invention is to provide a low-cost semiconductor device or memory device. Another object of one embodiment of the present invention is to provide a semiconductor device or memory device with low power consumption. Another object of one embodiment of the present invention is to provide a semiconductor device or memory device which operates at high speed. Another object of one embodiment of the present invention is to provide a semiconductor device or memory device which includes a transistor with favorable electrical characteristics. Another object of one embodiment of the present invention is to provide a semiconductor device or memory device which includes a transistor with a high on-state current. Another object of one embodiment of the present invention is to provide a semiconductor device or memory device which includes a transistor with small parasitic capacitance. Another object of one embodiment of the present invention is to provide a method for manufacturing the above-described transistor, semiconductor device, or memory device.

Note that the description of these objects does not preclude the existence of other objects. One embodiment of the present invention does not necessarily achieve all of these objects. Other objects can be derived from the description of the specification, the drawings, and the claims.

One embodiment of the present invention is a semiconductor device including a capacitor, a transistor, a first insulating layer, and a second insulating layer. The capacitor includes a first electrode having a pillar shape, a dielectric covering a side surface and a top surface of the first electrode, and a second electrode being over the dielectric and covering the side surface and the top surface of the first electrode. The first insulating layer is positioned over the second electrode. The second insulating layer is positioned over the first insulating layer. The second insulating layer includes an opening portion. The transistor includes an oxide semiconductor layer. The oxide semiconductor layer includes a region along a sidewall of the opening portion. Part of an end portion of the oxide semiconductor layer is positioned in the opening portion. The oxide semiconductor layer includes a region overlapping with the second electrode. One of a source electrode and a drain electrode of the transistor is electrically connected to the second electrode.

In the above-described embodiment, the second insulating layer may be positioned over one of the source electrode and the drain electrode of the transistor, the other of the source electrode and the drain electrode of the transistor may be positioned over the second insulating layer, and the oxide semiconductor layer may include a region in contact with a top surface of the one of the source electrode and the drain electrode of the transistor and a region in contact with a top surface of the other of the source electrode and the drain electrode of the transistor.

Another embodiment of the present invention is a semiconductor device including a first capacitor, a second capacitor, a first transistor, a second transistor, a first insulating layer, and a second insulating layer. The first capacitor includes a first electrode having a pillar shape, a first dielectric covering a side surface and a top surface of the first electrode, and a second electrode being over the first dielectric and covering the side surface and the top surface of the first electrode. The second capacitor includes a third electrode having a pillar shape, a second dielectric covering a side surface and a top surface of the third electrode, and a fourth electrode being over the second dielectric and covering the side surface and the top surface of the third electrode. The first insulating layer is positioned over the second electrode and the fourth electrode. The second insulating layer is positioned over the first insulating layer. The second insulating layer includes a first opening portion at least partly overlapping with a region positioned between the first capacitor and the second capacitor. The first transistor includes a first oxide semiconductor layer. The second transistor includes a second oxide semiconductor layer. Each of the first oxide semiconductor layer and the second oxide semiconductor layer includes a region along a sidewall of the first opening portion. One of a source electrode and a drain electrode of the first transistor is electrically connected to the second electrode. One of a source electrode and a drain electrode of the second transistor is electrically connected to the fourth electrode.

In the above-described embodiment, the semiconductor device may further include a third insulating layer. The first dielectric and the second dielectric may be positioned over the third insulating layer, the third insulating layer may include a second opening portion, and the first electrode may include a region in contact with a side surface of the third insulating layer in the second opening portion and a region in contact with the first dielectric.

In the above-described embodiment, a height from a bottom surface of the second electrode to the top surface of the first electrode may be greater than or equal to a width of the first electrode.

In the above-described embodiment, the semiconductor device may further include a conductive layer. The first insulating layer may include a third opening portion reaching the second electrode, the conductive layer may be positioned in the third opening portion, and the one of the source electrode and the drain electrode of the first transistor may include a region in contact with a top surface of the conductive layer.

In the above-described embodiment, the second insulating layer may be positioned over the one of the source electrode and the drain electrode of the first transistor and the one of the source electrode and the drain electrode of the second transistor, and the other of the source electrode and the drain electrode of the first transistor and the other of the source electrode and the drain electrode of the second transistor may be positioned over the second insulating layer.

Another embodiment of the present invention is a semiconductor device including a first capacitor, a second capacitor, a first transistor, a second transistor, a first insulating layer, a second insulating layer, and a third insulating layer. The first capacitor includes a first conductive layer, a second conductive layer, and a fourth insulating layer. The second capacitor includes a third conductive layer, a fourth conductive layer, and a fifth insulating layer. The first transistor includes a first oxide semiconductor layer, a fifth conductive layer, a sixth conductive layer, a seventh conductive layer, and a sixth insulating layer. The second transistor includes a second oxide semiconductor layer, the sixth conductive layer, an eighth conductive layer, a ninth conductive layer, and the sixth insulating layer. Each of the first conductive layer and the third conductive layer has a pillar shape. The fourth insulating layer covers a side surface and a top surface of the first conductive layer. The fifth insulating layer covers a side surface and a top surface of the third conductive layer. The second conductive layer is over the fourth insulating layer and covers the side surface and the top surface of the first conductive layer. The fourth conductive layer is over the fifth insulating layer and covers the side surface and the top surface of the third conductive layer. The first insulating layer is positioned over the second conductive layer and the fourth conductive layer. The fifth conductive layer and the eighth conductive layer are positioned over the first insulating layer. The fifth conductive layer is electrically connected to the second conductive layer. The eighth conductive layer is electrically connected to the fourth conductive layer. The second insulating layer is positioned over the fifth conductive layer and the eighth conductive layer. The sixth conductive layer is positioned over the second insulating layer. The third insulating layer is positioned over the sixth conductive layer and the second insulating layer. The seventh conductive layer and the ninth conductive layer are over the third insulating layer. The third insulating layer, the sixth conductive layer, and the second insulating layer include a first opening portion. The first opening portion includes a portion overlapping with the fifth conductive layer, a portion overlapping with the eighth conductive layer, and a portion overlapping with the first insulating layer and positioned between the fifth conductive layer and the eighth conductive layer. The sixth insulating layer covers a sidewall of the first opening portion. The first oxide semiconductor layer includes a region facing the sixth conductive layer with the sixth insulating layer therebetween in the first opening portion and a region in contact with the fifth conductive layer in the first opening portion, and a region in contact with the seventh conductive layer outside the first opening portion. The second oxide semiconductor layer includes a region facing the sixth conductive layer with the sixth insulating layer therebetween in the first opening portion, a region in contact with the eighth conductive layer in the first opening portion, and a region in contact with the ninth conductive layer outside the first opening portion.

In the above-described embodiment, the semiconductor device may further include a seventh insulating layer. The fourth insulating layer and the fifth insulating layer may be positioned over the seventh insulating layer, the seventh insulating layer may include a second opening portion, and the first conductive layer may include a region in contact with a side surface of the seventh insulating layer in the second opening portion and a region in contact with the fourth insulating layer.

In the above-described embodiment, a height from a bottom surface of the second conductive layer to the top surface of the first conductive layer may be greater than or equal to a width of the first conductive layer.

In the above-described embodiment, the semiconductor device may further include a tenth conductive layer. The first insulating layer may include a third opening portion reaching the second conductive layer, the tenth conductive layer may be positioned in the third opening portion, and the fifth conductive layer may include a region in contact with a top surface of the tenth conductive layer.

In the above-described embodiment, the sixth insulating layer in the first opening portion may have an annular shape in a plan view, and each of the first oxide semiconductor layer and the second oxide semiconductor layer in the first opening portion may have an arc shape in a plan view.

In the above-described embodiment, the fifth conductive layer may include a depressed portion at a position overlapping with the first opening portion, the sixth insulating layer may be in contact with a sidewall of the depressed portion, and the first oxide semiconductor layer may be in contact with at least part of a bottom portion of the depressed portion.

In the above-described embodiment, the fifth conductive layer may include a first layer and a second layer over the first layer, and the second layer may include the depressed portion.

In the above-described embodiment, the sixth insulating layer may be in contact with part of a side surface on the first opening portion side of the seventh conductive layer, and the first oxide semiconductor layer may be in contact with another part of the side surface on the first opening portion side of the seventh conductive layer.

In the above-described embodiment, the sixth insulating layer may be in contact with part of a side surface on the first opening portion side of the fifth conductive layer, and the first oxide semiconductor layer may be in contact with another part of the side surface on the first opening portion side of the fifth conductive layer.

In the above-described embodiment, an end portion of the first oxide semiconductor layer outside the first opening portion may be closer to the first opening portion than an end portion of the seventh conductive layer on the opposite side to the first opening portion is in a plan view.

In the above-described embodiment, the semiconductor device may further include an eighth insulating layer and an eleventh conductive layer. The eighth insulating layer may be positioned over the first oxide semiconductor layer and the second oxide semiconductor layer. The eleventh conductive layer may include, in the first opening portion, a region facing the sixth conductive layer with the eighth insulating layer, the first oxide semiconductor layer, and the sixth insulating layer therebetween and a region facing the sixth conductive layer with the eighth insulating layer, the second oxide semiconductor layer, and the sixth insulating layer therebetween.

In the above-described embodiment, a height of a bottom surface of a portion that is of the eleventh conductive layer and positioned between the fifth conductive layer and the eighth conductive layer may be lower than a height of a top surface of a portion that is of the fifth conductive layer and does not overlap with the first opening portion.

In the above-described embodiment, the semiconductor device may further include a ninth insulating layer and a twelfth conductive layer. The ninth insulating layer may be positioned over the eighth insulating layer and include a fifth opening portion at a position overlapping with the first opening portion, and the twelfth conductive layer may be over the ninth insulating layer and include a region in contact with the eleventh conductive layer.

With one embodiment of the present invention, a transistor, semiconductor device, or memory device which can be miniaturized or highly integrated can be provided. With one embodiment of the present invention, a highly reliable transistor, semiconductor device, or memory device can be provided. With one embodiment of the present invention, a low-cost semiconductor device or memory device can be provided. With one embodiment of the present invention, a semiconductor device or memory device with low power consumption can be provided. With one embodiment of the present invention, a semiconductor device or memory device which operates at high speed can be provided. With one embodiment of the present invention, a semiconductor device or memory device which includes a transistor with favorable electrical characteristics can be provided. With one embodiment of the present invention, a semiconductor device or memory device which includes a transistor with a high on-state current can be provided. With one embodiment of the present invention, a semiconductor device or memory device which includes a transistor with small parasitic capacitance can be provided. With one embodiment of the present invention, a method for manufacturing the above-described transistor, semiconductor device, or memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIGS. 1A to 1D are plan views illustrating an example of a semiconductor device;

FIGS. 2A and 2B are cross-sectional views illustrating an example of a semiconductor device;

FIG. 3A is a schematic perspective view illustrating an example of a semiconductor device, FIG. 3B is a plan view illustrating an example of a semiconductor device, and FIG. 3C is a circuit diagram illustrating an example of a memory cell;

FIG. 4A is a cross-sectional view illustrating an example of a semiconductor device and FIG. 4B is a plan view illustrating the example of the semiconductor device;

FIG. 5A is a cross-sectional view illustrating an example of a semiconductor device and FIG. 5B is a plan view illustrating the example of the semiconductor device;

FIGS. 6A and 6B are cross-sectional views illustrating an example of a semiconductor device;

FIGS. 7A and 7B are cross-sectional views each illustrating an example of a semiconductor device;

FIGS. 8A and 8B are cross-sectional views each illustrating an example of a semiconductor device;

FIG. 9 is a cross-sectional view illustrating an example of a semiconductor device;

FIGS. 10A and 10B are cross-sectional views each illustrating an example of a semiconductor device;

FIGS. 11A and 11B are cross-sectional views each illustrating an example of a semiconductor device;

FIGS. 12A and 12B are cross-sectional views each illustrating an example of a semiconductor device;

FIGS. 13A and 13B are cross-sectional views each illustrating an example of a semiconductor device;

FIGS. 14A and 14B are cross-sectional views each illustrating an example of a semiconductor device;

FIGS. 15A and 15B are cross-sectional views each illustrating an example of a semiconductor device;

FIG. 16 is a cross-sectional view illustrating an example of a semiconductor device;

FIGS. 17A and 17B are plan views each illustrating an example of a semiconductor device;

FIG. 18A is a plan view illustrating an example of a semiconductor device and FIGS. 18B and 18C are cross-sectional views illustrating the example of the semiconductor device;

FIG. 19A is a plan view illustrating an example of a semiconductor device and FIGS. 19B and 19C are cross-sectional views illustrating the example of the semiconductor device;

FIGS. 20A and 20D are plan views illustrating an example of a semiconductor device and FIGS. 20B and 20C are cross-sectional views illustrating the example of the semiconductor device;

FIGS. 21A and 21D are plan views illustrating an example of a semiconductor device and FIGS. 21B and 21C are cross-sectional views illustrating the example of the semiconductor device;

FIGS. 22A to 22C are plan views illustrating an example of a semiconductor device;

FIGS. 23A and 23B are cross-sectional views illustrating an example of a semiconductor device;

FIG. 24A is a plan view illustrating an example of a method for manufacturing a semiconductor device and FIGS. 24B and 24C are cross-sectional views illustrating the example of the method for manufacturing a semiconductor device;

FIG. 25A is a plan view illustrating the example of the method for manufacturing a semiconductor device and FIGS. 25B and 25C are cross-sectional views illustrating the example of the method for manufacturing a semiconductor device;

FIG. 26A is a plan view illustrating the example of the method for manufacturing a semiconductor device and FIGS. 26B and 26C are cross-sectional views illustrating the example of the method for manufacturing a semiconductor device;

FIG. 27A is a plan view illustrating the example of the method for manufacturing a semiconductor device and FIGS. 27B and 27C are cross-sectional views illustrating the example of the method for manufacturing a semiconductor device;

FIG. 28A is a plan view illustrating the example of the method for manufacturing a semiconductor device and FIGS. 28B and 28C are cross-sectional views illustrating the example of the method for manufacturing a semiconductor device;

FIG. 29A is a plan view illustrating the example of the method for manufacturing a semiconductor device and FIGS. 29B and 29C are cross-sectional views illustrating the example of the method for manufacturing a semiconductor device;

FIG. 30A is a plan view illustrating the example of the method for manufacturing a semiconductor device and FIGS. 30B and 30C are cross-sectional views illustrating the example of the method for manufacturing a semiconductor device;

FIG. 31A is a plan view illustrating the example of the method for manufacturing a semiconductor device and FIGS. 31B and 31C are cross-sectional views illustrating the example of the method for manufacturing a semiconductor device;

FIG. 32A is a plan view illustrating the example of the method for manufacturing a semiconductor device and FIGS. 32B and 32C are cross-sectional views illustrating the example of the method for manufacturing a semiconductor device;

FIG. 33A is a plan view illustrating the example of the method for manufacturing a semiconductor device and FIGS. 33B and 33C are cross-sectional views illustrating the example of the method for manufacturing a semiconductor device;

FIG. 34A is a plan view illustrating the example of the method for manufacturing a semiconductor device and FIGS. 34B and 34C are cross-sectional views illustrating the example of the method for manufacturing a semiconductor device;

FIG. 35A is a plan view illustrating the example of the method for manufacturing a semiconductor device and FIGS. 35B and 35C are cross-sectional views illustrating the example of the method for manufacturing a semiconductor device;

FIG. 36A is a plan view illustrating the example of the method for manufacturing a semiconductor device and FIGS. 36B and 36C are cross-sectional views illustrating the example of the method for manufacturing a semiconductor device;

FIG. 37A is a plan view illustrating the example of the method for manufacturing a semiconductor device and FIGS. 37B and 37C are cross-sectional views illustrating the example of the method for manufacturing a semiconductor device;

FIG. 38A is a plan view illustrating the example of the method for manufacturing a semiconductor device and FIGS. 38B and 38C are cross-sectional views illustrating the example of the method for manufacturing a semiconductor device;

FIG. 39A is a plan view illustrating the example of the method for manufacturing a semiconductor device and FIGS. 39B and 39C are cross-sectional views illustrating the example of the method for manufacturing a semiconductor device;

FIG. 40A is a plan view illustrating the example of the method for manufacturing a semiconductor device and FIGS. 40B and 40C are cross-sectional views illustrating the example of the method for manufacturing a semiconductor device;

FIG. 41A is a plan view illustrating the example of the method for manufacturing a semiconductor device and FIGS. 41B and 41C are cross-sectional views illustrating the example of the method for manufacturing a semiconductor device;

FIG. 42A is a plan view illustrating the example of the method for manufacturing a semiconductor device and FIGS. 42B and 42C are cross-sectional views illustrating the example of the method for manufacturing a semiconductor device;

FIG. 43 is a band diagram of an oxide semiconductor layer;

FIGS. 44A and 44B are plan views each illustrating an example of a semiconductor device;

FIGS. 45A and 45B are plan views each illustrating an example of a semiconductor device;

FIG. 46 is a cross-sectional view illustrating an example of a semiconductor device;

FIG. 47 is a cross-sectional view illustrating an example of a semiconductor device;

FIG. 48 is a block diagram illustrating an example of a semiconductor device;

FIGS. 49A to 49D are circuit diagrams each illustrating an example of a memory cell;

FIGS. 50A and 50B are schematic perspective views each illustrating an example of a semiconductor device;

FIG. 51 is a block diagram illustrating a CPU;

FIGS. 52A and 52B are schematic perspective views illustrating an example of a semiconductor device;

FIGS. 53A and 53B are schematic perspective views each illustrating an example of a semiconductor device;

FIG. 54 is a conceptual diagram showing a hierarchy of memory devices;

FIGS. 55A and 55B are circuit diagrams each illustrating an example of a semiconductor device and FIG. 55C illustrates an example of an electronic component including a semiconductor device;

FIG. 56 illustrates an example of an electronic component;

FIGS. 57A to 57C illustrate an example of a large computer, FIG. 57D illustrates an example of space equipment, and FIG. 57E illustrates an example of a storage system that can be used in a data center;

FIGS. 58A to 58F illustrate examples of electronic devices;

FIGS. 59A to 59G illustrate examples of electronic devices; and

FIGS. 60A to 60F illustrate examples of electronic devices.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

For easy understanding, the position, size, range, and the like of each component illustrated in drawings do not represent the actual position, size, range, and the like in some cases. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor elements and enables amplification of a current or a voltage, switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an oxide semiconductor (OS) transistor. A transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as Vo) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The content of an element such as hydrogen, oxygen, carbon, or nitrogen in a film can be analyzed by secondary ion mass spectrometry (SIMS) or X-ray photoelectron spectroscopy (XPS or electron spectroscopy for chemical analysis (ESCA)), for example. XPS is suitable when the content of a target element is high (e.g., 0.5 atomic % or more, or 1 atomic % or more). In contrast, SIMS is suitable when the content of a target element is low (e.g., less than 0.5 atomic %, or less than 1 atomic %). To compare the contents of elements, analysis with a combination of SIMS and XPS is preferably used.

Note that in this specification and the like, the term “content percentage” refers to the proportion of a component contained in a film. In the case where an oxide semiconductor layer contains a metal element X, a metal element Y, and a metal element Z whose atomic numbers are respectively represented by A_{X}, A_{Y}, and A_{Z}, the content percentage of the metal element X can be represented by A_{X}/(A_{X}+A_{Y}+A_{Z}). Moreover, in the case where the atomic ratio of the metal element X to the metal element Y to the metal element Z contained in an oxide semiconductor layer is represented by B_{X}:B_{Y}:B_{Z}, the content of the metal element X can be represented by B_{X}/(B_{X}+B_{Y}+B_{Z}).

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle subtended between two straight lines is greater than or equal to −10° and less than or equal to 10°. Thus, the case where the angle is greater than or equal to −5° and less than or equal to 5° is also included. The term “substantially parallel” indicates that the angle subtended between two straight lines is greater than or equal to −20° and less than or equal to 20°. The term “perpendicular” indicates that the angle subtended between two straight lines is greater than or equal to 800 and less than or equal to 100°. Thus, the case where the angle is greater than or equal to 85° and less than or equal to 950 is also included. In addition, the term “substantially perpendicular” indicates that the angle subtended between two straight lines is greater than or equal to 700 and less than or equal to 110°.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element such as a transistor or a switch (note that a wiring is not a circuit element) therebetween, for example. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film or the like of a transistor is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

Unless otherwise specified, an off-state current in this specification and the like refers to a leakage current generated between a source and a drain when a transistor is in an off state (also referred to as a non-conducting state or a cutoff state). Unless otherwise specified, the off state of an n-channel transistor means that a gate-source voltage V_{gs} is lower than a threshold voltage Vₜₕ (the off state of a p-channel transistor means that V_{gs} is higher than Vₜₕ).

Note that “normally-on characteristics” in this specification and the like means a state where a channel is formed and a current flows through a transistor even when no voltage is applied to a gate. Furthermore, “normally-off characteristics” means a state where a current does not flow through a transistor when no potential or a ground potential is applied to a gate.

Note that in this specification and the like, a tapered shape refers to a shape such that at least part of a side surface of a component is inclined with respect to a substrate surface or a formation surface of the component. For example, a tapered shape preferably includes a region where the angle subtended between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially planar shape with a slight curvature or with slight unevenness.

In this specification and the like, when the expression “A is positioned over B” is used, at least part of A is positioned over B. In other words, A includes a region positioned over B, for example. Similarly, when the expression “A is in contact with B” or “A overlaps with B” is used, at least part of A is in contact with or overlaps with B. This can be rephrased as that A includes a region in contact with B or A includes a region overlapping with B, for example. Similarly, in this specification and the like, when the expression “A covers B” is used, at least part of A covers B. This can be rephrased as that A includes a region covering B, for example.

In this specification and the like, disconnection refers to a phenomenon in which a layer, a film, or an electrode is split because of the shape of the formation surface (e.g., a level difference).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, a semiconductor device of one embodiment of the present invention and a method for manufacturing the semiconductor device will be described with reference to drawings.

One embodiment of the present invention relates to a semiconductor device including a pillar capacitor and a vertical transistor (also referred to as a vertical field effect transistor (VFET)). The semiconductor device of one embodiment of the present invention can include a memory cell including a pillar capacitor and a vertical transistor. Therefore, the semiconductor device of one embodiment of the present invention can be a memory device.

In this specification and the like, a vertical transistor refers to a transistor in which a source electrode and a drain electrode are provided at different heights. For example, a transistor in which the bottom surface of the source electrode and the bottom surface of the drain electrode are provided at different heights can be referred to as a vertical transistor. Here, of the source electrode and the drain electrode, an electrode at a lower height from a reference surface is referred to as a lower electrode, and an electrode at a higher height from the reference surface is referred to as an upper electrode. The reference surface can be, for example, the top surface of a substrate or the top surface of a base insulating layer. An interlayer film is provided between the lower electrode and the upper electrode.

In this specification and the like, a pillar capacitor refers to a capacitor in which one of a pair of electrodes has a pillar shape and a dielectric and the other of the pair of electrodes cover the side surface and the top surface of the electrode. In this specification and the like, a pillar shape indicates that the length in the direction perpendicular to the formation surface (height) is greater than or equal to the length in the direction parallel to the formation surface (width). Furthermore, in this specification and the like, a ratio between the height and the width, i.e., a value obtained by dividing the height by the width, is referred to as an aspect ratio. In a pillar-shaped structure, the aspect ratio is greater than or equal to one.

The semiconductor device of one embodiment of the present invention includes a first pillar capacitor, a second pillar capacitor, a first vertical transistor, a second vertical transistor, a first interlayer film, and a second interlayer film. The first pillar capacitor and the second pillar capacitor are provided on the same formation surface. The first interlayer film is positioned over the first pillar capacitor and the second pillar capacitor. The second interlayer film is positioned over the first interlayer film and has an opening portion. Components of the first vertical transistor and the second vertical transistor are partly provided in the opening portion. Specifically, at least part of a semiconductor layer of the first vertical transistor and at least part of a semiconductor layer of the second vertical transistor are provided in the opening portion. Thus, a channel formation region of the first vertical transistor and a channel formation region of the second vertical transistor are provided in the opening portion.

At least part of the opening portion overlaps with a region between the first capacitor and the second capacitor. Thus, the first vertical transistor and the second vertical transistor can be provided to respectively include a region overlapping with the first pillar capacitor and a region overlapping with the second pillar capacitor.

The capacitance per unit area of a pillar capacitor can be higher than that of a planar capacitor (also referred to as parallel-plate capacitor), for example. Thus, in the case where a pillar capacitor is included in a memory cell, an increase in the area occupied by the memory cell can be inhibited and the operation of reading data from the memory cell can be stabilized as compared with the case where a planar capacitor is included, for example. In addition, the area occupied by a vertical transistor can be significantly smaller than that occupied by a planar transistor, for example.

In this specification and the like, a planar capacitor refers to a capacitor in which the aspect ratio of one of a pair of electrodes is lower than one and a dielectric and the other of the pair of electrodes are provided over the electrode. In this specification and the like, a planar transistor refers to a transistor in which a source electrode and a drain electrode are positioned at the same or substantially the same height and a current flowing through a semiconductor layer contains a lateral component.

In the semiconductor device of one embodiment of the present invention, a pillar capacitor and a vertical transistor are used as the capacitor and the transistor included in the memory cell. In addition, the vertical transistor is provided over the pillar capacitor. Furthermore, components of a plurality of vertical transistors are partly provided in one opening portion. Thus, one embodiment of the present invention can provide a semiconductor device that occupies a small area per memory cell. Accordingly, a semiconductor device that can be miniaturized or highly integrated can be provided.

### Structure Example 1 of Semiconductor Device

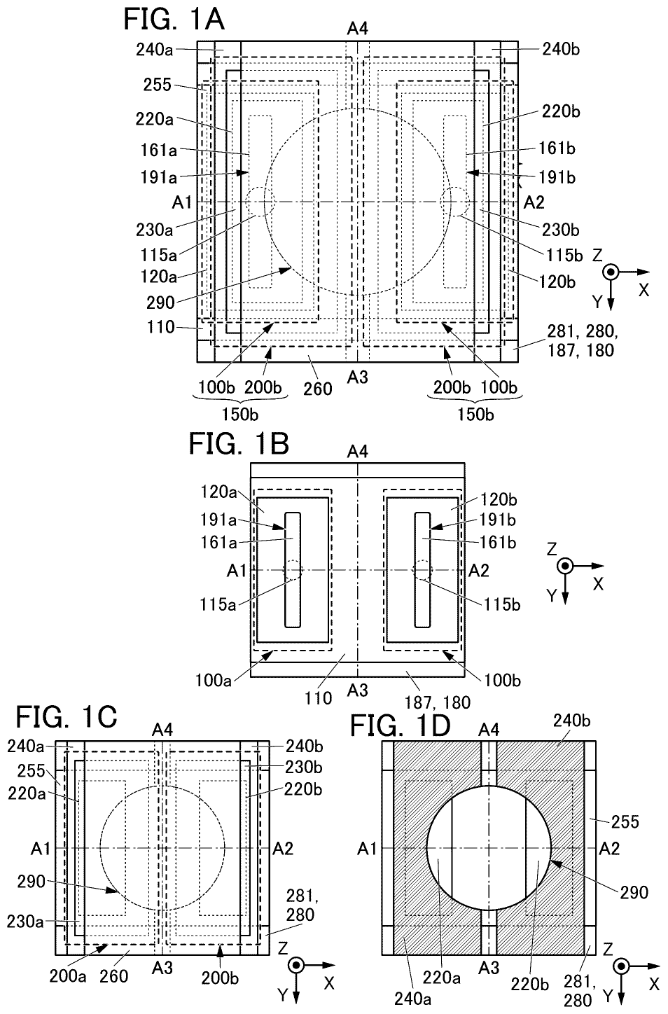

FIG. 1A is a plan view illustrating an example of a semiconductor device of one embodiment of the present invention. The semiconductor device illustrated in FIG. 1A includes a capacitor 100a, a capacitor 100b, a transistor 200a, and a transistor 200b. That is, the semiconductor device illustrated in FIG. 1A includes two capacitors and two transistors.

FIG. 1B is a plan view illustrating an example of the capacitor 100a and the capacitor 100b. FIG. 1C is a plan view illustrating an example of the transistor 200a and the transistor 200b. FIGS. 1B and 1C are diagrams in which some components illustrated in FIG. 1A are omitted. FIG. 1D is a diagram in which some components illustrated in FIG. 1C are omitted. For the sake of clarity of the drawings, some components, e.g., an insulating layer, are not illustrated in the plan views in FIGS. 1A and 1D. Some components may be omitted also in plan views mentioned below.

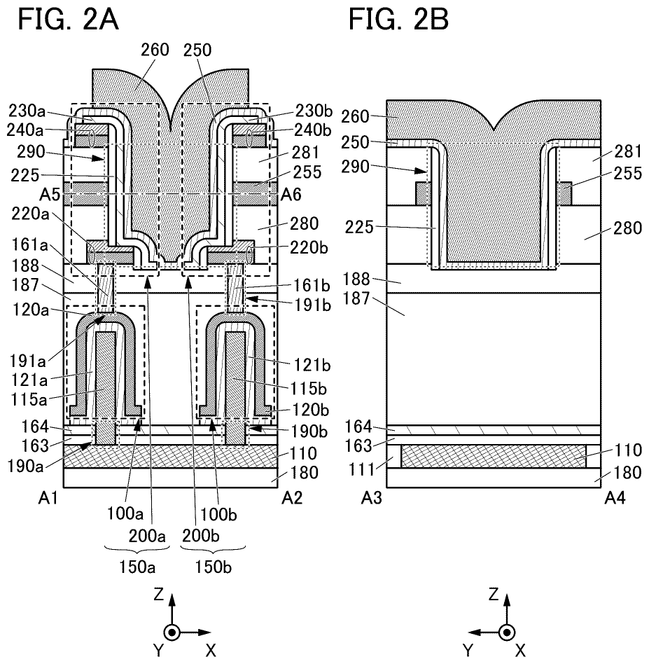

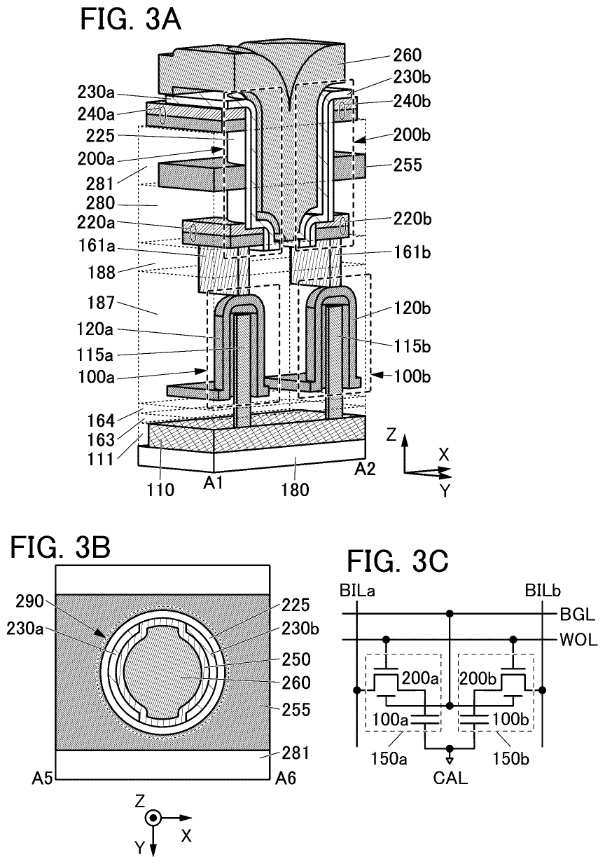

FIG. 2A is a cross-sectional view taken along a dashed-dotted line A1-A2 in FIG. 1A, for example. FIG. 2B is a cross-sectional view taken along a dashed-dotted line A3-A4 in FIG. 1A, for example. FIG. 3A is a schematic perspective view illustrating the semiconductor device illustrated in FIG. 1A to FIG. 2B. Specifically, FIG. 3A is a schematic perspective view of the semiconductor device sectioned along the dashed-dotted line A1-A2 in FIG. 1A, for example. Some components are omitted in FIG. 3A. FIG. 3B is a cross-sectional view taken along a dashed-dotted line A5-A6 in FIG. 2A. FIG. 3B is also referred to as a plan view.

In FIG. 1A to FIG. 3B, the X direction, the Y direction, and the Z direction are indicated by arrows. The directions denoted by X, Y, and Z are consistent in FIG. 1A to FIG. 3B but may be inconsistent among the drawings. The same applies to plan views and cross-sectional views mentioned below.

FIG. 3C is a circuit diagram of the semiconductor device illustrated in FIG. 1A and FIG. 2A. The semiconductor device of one embodiment of the present invention includes a memory cell 150a and a memory cell 150b as illustrated in FIG. 1A, FIG. 2A, FIG. 3A, and FIG. 3C. The memory cell 150a includes the capacitor 100a and the transistor 200a. The memory cell 150b includes the capacitor 100b and the transistor 200b. In other words, the structure illustrated in FIG. 1A, FIG. 2A, and FIG. 3A functions as two memory cells.

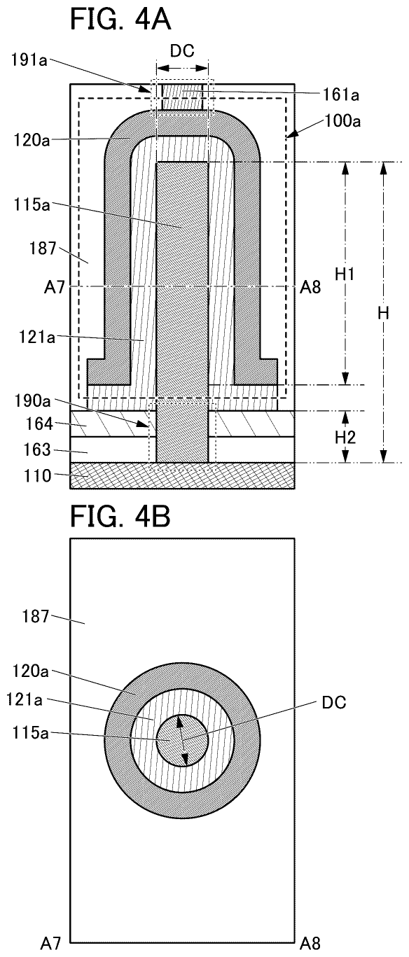

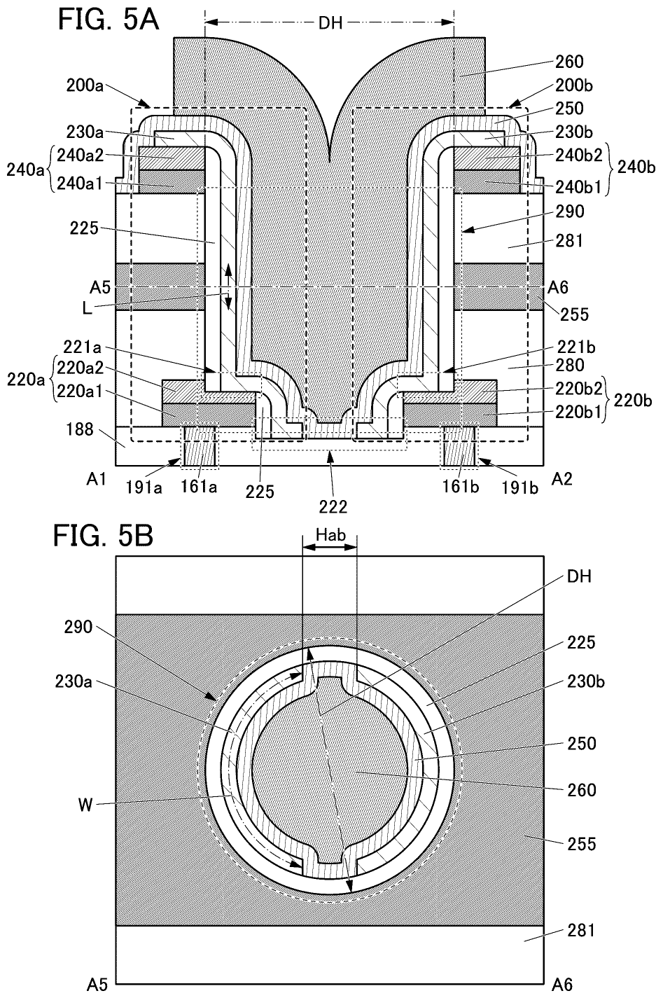

FIG. 4A is an enlarged view of a region including the capacitor 100a illustrated in FIG. 2A. FIG. 4B is a cross-sectional view taken along a dashed-dotted line A7-A8 in FIG. 4A. Note that FIG. 4B is also referred to as a plan view. FIG. 5A is an enlarged view of a region including the transistor 200a and the transistor 200b illustrated in FIG. 2A. FIG. 5B is an enlarged view of FIG. 3B.

One of a pair of electrodes of the capacitor 100a and one of a pair of electrodes of the capacitor 100b are connected to a wiring CAL. One of a source and a drain of the transistor 200a is connected to the other of the pair of electrodes of the capacitor 100a. The other of the source and the drain of the transistor 200a is connected to a wiring BILa. A first gate of the transistor 200a is connected to a wiring WOL. A second gate of the transistor 200a is connected to a wiring BGL.

One of a source and a drain of the transistor 200b is connected to the other of the pair of electrodes of the capacitor 100b. The other of the source and the drain of the transistor 200b is connected to a wiring BILb. A first gate of the transistor 200b is connected to the wiring WOL. A second gate of the transistor 200b is connected to the wiring BGL.

The semiconductor device illustrated in FIG. 1A to FIG. 5B includes an insulating layer 180 over a substrate (not illustrated), a conductive layer 110 and an insulating layer 111 over the insulating layer 180, the memory cell 150a and the memory cell 150b over the conductive layer 110, an insulating layer 163 over the conductive layer 110 and the insulating layer 111, an insulating layer 164 over the insulating layer 163, an insulating layer 187 over the insulating layer 164, an insulating layer 188 over the insulating layer 187, a conductive layer 161a and a conductive layer 161b over the insulating layer 188, an insulating layer 280 over the insulating layer 188, and an insulating layer 281 over the insulating layer 280. Here, the top surface of the conductive layer 110 and the top surface of the insulating layer 111 can be level or substantially level with each other.

The insulating layer 180, the insulating layer 111, the insulating layer 163, the insulating layer 164, the insulating layer 187, the insulating layer 188, the insulating layer 280, and the insulating layer 281 function as interlayer films. The conductive layer 110 functions as the wiring CAL. Note that in the following description, the memory cell 150a and the memory cell 150b are collectively referred to as a memory cell 150 in some cases. The capacitor 100a and the capacitor 100b are collectively referred to as a capacitor 100 in some cases. Furthermore, the transistor 200a and the transistor 200b are collectively referred to as a transistor 200, in some cases.

The memory cell 150a includes the capacitor 100a over the conductive layer 110 and the transistor 200a over the capacitor 100a. Similarly, the memory cell 150b includes the capacitor 100b over the conductive layer 110 and the transistor 200b over the capacitor 100b.

The capacitor 100a includes a conductive layer 115a over the conductive layer 110, an insulating layer 121a over the conductive layer 115a, and a conductive layer 120a over the insulating layer 121a. Similarly, the capacitor 100b includes a conductive layer 115b over the conductive layer 110, an insulating layer 121b over the conductive layer 115b, and a conductive layer 120b over the insulating layer 121b. Note that in the following description, the conductive layer 115a and the conductive layer 115b are collectively referred to as a conductive layer 115 in some cases. Furthermore, the insulating layer 121a and the insulating layer 121b are collectively referred to as an insulating layer 121 in some cases. Moreover, the conductive layer 120a and the conductive layer 120b are collectively referred to as a conductive layer 120 in some cases.

In the capacitor 100a and the capacitor 100b, the conductive layer 115a and the conductive layer 115b each function as one of a pair of electrodes (also referred to as a lower electrode). In the capacitor 100a and the capacitor 100b, the conductive layer 120a and the conductive layer 120b each function as the other of the pair of electrodes (also referred to as an upper electrode). Furthermore, the insulating layer 121a functions as a dielectric of the capacitor 100a, and the insulating layer 121b functions as a dielectric of the capacitor 100b. That is, the capacitor 100 is a metal-insulator-metal (MIM) capacitor.

As illustrated in FIGS. 2A and 2B, an opening portion 190a and an opening portion 190b reaching the conductive layer 110 are provided in the insulating layer 163 and the insulating layer 164. The conductive layer 115a includes a region in contact with the top surface of the conductive layer 110, a region in contact with the side surface of the insulating layer 163 in the opening portion 190a, a region in contact with the side surface of the insulating layer 164 in the opening portion 190a, and a region in contact with the insulating layer 121a. Similarly, the conductive layer 115b includes a region in contact with the top surface of the conductive layer 110, a region in contact with the side surface of the insulating layer 163 in the opening portion 190b, a region in contact with the side surface of the insulating layer 164 in the opening portion 190b, and a region in contact with the insulating layer 121b. The conductive layer 115a and the conductive layer 115b each have a pillar shape. Note that in the following description, the opening portion 190a and the opening portion 190b are collectively referred to as an opening portion 190 in some cases.

In the case where the pillar-shaped conductive layer 115 is provided to include the regions in contact with the side surfaces of the insulating layer 163 and the insulating layer 164 in the opening portion 190, the conductive layer 115 can be inhibited from falling down in the manufacturing process of the semiconductor device, for example, as compared with the case where the insulating layer 163 and the insulating layer 164 are not provided in the semiconductor device. Thus, the semiconductor device can be provided with high manufacturing yield at low cost. Note that the insulating layer 163 or the insulating layer 164 is not necessarily provided. As long as the conductive layer 115 does not fall down, both the insulating layer 163 and the insulating layer 164 are not necessarily provided.

The insulating layer 121a is positioned over the conductive layer 115a and the insulating layer 164. The insulating layer 121b is positioned over the conductive layer 115b and the insulating layer 164. The insulating layer 121a is provided over the insulating layer 164 to cover the side surface and the top surface of the conductive layer 115a. Similarly, the insulating layer 121b is provided over the insulating layer 164 to cover the side surface and the top surface of the conductive layer 115b.

The conductive layer 120a is provided over the insulating layer 121a to include a region overlapping with the conductive layer 115a. Similarly, the conductive layer 120b is provided over the insulating layer 121b to include a region overlapping with the conductive layer 115b. The conductive layer 120a is provided over the insulating layer 121a to cover the side surface and the top surface of the conductive layer 115a. Similarly, the conductive layer 120b is provided over the insulating layer 121b to cover the side surface and the top surface of the conductive layer 115b.

In the above-described manner, the capacitor 100 includes the pillar-shaped conductive layer 115 and the insulating layer 121 and the conductive layer 120 that cover the side surface and the top surface of the conductive layer 115. Thus, the capacitor 100 is a pillar capacitor.

The conductive layer 120a includes a region that overlaps with the top surface of the conductive layer 115a with the insulating layer 121a therebetween and a region that faces the side surface of the conductive layer 115a. Similarly, the conductive layer 120b includes a region that faces the side surface of the conductive layer 115b with the insulating layer 121b therebetween. Accordingly, the capacitance of the capacitor 100a and the capacitor 100b can be increased without an increase in the area, as compared with a planar capacitor, for example. Increasing the capacitance per unit area of the capacitor 100a and the capacitor 100b in this manner allows a stable read operation of the semiconductor device. This also allows further miniaturization or higher integration of the semiconductor device.

As illustrated in FIGS. 1A and 1B, the conductive layer 115a and the conductive layer 115b are preferably circular in a plan view. That is, the conductive layer 115a and the conductive layer 115b each preferably have a cylindrical shape. Thus, the conductive layer 115a and the conductive layer 115b can have a structure without a corner portion in a plan view. In the case where the conductive layer 115a and the conductive layer 115b include corner portions, electric field concentration might occur in regions of the insulating layer 121a and the insulating layer 121b in the vicinity of the corner portions. This might cause dielectric breakdown of the insulating layer 121a and the insulating layer 121b. Thus, in the case where the conductive layer 115a and the conductive layer 115b each have a cylindrical shape, electric field concentration in the insulating layer 121a and the insulating layer 121b can be inhibited in some cases. Note that in this specification and the like, a circular shape is not necessarily a perfect circular shape.

In the case where the conductive layer 115a and the conductive layer 115b are circular in a plan view, the opening portion 190a and the opening portion 190b are also circular in a plan view. This can increase processing accuracy in forming the opening portion 190a and the opening portion 190b, making it possible to form the opening portions in minute sizes.

Note that the conductive layer 115a and the conductive layer 115b may each include a corner portion in a plan view. For example, the conductive layer 115a and the conductive layer 115b may be square, rectangular, or polygonal in a plan view. In the case where the conductive layer 115a and the conductive layer 115b each have a structure including a corner portion in a plan view, the base areas of the conductive layer 115a and the conductive layer 115b can be larger than those of the case where the conductive layer 115a and the conductive layer 115b are circular in some cases. This can inhibit the conductive layer 115a and the conductive layer 115b from falling down in the manufacturing process of the semiconductor device, for example, in some cases.

FIG. 2A illustrates an example in which an end portion of the insulating layer 121a is aligned or substantially aligned with an end portion of the conductive layer 120a and an end portion of the insulating layer 121b is aligned or substantially aligned with an end portion of the conductive layer 120b. Although details will be described later, by processing an insulating film to be the insulating layer 121a and the insulating layer 121b and a conductive film to be the conductive layer 120a and the conductive layer 120b using the same mask, the end portion of the insulating layer 121a can be aligned or substantially aligned with the end portion of the conductive layer 120a, and the end portion of the insulating layer 121b can be aligned or substantially aligned with the end portion of the conductive layer 120b.

The insulating layer 187 is positioned over the conductive layer 120a, the conductive layer 120b, the insulating layer 121a, the insulating layer 121b, and the insulating layer 164. The insulating layer 188 is positioned over the insulating layer 187. The insulating layer 187 can be planarized to have a planar top surface. The insulating layer 187 is provided to fill a region between the capacitors 100. Note that the insulating layer 188 is not necessarily provided.

An opening portion 191a reaching the conductive layer 120a and an opening portion 191b reaching the conductive layer 120b are provided in the insulating layer 188 and the insulating layer 187. The conductive layer 161a is provided in the opening portion 191a, and the conductive layer 161b is provided in the opening portion 191b.

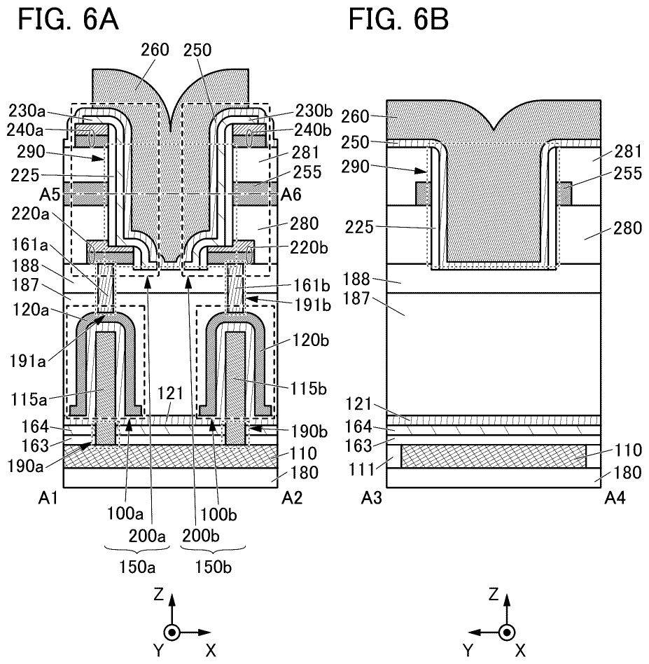

FIGS. 6A and 6B illustrate an example in which the dielectric of the capacitor 100a and the dielectric of the capacitor 100b illustrated in FIGS. 2A and 2B are the same insulating layer. For the plan view structure example, FIGS. 1A to 1D can be referred to. FIG. 3B can be referred to for a cross-sectional view along a dashed-dotted line A5-A6 in FIG. 6A.

In FIGS. 6A and 6B, the insulating layer functioning as the dielectrics of the capacitor 100a and the capacitor 100b is the insulating layer 121. For example, the semiconductor device having the structure illustrated in FIGS. 6A and 6B can be manufactured by, after forming the conductive layer 120a and the conductive layer 120b, forming the insulating layer 187 without processing the insulating film under the conductive layer 120a and the conductive layer 120b.

### [Transistor 200]

The transistor 200a includes a conductive layer 220a over the conductive layer 161a and the insulating layer 188; a conductive layer 255 over the insulating layer 280; a conductive layer 240a over the insulating layer 281; an insulating layer 225; an oxide semiconductor layer 230a over the conductive layer 220a and the conductive layer 240a; an insulating layer 250 over the oxide semiconductor layer 230a; and a conductive layer 260 over the insulating layer 250. Here, FIG. 1D is a plan view in which the conductive layer 260, the oxide semiconductor layer 230a, and the oxide semiconductor layer 230b illustrated in FIG. 1C are omitted and the conductive layers 240a and 240b are shown with hatching patterns.

Similarly, the transistor 200b includes a conductive layer 220b over the conductive layer 161b and the insulating layer 188; the conductive layer 255; the conductive layer 240b over the insulating layer 281; the insulating layer 225; the oxide semiconductor layer 230b over the conductive layer 220b and the conductive layer 240b; the insulating layer 250 over the oxide semiconductor layer 230b; and the conductive layer 260 over the insulating layer 250.

The oxide semiconductor layer 230a and the oxide semiconductor layer 230b function as semiconductor layers of the transistor 200a and the transistor 200b, respectively. The conductive layer 255 functions as a first gate electrode of each of the transistor 200a and the transistor 200b. The insulating layer 225 functions as a first gate insulating layer of each of the transistor 200a and the transistor 200b. The conductive layer 260 functions as a second gate electrode of each of the transistor 200a and the transistor 200b. The insulating layer 250 functions as a second gate insulating layer of each of the transistor 200a and the transistor 200b.

The conductive layer 220a functions as one of a source electrode and a drain electrode of the transistor 200a. The conductive layer 220b functions as one of a source electrode and a drain electrode of the transistor 200b. The conductive layer 240a functions as the other of the source electrode and the drain electrode of the transistor 200a. The conductive layer 240b functions as the other of the source electrode and the drain electrode of the transistor 200b.

The conductive layer 220a is connected to the conductive layer 120a through the conductive layer 161a. In this manner, the upper electrode of the capacitor 100a is connected to one of the source electrode and the drain electrode of the transistor 200a. Similarly, the conductive layer 220b is connected to the conductive layer 120b through the conductive layer 161b. Thus, the upper electrode of the capacitor 100b is connected to one of the source electrode and the drain electrode of the transistor 200b. The conductive layer 161a can be in contact with the conductive layer 120a and the conductive layer 220a, for example. The conductive layer 161b can be in contact with the conductive layer 120b and the conductive layer 220b, for example. Furthermore, the conductive layer 220a can include a region in contact with the top surface of the conductive layer 161a, for example. The conductive layer 220b can include a region in contact with the top surface of the conductive layer 161b, for example.

The conductive layer 255 is provided to extend in the X direction and the conductive layer 260 is provided to extend in the Y direction. The conductive layer 255 functions as one of the wiring WOL and the wiring BGL. The conductive layer 260 functions as the other of the wiring WOL and the wiring BGL. The conductive layer 255 and the conductive layer 260 can each be regarded as also having a function of a gate wiring. In addition, the conductive layer 255 may be provided to extend in the Y direction. The conductive layer 260 may be provided to extend in the X direction.

The insulating layer 280 is positioned over the conductive layers 220a and 220b. The insulating layer 281 is positioned over the conductive layer 255.

As illustrated in FIGS. 1A, 1C, and 1D and FIG. 2A to FIG. 3B, an opening portion 290 reaching the conductive layers 220a and 220b and the insulating layer 188 is provided in the insulating layer 280, the conductive layer 255, and the insulating layer 281. As illustrated in FIGS. 1A, 1C, and 1D and FIG. 3B, the opening portion 290 preferably has a circular shape in the plan view. When the opening portion has a circular shape, the processing accuracy in forming the opening portion can be increased, and thus the opening portion can be formed to have a minute size.

The opening portion 290 includes an opening portion in the insulating layer 280, an opening portion of the conductive layer 255, and an opening portion of the insulating layer 281. The shape and the size of the opening portion 290 in the plan view may differ from layer to layer. When the shape of the opening portion 290 is circular in the plan view, the opening portions included in the layers may or may not be concentric with each other.

At least parts of the components of the transistor 200a and the transistor 200b are provided in the opening portion 290. Specifically, at least parts of the insulating layer 225, the oxide semiconductor layer 230a, the oxide semiconductor layer 230b, the insulating layer 250, and the conductive layer 260 are provided in the opening portion 290. In addition, the parts of the insulating layer 225, the oxide semiconductor layer 230a, the oxide semiconductor layer 230b, the insulating layer 250, and the conductive layer 260 that are provided in the opening portion 290 reflect the shape of the opening portion 290.

Thus, in the semiconductor device of one embodiment of the present invention, a plurality of transistors 200 are provided in one opening portion 290. Note that a structure in which one transistor 200 is provided in one opening portion 290 may also be employed.

The insulating layer 225 is provided along the sidewall of the opening portion 290, the side surface of the conductive layer 220a that overlaps with the opening portion 290, and the side surface of the conductive layer 220b that overlaps with the opening portion 290. The oxide semiconductor layer 230a is provided along the top surface of the conductive layer 240a, the side surface of the insulating layer 225, the top surface of the conductive layer 220a, and the top surface of the insulating layer 188. The oxide semiconductor layer 230b is provided along the top surface of the conductive layer 240b, the side surface of the insulating layer 225, the top surface of the conductive layer 220b, and the top surface of the insulating layer 188. The insulating layer 250 is provided along the top surface and the side surface of the oxide semiconductor layer 230a, the top surface and the side surface of the oxide semiconductor layer 230b, the top surface of the insulating layer 188, the top surface and the side surface of the conductive layer 240a, the top surface and the side surface of the conductive layer 240b, and the top surface of the insulating layer 281. Here, the insulating layer 225 is provided along the sidewall of the opening portion 290, and the oxide semiconductor layers 230a and 230b are provided along the side surface of the insulating layer 225, which means that the oxide semiconductor layers 230a and 230b are provided along the sidewall of the opening portion 290. The insulating layer 250 is provided along the side surfaces of the oxide semiconductor layers 230a and 230b in the opening portion 290, which means that the insulating layer 250 is also provided along the sidewall of the opening portion 290.

The oxide semiconductor layer 230a includes a region in contact with the top surface of the conductive layer 220a and a region in contact with the top surface of the conductive layer 240a. Similarly, the oxide semiconductor layer 230b includes a region in contact with the top surface of the conductive layer 220b and a region in contact with the top surface of the conductive layer 240b.

The conductive layer 240a and the conductive layer 240b are provided apart from each other over the insulating layer 281. The conductive layer 240a and the conductive layer 240b are provided to extend in the Y direction. The conductive layer 240a and the conductive layer 240b function as the wiring BILa and the wiring BILb, respectively. Alternatively, the conductive layer 240a and the conductive layer 240b may be provided to extend in the X direction.

The conductive layer 240a and the conductive layer 240b include a cutout portion at a position overlapping with the opening portion 290. In a plan view, the outline of the cutout portion coincides or substantially coincides with part of the outline of the opening portion 290. For example, in the case where the opening portion 290 is circular in the plan view, the cutout portion has an arc shape. The sidewall of the opening portion 290 includes the side surface of the insulating layer 280, the side surface of the conductive layer 255, and the side surface of the insulating layer 281.

The contact area between the conductive layer 240a and the oxide semiconductor layer 230a and the contact area between the conductive layer 240b and the oxide semiconductor layer 230b are larger in the case where the conductive layer 240a and the conductive layer 240b each include the cutout portion than in the case where the conductive layer 240a and the conductive layer 240b include no cutout portion. Thus, the on-state current of the transistor 200a and the transistor 200b can be increased. Here, the case where the conductive layer 240a and the conductive layer 240b include no cutout portion refers to the case where the side surfaces of the conductive layers 240a and 240b that face each other do not coincide with the outline of the opening portion 290, in which case the shapes of the conductive layers 240a and 240b in the plan view are, for example, quadrangular.

The insulating layer 225 is provided along at least part of the sidewall of the opening portion 290. In FIG. 2A to FIG. 3B, the insulating layer 225 is provided to cover the sidewall of the opening portion 290. Specifically, the insulating layer 225 includes a region in contact with the side surface of the insulating layer 281, a region in contact with the side surface of the conductive layer 255, and a region in contact with the side surface of the insulating layer 280 in the opening portion 290. The insulating layer 225 includes a region in contact with the inner side surface (on the opening portion 290 side in the plan view) of the conductive layer 240a and a region in contact with the inner side surface (on the opening portion 290 side in the plan view) of the conductive layer 240b. The insulating layer 225 can also be referred to as a sidewall, a sidewall insulating layer, or a sidewall protective layer, for example.

The insulating layer 225 includes a region in contact with the side surface of the conductive layer 220a on the opening portion 290 side and a region in contact with the side surface of the conductive layer 220b on the opening portion 290 side in some cases. In this case, the insulating layer 225 can include a region in contact with the insulating layer 188.

The oxide semiconductor layer 230a and the oxide semiconductor layer 230b are provided apart from each other. As illustrated in FIG. 3B, the oxide semiconductor layer 230a and the oxide semiconductor layer 230b in the opening portion 290 are each provided to have an arc shape in the plan view.

The oxide semiconductor layer 230a and the oxide semiconductor layer 230b are provided to cover part of the insulating layer 225 in the opening portion 290. The oxide semiconductor layer 230a and the oxide semiconductor layer 230b each include a region facing the conductive layer 255 with the insulating layer 225 therebetween in the opening portion 290. The oxide semiconductor layer 230a includes a region in contact with the top surface of the conductive layer 220a in the opening portion 290 and a region in contact with the top surface of the conductive layer 240a outside the opening portion 290. Similarly, the oxide semiconductor layer 230b includes a region in contact with the top surface of the conductive layer 220b in the opening portion 290 and a region in contact with the top surface of the conductive layer 240b outside the opening portion 290. The oxide semiconductor layer 230a and the oxide semiconductor layer 230b can each include a region in contact with the top surface of the insulating layer 188.

Part of an end portion of the oxide semiconductor layer 230a and part of an end portion of the oxide semiconductor layer 230b are positioned in the opening portion 290. Another part of the end portion of the oxide semiconductor layer 230a is positioned over the conductive layer 240a. Similarly, another part of the end portion of the oxide semiconductor layer 230b is positioned over the conductive layer 240b. FIG. 1A to FIG. 5B illustrate an example in which another part of the end portion of the oxide semiconductor layer 230a is positioned inside (on the opening portion 290 side of) an end portion of the conductive layer 240a on the opposite side to the opening portion 290 in a plan view. Similarly, FIG. 1A to FIG. 5B illustrate an example in which another part of the end portion of the oxide semiconductor layer 230b is positioned inside (on the opening portion 290 side of) an end portion of the conductive layer 240b on the opposite side to the opening portion 290 in a plan view.

The insulating layer 250 is provided to cover the oxide semiconductor layer 230a and the oxide semiconductor layer 230b in the opening portion 290. The insulating layer 250 is provided to cover the top surfaces and the side surfaces of the oxide semiconductor layer 230a, the oxide semiconductor layer 230b, the conductive layer 240a, and the conductive layer 240b over the insulating layer 281. The insulating layer 250 can include a region in contact with the insulating layer 188. The insulating layer 250 has a depressed portion at a position overlapping with the opening portion 290.

As described above, FIG. 1A to FIG. 5B illustrate a structure in which in the outside of the opening portion 290, the end portion of an oxide semiconductor layer 230 is positioned inside the end portion of the conductive layer 240. In addition, in the plan view, the end portion of the oxide semiconductor layer 230 outside the opening portion 290 is positioned inside the end portion of the conductive layer 240 on the opposite side to the opening portion 290, that is, the end portion of the oxide semiconductor layer 230 outside the opening portion 290 is closer to the opening portion 290 than the end portion of the conductive layer 240 on the opposite side to the opening portion 290 is. In this case, the top surface of the conductive layer 240a includes a region in contact with the insulating layer 250 and a region in contact with the oxide semiconductor layer 230a. Similarly, the top surface of the conductive layer 240b includes a region in contact with the insulating layer 250 and a region in contact with the oxide semiconductor layer 230b.

The conductive layer 260 is provided to fill at least part of the depressed portion of the insulating layer 250. The conductive layer 260 includes a region facing the oxide semiconductor layer 230a with the insulating layer 250 therebetween and a region facing the oxide semiconductor layer 230b with the insulating layer 250 therebetween in the opening portion 290. The conductive layer 260 includes a region facing the conductive layer 255 with the insulating layer 225, the oxide semiconductor layer 230a, and the insulating layer 250 therebetween and a region facing the conductive layer 255 with the insulating layer 225, the oxide semiconductor layer 230b, and the insulating layer 250 therebetween in the opening portion 290.

As described above, the oxide semiconductor layer 230a and the oxide semiconductor layer 230b are provided in the opening portion 290. The transistor 200a and the transistor 200b each have a structure in which a current flows in the vertical direction since one of a source electrode and a drain electrode (here, the conductive layer 220a and the conductive layer 220b) is positioned on the lower side and the other of the source electrode and the drain electrode (here, the conductive layer 240a and the conductive layer 240b) is positioned on the upper side. In other words, a channel is formed along the sidewall of the opening portion 290. That is, the transistor 200a and the transistor 200b are vertical transistors.

The conductive layer 255 includes a region facing the conductive layer 260 with the insulating layer 225, the oxide semiconductor layer 230a, and the insulating layer 250 therebetween and a region facing the conductive layer 260 with the insulating layer 225, the oxide semiconductor layer 230b, and the insulating layer 250 therebetween. In the oxide semiconductor layer 230a and the oxide semiconductor layer 230b, the region sandwiched between the conductive layer 255 and the conductive layer 260 and the vicinity of the region function as channel formation regions of the transistor 200a and the transistor 200b. One of a region of the oxide semiconductor layer 230a which is in the vicinity of the conductive layer 220a and a region of the oxide semiconductor layer 230a which is in the vicinity of the conductive layer 240a functions as a source region, and the other functions as a drain region. Similarly, one of a region of the oxide semiconductor layer 230b which is in the vicinity of the conductive layer 220b and a region of the oxide semiconductor layer 230b which is in the vicinity of the conductive layer 240b functions as a source region, and the other functions as a drain region. In other words, a channel formation region is sandwiched between the source region and the drain region.

The above structure enables the channel formation region and at least one of the source region and the drain region to be formed in the opening portion 290. Thus, the areas occupied by the transistor 200a and the transistor 200b can be reduced as compared with a planar transistor in which the channel formation region, the source region, and the drain region are provided separately on the XY plane. Accordingly, the semiconductor device can be miniaturized or highly integrated.

At least part of the opening portion 290 overlaps with a region between the capacitor 100a and the capacitor 100b. Specifically, at least part of the opening portion 290 overlaps with a region between the conductive layer 120a and the conductive layer 120b. The opening portion 290 can include a region overlapping with the conductive layer 120a and a region overlapping with the conductive layer 120b. Furthermore, the opening portion 290 may include a region overlapping with the conductive layer 115a and a region overlapping with the conductive layer 115b.

In the above-described manner, the transistor 200a can be provided to include a region overlapping with the capacitor 100a. For example, the conductive layer 220a, the oxide semiconductor layer 230a, the conductive layer 240a, the conductive layer 255, the conductive layer 260, the insulating layer 225, and the insulating layer 250 can each include a region overlapping with the conductive layer 120a. Similarly, the transistor 200b can be provided to include a region overlapping with the capacitor 100b. For example, the conductive layer 220b, the oxide semiconductor layer 230b, the conductive layer 240b, the conductive layer 255, the conductive layer 260, the insulating layer 225, and the insulating layer 250 can each include a region overlapping with the conductive layer 120b. Accordingly, the area occupied by one memory cell 150 can be reduced. Thus, the semiconductor device can be miniaturized or highly integrated.

In the semiconductor device of one embodiment of the present invention, the channel formation regions of the transistor 200a and the transistor 200b are provided in the same opening portion 290. This structure can reduce the area occupied by one memory cell 150, for example, compared with the case where the channel formation region of only one transistor is provided in one opening portion 290. Accordingly, the semiconductor device can be miniaturized or highly integrated.

In particular, in the semiconductor device of one embodiment of the present invention, the transistor 200a and the transistor 200b are provided to each include a region overlapping with the pillar capacitor, which can have high capacitance even when miniaturized. That is, with this structure, both the capacitors and the transistors are easily miniaturized or highly integrated. Accordingly, in one embodiment of the present invention, the semiconductor device can be favorably miniaturized or highly integrated.

The transistor 200a and the transistor 200b illustrated in FIG. 1A to FIG. 3B each include the conductive layer 255 functioning as the first gate electrode and the conductive layer 260 functioning as the second gate electrode. By changing the potential applied to the conductive layer 260 independently of the potential applied to the conductive layer 255, the threshold voltages Vth of the transistors can be controlled. Specifically, when a negative potential is applied to the conductive layer 260, the Vₜₕ of the transistors can be further increased and the off-state currents can be reduced. Thus, a drain current at a potential applied to the conductive layer 255 of 0 V can be lower when a negative potential is applied to the conductive layer 260 than when no potential or a potential of 0 V or higher is applied to the conductive layer 260. In addition, the conductive layer 255 may function as the second gate electrode and the conductive layer 260 may function as the first gate electrode.

Alternatively, the conductive layer 260 may be connected to the conductive layer 255. By applying the same potential to the conductive layer 255 and the conductive layer 260 that are connected to each other, the on-state current can be increased, variations in the initial characteristics can be reduced, degradation in electric characteristics due to a negative gate bias-temperature (-GBT) stress test, and a change in the current onset voltage at different drain voltages can be suppressed.

As described above, the transistor 200a and the transistor 200b illustrated in FIG. 1A to FIG. 3B each have a structure including two gate electrodes (the first gate electrode and the second gate electrode). Thus, the transistor 200a and the transistor 200b can have favorable electrical characteristics.

It is preferable that the conductive layer 240a and the conductive layer 240b not positioned in the opening portion 290. That is, it is preferable that the conductive layer 240a and the conductive layer 240b not include a region in contact with the side surface of the insulating layer 281 in the opening portion 290. With this structure, cutout portions of the conductive layer 240a and the conductive layer 240b and an opening portion of the insulating layer 280 can be formed collectively. Furthermore, the insulating layer 225, the oxide semiconductor layer 230a, the oxide semiconductor layer 230b, and the like can be inhibited from being divided due to a step between the conductive layer 240a and the insulating layer 280, a step between the conductive layer 240b and the insulating layer 280, or the like.

In addition, Parts of components of three or more transistors may be provided in the opening portion 290. For example, parts of components of four transistors can be provided in the opening portion 290.

FIG. 4A is an enlarged view of a region including the capacitor 100a illustrated in FIG. 2A as described above. FIG. 4B is a cross-sectional view taken along the dashed-dotted line A7-A8 in FIG. 4A. Although a structure example of the capacitor 100a is described below with reference to FIGS. 4A and 4B, the description can apply to the capacitor 100b by replacing a with b, for example.

In FIG. 4A, the height of the conductive layer 115a having a pillar shape is defined as a height H. The height from the bottom surface of the conductive layer 120a to the top surface of the conductive layer 115a is defined as a height H1. The height H1 can be the height of a region where the side surface of the conductive layer 115a and the side surface of the conductive layer 120a face each other. Furthermore, the total thickness of the insulating layer 163 and the insulating layer 164 is defined as a height H2. The height H2 can be the height from the top surface of the conductive layer 110 to the bottom surface of the insulating layer 121a. Here, a part of the undersurface of the conductive layer 120a that is the lowest in height from the top surface of the insulating layer 164 is defined as the bottom surface of the conductive layer 120a. A part of the undersurface of the insulating layer 121a that is in contact with the top surface of the insulating layer 164 is defined as the bottom surface of the insulating layer 121a.

FIGS. 4A and 4B illustrate a width DC of the conductive layer 115a. In the case where the conductive layer 115a has a cylindrical shape, the diameter can be the width DC. In the case where the conductive layer 115a has a pillar shape with a square bottom surface, the length of one side of the square can be the width DC. In the case where the conductive layer 115a has a pillar shape with a rectangular bottom surface, the length of the short side of the rectangle can be the width DC. Alternatively, the length of the long side of the rectangle may be the width DC. Furthermore, in the case where the conductive layer 115a has a pillar shape with a polygonal bottom surface, the length of the shortest side of the polygon can be the width DC, for example. Note that in the case where the width of the bottom surface of the conductive layer 115a is different from the width of the top surface of the conductive layer 115a, the width of the bottom surface can be the width DC. Here, the ratio between the height H and the width DC, i.e., the value obtained by dividing the height H by the width DC, is referred to as the aspect ratio of the conductive layer 115a. As the aspect ratio is higher, the height H increases with respect to the width DC.

The height H1 with respect to the width DC is preferably as large as possible within the range where the conductive layer 115a does not fall down in the manufacturing process of the semiconductor device. This can increase the capacitance of the capacitor 100a while reducing the area occupied by the capacitor 100a. Thus, the read operation of the semiconductor device can be stabilized, and miniaturization or high integration of the semiconductor device can be promoted.

The height H1 can be, for example, greater than or equal to 1 time and less than or equal to 100 times the width DC, and is preferably greater than or equal to 1 time and less than or equal to 50 times, further preferably greater than or equal to 1 time and less than or equal to 30 times, still further preferably greater than or equal to 1.5 times and less than or equal to 10 times the width DC. The width DC can be, for example, greater than or equal to 5 nm and less than or equal to 100 nm, preferably greater than or equal to 5 nm and less than or equal to 50 nm, further preferably greater than or equal to 10 nm and less than or equal to 30 nm. For example, the height H1 can be greater than or equal to 5 nm and less than or equal to 2000 nm, and is preferably greater than or equal to 7.5 nm and less than or equal to 1000 nm, further preferably greater than or equal to 10 nm and less than or equal to 500 nm, still further preferably greater than or equal to 15 nm and less than or equal to 300 nm.

The height H2 is preferably set such that the conductive layer 115a does not fall down in the manufacturing process of the semiconductor device and the height H1 is as high as possible.

FIG. 4B illustrates an example where the conductive layer 115a has a circular shape in a plan view. As described above, the insulating layer 121a and the conductive layer 120a are provided along the shape of the conductive layer 115a. Thus, in the example illustrated in FIG. 4B, the insulating layer 121a and the conductive layer 120a each have an annular shape in the plan view along the dashed-dotted line A7-A8 in FIG. 4A. Specifically, in the plan view along the dashed-dotted line A7-A8 in FIG. 4A, the insulating layer 121a and the conductive layer 120a each have an annular shape having an opening portion that is concentric with the conductive layer 115a. The conductive layer 120a is provided outside the insulating layer 121a (on the opposite side to the conductive layer 115a).

FIG. 5A is an enlarged view of a region including the transistor 200a and the transistor 200b illustrated in FIG. 2A as described above. FIG. 5B is an enlarged view of FIG. 3B.

As illustrated in FIG. 5B, the side surface of the conductive layer 255 provided outside the opening portion 290 faces the side surface of the oxide semiconductor layer 230a and the side surface of the oxide semiconductor layer 230b with the insulating layer 225 therebetween. The side surface of the conductive layer 260 provided in the region including the center of the opening portion 290 faces the side surface of the oxide semiconductor layer 230a and the side surface of the oxide semiconductor layer 230b with the insulating layer 250 therebetween. In other words, at least part of a portion of the oxide semiconductor layer 230a that is positioned in the opening portion 290 serves as the channel formation region of the transistor 200a. At least part of a portion of the oxide semiconductor layer 230b that is positioned in the opening portion 290 serves as the channel formation region of the transistor 200b. In this case, for example, the channel width of the transistor 200a is determined by the length of the perimeter of a portion of the oxide semiconductor layer 230a that is positioned in the opening portion 290. The channel width of the transistor 200b is determined by the length of the perimeter of a portion of the oxide semiconductor layer 230b that is positioned in the opening portion 290. Accordingly, it can be said that the channel widths of the transistor 200a and the transistor 200b are determined by the width of the opening portion 290 (the diameter in the case where the opening portion 290 is circular in the plan view) and the distance between the oxide semiconductor layer 230a and the oxide semiconductor layer 230b, e.g., the distance between the end portion of the oxide semiconductor layer 230a and the end portion of the oxide semiconductor layer 230b. In FIGS. 5A and 5B, the width of the opening portion 290 is denoted by DH. FIG. 5B also illustrates a channel width W of the transistor 200a and a distance Hab between the end portion of the oxide semiconductor layer 230a and the end portion of the oxide semiconductor layer 230b. Note that the distance Hab can be measured on the XY plane including the conductive layer 255.

By increasing the width DH of the opening portion 290, the channel width per unit area can be increased and the on-state current can be increased. Meanwhile, the area occupied by the transistor 200, for example, the area of the transistor 200 in the plan view, is roughly determined by the width of the opening portion 290. When the width DH of the opening portion 290 is reduced, the area occupied by the transistor 200 can be reduced and the semiconductor device can be highly integrated.

The width DH of the opening portion 290 sometimes varies in the depth direction (the Z direction in the case where the side surface of the opening portion 290 is perpendicular to the substrate surface). Here, the shortest distance between two side surfaces of the insulating layer 281 in the opening portion 290 in a cross-sectional view is particularly used as the width DH. In other words, the minimum width of the opening portion 290 in the insulating layer 281 is used as the width DH of the opening portion 290. Here, the cross-sectional view refers to a cross section seen from the X direction or the Y direction of a region including the center (or the center of gravity) of the opening portion 290 seen from the Z direction. The width of the opening portion 290 at the highest position, the width of the opening portion 290 at the lowest position, or the width of the opening portion 290 at the midpoint therebetween in the insulating layer 281, or the average value of these three widths may be used as the width DH.

Although an example in which the width DH is determined by the width of the opening portion 290 in the insulating layer 281 is described here, there is no particular limitation on the method for determining the width DH. For example, in the cross-sectional view, the shortest distance between the two side surfaces of the conductive layer 255 on the opening portion 290 side or the shortest distance between the two side surfaces of the insulating layer 281 on the opening portion 290 side can be used as the width DH. For example, the shortest distance between the inner side surface (on the opening portion 290 side in the plan view) of the conductive layer 240a and the inner side surface (on the opening portion 290 side in the plan view) of the conductive layer 240b in the cross-sectional view may be used as the width DH.

The width DH of the opening portion 290 is determined by the thicknesses of the insulating layer 225, the oxide semiconductor layer 230a, the insulating layer 250, and the conductive layer 260 provided in the opening portion 290. The width DH of the opening portion 290 is preferably, for example, greater than or equal to 5 nm, greater than or equal to 10 nm, or greater than or equal to 20 nm and less than or equal to 300 nm, less than or equal to 200 nm, less than or equal to 100 nm, less than or equal to 60 nm, less than or equal to 50 nm, less than or equal to 40 nm, or less than or equal to 30 nm.

Note that the width DH of the opening portion 290 is larger than the distance Hab. Specifically, the width DH of the opening portion 290 is preferably larger than the sum of twice the thickness of the insulating layer 225 and the distance Hab. In this manner, the oxide semiconductor layer 230a and the oxide semiconductor layer 230b (also collectively referred to as an oxide semiconductor layer 230) can be provided in the opening portion 290. Here, the thickness of the insulating layer 225 refers to the width in the X direction of at least part of the insulating layer 225 in the example illustrated in FIG. 5A. Furthermore, the width DH of the opening portion 290 is preferably larger than the sum of twice the thickness of the insulating layer 225, twice the thickness of the oxide semiconductor layer 230a or 230b, and the distance Hab. This can inhibit a reduction in the thickness (i.e., decreased film thickness) of the oxide semiconductor layer 230 and can thus inhibit a reduction in the area of the channel formation region in the plan view. Here, for example, the thickness of the oxide semiconductor layer 230 refers to the width in the X direction of at least part of the oxide semiconductor layer 230 positioned in the opening portion 290 in the example illustrated in FIG. 5A.

Furthermore, a small distance Hab is preferable. When the distance Hab is shortened, the channel width W can be increased. Moreover, the semiconductor device can be miniaturized or highly integrated. For example, the distance Hab is preferably greater than or equal to 10 nm and less than or equal to 60 nm, further preferably greater than or equal to 10 nm and less than or equal to 50 nm, still further preferably greater than or equal to 10 nm and less than or equal to 40 nm, yet still further preferably greater than or equal to 10 nm and less than or equal to 30 nm. The distance Hab is, for example, preferably greater than or equal to 5 nm and less than or equal to 50 nm, further preferably greater than or equal to 5 nm and less than or equal to 40 nm, still further preferably greater than or equal to 5 nm and less than or equal to 30 nm.

The channel length of each of the transistors 200a and 200b corresponds to the distance between the source region and the drain region. For example, in the case where the conductive layer 255 functions as the first gate electrode, the channel length of each of the transistor 200a and the transistor 200b is the length of a region of each of the oxide semiconductor layer 230a and the oxide semiconductor layer 230b that faces the conductive layer 255 with the insulating layer 225 therebetween in the cross-sectional view. In other words, the channel lengths of the transistor 200a and the transistor 200b are determined by the thickness of the conductive layer 255. In the case where the conductive layer 260 and the conductive layer 255 are connected to each other, the channel lengths of the transistor 200a and the transistor 200b are the lengths of regions interposed between the conductive layer 260 and the conductive layer 255 in the oxide semiconductor layer 230a and the oxide semiconductor layer 230b in the cross-sectional view. In other words, the channel lengths of the transistor 200a and the transistor 200b are determined by the thickness of the conductive layer 255. In FIG. 5A, the channel length L of the transistor 200a is indicated by a dashed-dotted double-headed arrow.

In the case where the conductive layer 260 functions as the first gate electrode, the channel length of the transistor 200a can be determined by the thickness of the insulating layer 280 over the conductive layer 220a, the thickness of the conductive layer 255, the thickness of the insulating layer 281, the thickness of the conductive layer 240a, and the like in the cross-sectional view. Similarly, the channel length of the transistor 200b can be determined by the thickness of the insulating layer 280 over the conductive layer 220b, the thickness of the conductive layer 255, the thickness of the insulating layer 281, the thickness of the conductive layer 240b, and the like in the cross-sectional view.

Further miniaturization of a planar transistor is difficult since the channel length of the planar transistor is restricted by the light exposure limit of photolithography; however, the channel lengths of the transistor 200a and the transistor 200b can be determined by the thickness or the like of the conductive layer 255. Thus, the transistor 200a and the transistor 200b can each have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200a and the transistor 200b can have higher on-state current and higher frequency characteristics.

Note that the channel length of each of the transistor 200a and the transistor 200b is determined by the thickness or the like of the conductive layer 255; thus, the channel length does not affect the area occupied by the transistor 200a and the transistor 200b, for example, the area occupied by the transistor 200a and the transistor 200b in the plan view. When the channel lengths of the transistor 200a and the transistor 200b are, for example, less than or equal to 1 μm, less than or equal to 500 nm, or less than or equal to 300 nm, the productivity, yield, and the like in the formation of the opening portion 290 and the like can be increased.

From the above, the channel length of the transistor included in the semiconductor device of one embodiment of the present invention is preferably greater than or equal to 0.1 nm, greater than or equal to 1 nm, or greater than or equal to 5 nm, and less than or equal to 1 μm, less than or equal to 500 nm, or less than or equal to 300 nm.

The channel length L of the transistor 200 is preferably shorter than at least the channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables the transistor to have favorable electrical characteristics and high reliability.

In addition, the channel width W of the transistor 200 may be less than or equal to the channel length L of the transistor 200. This structure enables miniaturization or high integration of the semiconductor device.

As described above, when the opening portion 290 is formed to be circular in the plan view, the insulating layer 225 in the opening portion 290 has a ring shape or an annular shape in the plan view. Specifically, the insulating layer 225 includes an annular portion having an opening portion that is concentric with the opening portion 290. The oxide semiconductor layer 230a and the oxide semiconductor layer 230b are provided to be arc-shaped. Furthermore, the insulating layer 250 and the conductive layer 260 are provided along the shapes of the insulating layer 225, the oxide semiconductor layer 230a, and the oxide semiconductor layer 230b. This makes each of the distance between the conductive layer 255 and the oxide semiconductor layer 230a and the distance between the conductive layer 260 and the oxide semiconductor layer 230a substantially uniform, so that a gate electric field can be substantially uniformly applied to the oxide semiconductor layer 230a. Similarly, this makes each of the distance between the conductive layer 255 and the oxide semiconductor layer 230b and the distance between the conductive layer 260 and the oxide semiconductor layer 230b substantially uniform, so that a gate electric field can be substantially uniformly applied to the oxide semiconductor layer 230b.

Although this embodiment describes the example where the conductive layer 115a, the conductive layer 115b, and the opening portion 290 each have a circular shape in the plan view, the present invention is not limited to the example. The conductive layer 115a, the conductive layer 115b, and the opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape having at least one interior angle greater than 180°) or a convex polygonal shape (a polygonal shape having all the interior angles less than or equal to 180°).

The conductive layer 240a and the conductive layer 240b can each have a stacked-layer structure of two or more layers. FIG. 5A illustrates an example where the conductive layer 240a has a two-layer structure of a conductive layer 240a1 and a conductive layer 240a2 over the conductive layer 240al. Similarly, in the example, the conductive layer 240b has a two-layer structure of a conductive layer 240b1 and a conductive layer 240b2 over the conductive layer 240b1.

The conductive layer 220a and the conductive layer 220b can each have a stacked-layer structure of two or more layers. FIG. 5A illustrates an example where the conductive layer 220a has a two-layer structure of a conductive layer 220a1 and a conductive layer 220a2 over the conductive layer 220al. Similarly, in the example, the conductive layer 220b has a two-layer structure of a conductive layer 220b1 and a conductive layer 220b2 over the conductive layer 220b1.

In the example illustrated in FIG. 5A, the top surface of the conductive layer 220a includes a depressed portion 221a and the top surface of the conductive layer 220b includes a depressed portion 221b. Specifically, the top surface of the conductive layer 220a2 includes the depressed portion 221a and the top surface of the conductive layer 220b2 includes the depressed portion 221b. Hereinafter, the depressed portion 221a and the depressed portion 221b may be collectively referred to as a depressed portion 221.

The depressed portion 221a and the depressed portion 221b are provided at positions overlapping with the opening portion 290. In the case where the conductive layer 220a has a two-layer structure of the conductive layer 220a1 and the conductive layer 220a2, the bottom surface of the depressed portion 221a corresponds to the bottom surface of the depressed portion of the conductive layer 220a2, and the side surface of the depressed portion 221a corresponds to the side surface of the depressed portion of the conductive layer 220a2. Similarly, the bottom surface of the depressed portion 221b corresponds to the bottom surface of the depressed portion of the conductive layer 220b2, and the side surface of the depressed portion 221b corresponds to the side surface of the depressed portion of the conductive layer 220b2. The bottom portion of the opening portion 290 includes the bottom surface of the depressed portion 221a and the bottom surface of the depressed portion 221b. The sidewall of the opening portion 290 can be regarded as including the side surface of the depressed portion 221a, the side surface of the depressed portion 221b, the side surface of the insulating layer 280, the side surface of the conductive layer 255, and the side surface of the insulating layer 281. Note that the depressed portion 221a and the depressed portion 221b may be regarded as being included in the opening portion 290.

When each conductive layer 220 (the conductive layers 220a and 220b) includes the depressed portion 221 at the position overlapping with the opening portion 290, the heights of the undersurfaces of the insulating layer 250 and the conductive layer 260 in the opening portion 290 can be made lower than the height of the top surface of the conductive layer 220 which is in contact with the insulating layer 280, as compared with the case where the depressed portion 221 is not provided. Here, the heights of the surfaces can be determined with a surface where a transistor is formed (formation surface of a transistor) used as a reference plane. Here, the top surface of the insulating layer 188 in a region overlapping with the conductive layer 220 is used as a reference plane. The reference plane is not limited to a surface where a transistor is formed. For example, the top surface of a substrate where a transistor or a semiconductor device is provided may be used as the reference plane.

When the height of the bottom surface of the conductive layer 260 is lowered, a gate electric field is easily applied from the conductive layer 260 to the channel formation regions of the oxide semiconductor layers 230a and 230b. Accordingly, the transistors 200a and 200b can have favorable electrical characteristics. Furthermore, a gate electric field is also easily applied from the conductive layer 260 to a region of the oxide semiconductor layer 230a that is in contact with the conductive layer 220a2 and a region of the oxide semiconductor layer 230b that is in contact with the conductive layer 220b2. This can increase the on-state current of the transistor 200a and the transistor 200b. In both of the cases where the conductive layer 220a and the conductive layer 220b are used for the drain electrodes and where the conductive layer 240a and the conductive layer 240b are used for the drain electrodes, the transistor 200a and the transistor 200b can have favorable electrical characteristics.

In the case where the depressed portion 221 is provided in the conductive layer 220a2 and the conductive layer 220b2, a depressed portion 222 is provided in the insulating layer 188 at a position overlapping with the opening portion 290 in some cases, for example. In that case, the height of the bottom surface of the insulating layer 250 and the height of the bottom surface of the conductive layer 260 in the opening portion 290 can be further lowered.

In the case where the insulating layer 188 includes the depressed portion 222, part of the end portion of the oxide semiconductor layer 230a and part of the end portion of the oxide semiconductor layer 230b can be positioned in the depressed portion 222. Note that the depressed portion 222 may be included in the opening portion 290.

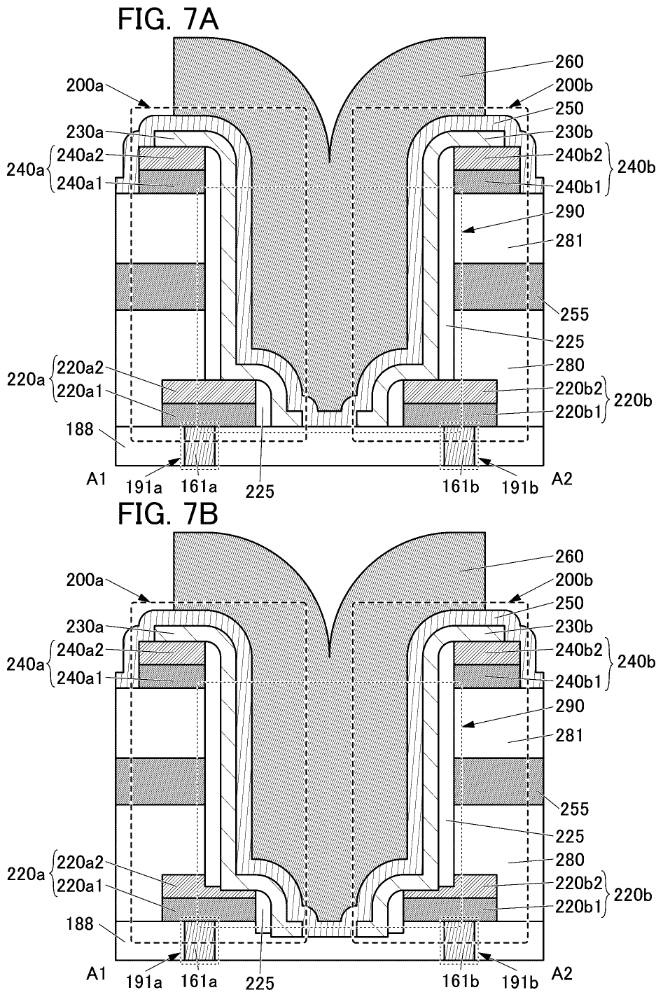

FIG. 7A illustrates an example in which the conductive layer 220a2, the conductive layer 220b2, and the insulating layer 188 illustrated in FIG. 5A have no depressed portions. In the example illustrated in FIG. 7A, the heights of the bottom surfaces of the oxide semiconductor layer 230a, the oxide semiconductor layer 230b, and the insulating layer 250 in the opening portion 290 can be the same as or substantially the same as the heights of the bottom surface of the conductive layer 220al and the bottom surface of the conductive layer 220b1. In the example illustrated in FIG. 7A, the height of the bottom surface of the insulating layer 225 can be the same as or substantially the same as the heights of the top surface of the conductive layer 220a2 and the top surface of the conductive layer 220b2.

FIG. 7B illustrates an example in which the conductive layer 220a2 and the conductive layer 220b2 illustrated in FIG. 5A each include a first depressed portion and a second depressed portion positioned outside the first depressed portion. FIG. 7B illustrates an example in which the first depressed portion has a larger depth than the second depressed portion. In other words, the bottom portion of the first depressed portion is positioned below (on the insulating layer 188 side of) the bottom portion of the second depressed portion. When the opening portion 290 is formed, the second depressed portion is provided in the conductive layer 220a2 and the conductive layer 220b2. After that, when the insulating film is formed and processed to form the insulating layer 225, the first depressed portion is provided in the conductive layer 220a2 and the conductive layer 220b2. Thus, in FIG. 7B, the sidewall of the second depressed portion is aligned with the side surface of the insulating layer 280 in the opening portion 290. A sidewall of the first depressed portion is aligned with a surface of the insulating layer 225 on the oxide semiconductor layer 230a side or the oxide semiconductor layer 230b side. Hereinafter, the first depressed portion and the second depressed portion are collectively referred to as a depressed portion in some cases.

In FIG. 7B, the insulating layer 225 is in contact with the bottom portions and the sidewalls of the depressed portions (specifically, the second depressed portions) of the conductive layer 220a and the conductive layer 220b, and is in contact with the side surfaces of the insulating layer 280, the conductive layer 255, the insulating layer 281, the conductive layer 240a, and the conductive layer 240b in the opening portion 290. The oxide semiconductor layer 230a is in contact with the bottom portion and the sidewall of the depressed portion (specifically, the first depressed portion) of the conductive layer 220a and the side surface of the insulating layer 225 in the opening portion 290. Similarly, the oxide semiconductor layer 230b is in contact with the bottom portion and the sidewall of the depressed portion (specifically, the first depressed portion) of the conductive layer 220b and the side surface of the insulating layer 225 in the opening portion 290. The insulating layer 250 is positioned inside the oxide semiconductor layer 230a and the oxide semiconductor layer 230b in the opening portion 290. The conductive layer 260 is positioned inside the insulating layer 250 in the opening portion 290.

When the conductive layer 220a2 includes the first depressed portion and the second depressed portion, the side surface of the conductive layer 220a2 is in contact with the oxide semiconductor layer 230a. Accordingly, the contact area between the conductive layer 220a2 and the oxide semiconductor layer 230a can be increased, so that the contact resistance between the conductive layer 220a2 and the oxide semiconductor layer 230a can be lowered. Thus, the on-state current of the transistor 200a can be increased. Similarly, when the conductive layer 220b2 includes the first depressed portion and the second depressed portion, the on-state current of the transistor 200b can be increased.

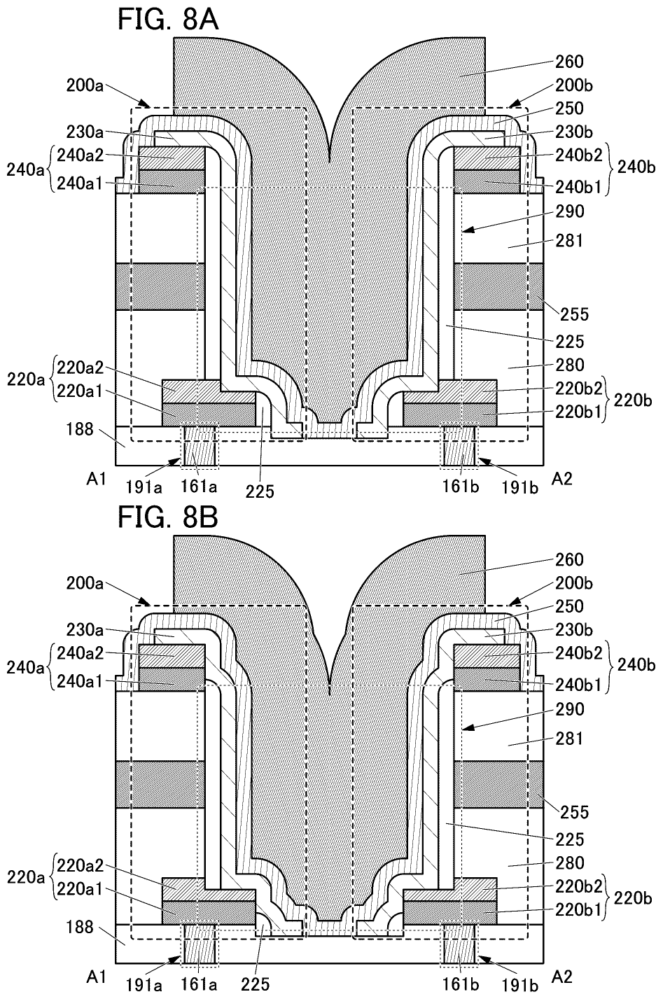

Although FIG. 7B illustrates the structure in which the conductive layer 220a2 includes the first depressed portion and the second depressed portion, the present invention is not limited to the structure. FIG. 8A illustrates an example in which only the second depressed portion is provided in the conductive layer 220a2 illustrated in FIG. 7B. In other words, the conductive layer 220a2 and the conductive layer 220b2 may have no depressed portion in a region overlapping with the insulating layer 225.

In the conductive layer 220a2 and the conductive layer 220b2, a depressed portion may be formed in one or both of a step of forming the opening portion 290 and a step of forming the insulating layer 225. In the example of the semiconductor device illustrated in FIG. 7B, depressed portions are formed in the conductive layer 220a2 and the conductive layer 220b2 in both of the steps. Meanwhile, FIG. 8A illustrates an example of the semiconductor device in which a depressed portion is not formed in the conductive layer 220a2 and the conductive layer 220b2 in the step of forming the opening portion 290, and a depressed portion is formed in the conductive layer 220a2 and the conductive layer 220b2 in the step of forming the insulating layer 225.

In the example illustrated in FIG. 8A, the insulating layer 225 is in contact with the side surface of the insulating layer 280, the side surface of the conductive layer 255, the side surface of the insulating layer 281, the side surface of the conductive layer 240a, the side surface of the conductive layer 240b, the top surface of the conductive layer 220a2, and the top surface of the conductive layer 220b2 in the opening portion 290. The oxide semiconductor layer 230a is in contact with the bottom portion and the sidewall of the depressed portion in the conductive layer 220a2 and the side surface of the insulating layer 225 in the opening portion 290. Similarly, the oxide semiconductor layer 230b is in contact with the bottom portion and the sidewall of the depressed portion of the conductive layer 220b2 and the side surface of the insulating layer 225 in the opening portion 290.

When the depressed portion is formed in the conductive layer 220a2 in the step of forming the insulating layer 225, the oxide semiconductor layer 230a can be in contact with the bottom portion and the sidewall of the depressed portion of the conductive layer 220a2. This is preferable because the contact area between the oxide semiconductor layer 230a and the conductive layer 220a2 is increased and the contact resistance between the oxide semiconductor layer 230a and the conductive layer 220a2 can be reduced. Similarly, when the depressed portion is formed in the conductive layer 220b2 in the step of forming the insulating layer 225, the contact resistance between the oxide semiconductor layer 230b and the conductive layer 220b2 can be lowered, which is preferable.

FIG. 8B illustrates an example in which the side surface of the conductive layer 240a2 and the side surface of the conductive layer 240b2 are not covered with the insulating layer 225. In the example illustrated in FIG. 8B, the side surface of the conductive layer 220a2 and the side surface of the conductive layer 220b2 are not covered with the insulating layer 225.

The insulating layer 225 illustrated in FIG. 8B can be in contact with at least part of the side surface of the conductive layer 240a1 and at least part of the side surface of the conductive layer 240b1. The insulating layer 225 illustrated in FIG. 8B can be in contact with at least part of the side surface of the conductive layer 220a1 and at least part of the side surface of the conductive layer 220b1. Here, the insulating layer 225 is in contact with neither the side surface on the opening portion 290 side of the conductive layer 240a2 nor the side surface on the opening portion 290 side of the conductive layer 240b2. The insulating layer 225 is in contact with neither the side surface of the conductive layer 220a2 nor the side surface of the conductive layer 220b2. Note that the insulating layer 225 may be in contact with at least parts of the side surface of the conductive layer 240a2 and the side surface of the conductive layer 240b2. The insulating layer 225 may be in contact with at least parts of the side surface of the conductive layer 220a2 and the side surface of the conductive layer 220b2.

In the case where the conductive layer 260 functions as the first gate electrode, the channel lengths of the transistor 200a and the transistor 200b can be shortened with the structure illustrated in FIG. 8B. Accordingly, the transistor can have a high on-state current.

In the case where the side surface on the opening portion 290 side of the conductive layer 240a2 includes a portion not covered with the insulating layer 225, the portion is in contact with the oxide semiconductor layer 230a. Similarly, in the case where the side surface on the opening portion 290 side of the conductive layer 240b2 includes a portion not covered with the insulating layer 225, the portion is in contact with the oxide semiconductor layer 230b. In this way, the contact area between the oxide semiconductor layer 230a and the conductive layer 240a2 and the contact area between the oxide semiconductor layer 230b and the conductive layer 240b2 can be increased. Thus, the contact resistance between the oxide semiconductor layer 230a and the conductive layer 240a and the contact resistance between the oxide semiconductor layer 230b and the conductive layer 240b can be lowered.

Furthermore, in the case where at least part of the side surface of the conductive layer 240al is not covered with the insulating layer 225, a portion of the conductive layer 240a1 that is not covered with the insulating layer 225 is in contact with the oxide semiconductor layer 230a. Similarly, in the case where at least part of the side surface of the conductive layer 240b1 is not covered with the insulating layer 225, a portion of the conductive layer 240b1 that is not covered with the insulating layer 225 is in contact with the oxide semiconductor layer 230b. In this manner, the contact area between the oxide semiconductor layer 230a and the conductive layer 240a and the contact area between the oxide semiconductor layer 230b and the conductive layer 240b can be increased. Thus, the contact resistance between the oxide semiconductor layer 230a and the conductive layer 240a and the contact resistance between the oxide semiconductor layer 230b and the conductive layer 240b can be lowered.

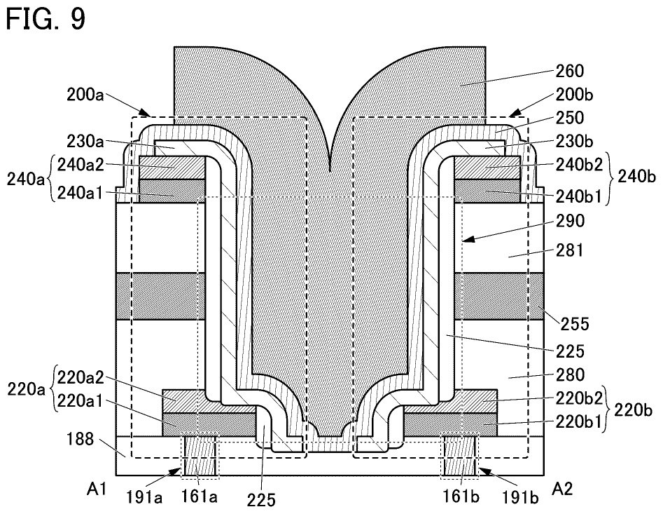

FIG. 9 is a diagram illustrating an example in which the depressed portion in the conductive layer 220a2 and the depressed portion in the conductive layer 220b2 illustrated in FIG. 7B each include a curved portion. Specifically, in the example illustrated in FIG. 9, the first depressed portion and the second depressed portion each include a curved portion.

When the depressed portion of the conductive layer 220a2 and the depressed portion of the conductive layer 220b2 each have a curved portion, portions of the oxide semiconductor layer 230a, the oxide semiconductor layer 230b, the insulating layer 250, and the like that are provided over the depressed portions and in the vicinities of the depressed portions each have a curved portion in some cases. In other words, the portions each have a curved surface or a concave surface in the cross-sectional view in some cases. In addition, the portions may each have no corner portion in the cross-sectional view in some cases. Accordingly, the concentration of electric field in the insulating layer 250 in the vicinity of the depressed portions is relieved, and the withstand voltages of the transistor 200a and the transistor 200b can be increased, so that the electrostatic breakdown of the transistor 200a and the transistor 200b can be inhibited. Accordingly, the reliability of the semiconductor device can be improved.

### <Component Materials of Semiconductor Device>

Materials that can be used for the semiconductor device of this embodiment are described below. Note that the layers included in the semiconductor device of this embodiment may each have a single-layer structure or a stacked-layer structure. Hereinafter, the oxide semiconductor layer 230a and the oxide semiconductor layer 230b are collectively referred to as the oxide semiconductor layer 230 in some cases. The conductive layer 120a and the conductive layer 120b are collectively referred to as a conductive layer 120 in some cases. The conductive layer 161a and the conductive layer 161b are collectively referred to as a conductive layer 161 in some cases. The conductive layers 220a and the conductive layer 220b are collectively referred to as the conductive layer 220 in some cases. Furthermore, the conductive layer 240a and the conductive layer 240b are collectively referred to a conductive layer 240 in some cases.

### [Oxide Semiconductor Layer]

As described above, the oxide semiconductor layer 230 includes the channel formation region. The oxide semiconductor layer 230 further includes the source region and the drain region. The source region and the drain region are low-resistance regions having a higher carrier concentration than the channel formation region. The oxide semiconductor layer 230 may have a single-layer structure or a stacked-layer structure of two or more layers.

There is no particular limitation on the crystallinity of the semiconductor material used for the oxide semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

In the transistor 200, the oxide semiconductor layer 230 including the channel formation region preferably includes a metal oxide (also referred to as an oxide semiconductor) functioning as a semiconductor. In the case where a metal oxide functioning as a semiconductor is used for the oxide semiconductor layer 230, the transistor 200 can be regarded as an OS transistor.

When oxygen vacancies (Vo) and impurities are in the channel formation region of the oxide semiconductor in an OS transistor, electrical characteristics of the OS transistor easily vary and the reliability thereof may worsen in some cases. A defect that is an oxygen vacancy into which hydrogen enters (hereinafter also referred to as V_{O}H in some cases) is formed and an electron serving as a carrier is generated in some cases. Thus, when the channel formation region of the oxide semiconductor includes oxygen vacancies, the OS transistor tends to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

Meanwhile, preferably, the source region and the drain region of the OS transistor include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the OS transistor are preferably regions having higher carrier concentrations and lower resistances than the channel formation region.

The band gap of the metal oxide functioning as a semiconductor is preferably greater than or equal to 2.0 eV, further preferably greater than or equal to 2.5 eV. The use of a metal oxide having a wide band gap for the oxide semiconductor layer 230 can reduce the off-state current of the transistor 200. The off-state current of the OS transistor is small, so that power consumption of the semiconductor device can be sufficiently reduced. The OS transistor has high frequency characteristics, which enables the semiconductor device to operate at high speed.

For the oxide semiconductor layer that can be used as the semiconductor layer of the transistor of one embodiment of the present invention, description in Embodiment 2 can be referred to. Here, detailed description thereof is omitted.

Note that for the semiconductor device of this embodiment, a transistor including a different semiconductor material in its channel formation region may be used. Examples of the different semiconductor material include a single-element semiconductor and a compound semiconductor.

Examples of the single-element semiconductor that can be used as the semiconductor material include silicon and germanium. Examples of silicon that can be used as the semiconductor material include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure. Other examples of the compound semiconductor include an organic semiconductor and a nitride semiconductor. In addition, the oxide semiconductor as mentioned above is also one kind of the compound semiconductor. These semiconductor materials may contain an impurity as a dopant.

The semiconductor device of this embodiment may include a transistor containing a layered material functioning as a semiconductor in a channel formation region. Note that the details of the layered material will be described in Embodiment 6.

### [Insulating Layer]

An inorganic insulating film is preferably used for each of the insulating layers (the insulating layer 180, the insulating layer 111, the insulating layer 163, the insulating layer 164, the insulating layer 121, the insulating layer 187, the insulating layer 188, the insulating layer 280, the insulating layer 281, the insulating layer 250, the insulating layer 225, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

With miniaturization and high integration of a transistor, for example, a problem such as generation of a leakage current may arise because of a thin gate insulating layer. When a material with a high relative permittivity (a high-k material) is used for the gate insulating layer, the voltage at the time of operation of the transistor can be reduced while the physical thickness is maintained. Furthermore, the equivalent oxide thickness (EOT) of the gate insulating layer can be reduced. By contrast, when a material with a low relative permittivity is used for the insulating layer functioning as an interlayer film, the parasitic capacitance generated between wirings can be reduced. Thus, a material is preferably selected depending on the function of an insulating layer. In addition, a material with a low relative permittivity is a material with high dielectric strength.

Examples of the material with a high relative permittivity include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of the inorganic insulating material with a low relative permittivity include silicon oxide containing fluorine, silicon oxide containing carbon, and silicon oxide containing carbon and nitrogen. Another example is porous silicon oxide. Note that these silicon oxides can contain nitrogen.

A material that can have ferroelectricity may be used for the insulating layer included in the semiconductor device. Examples of the material that can have ferroelectricity include metal oxides such as hafnium oxide, zirconium oxide, and hafnium zirconium oxide. Examples of the material that can have ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include the above metal nitride to which an element M3 is added. The element M3 is one or more of magnesium, calcium, strontium, zinc, cadmium, and the like. Here, the atomic ratio between the element M1, the element M2, and the element M3 can be set as appropriate.

Examples of the material that can have ferroelectricity also include perovskite-type oxynitrides such as SrTaO₂N and BaTaO₂N, and GaFeO₃ with a κ-alumina-type structure.

The metal oxides and metal nitrides described above are non-limiting examples. For example, a metal oxynitride in which nitrogen is added to any of the above metal oxides, a metal nitride oxide in which oxygen is added to any of the above metal nitrides, or the like may be used.

As the material that can have ferroelectricity, a mixture or a compound each containing a plurality of materials selected from the above-listed materials can be used, for example. Alternatively, the insulating layer 121 to be described in Embodiment 3 can have a stacked-layer structure of a plurality of materials selected from the above-listed materials. Incidentally, since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

A metal oxide containing one or both of hafnium and zirconium can have ferroelectricity even when being a thin film of several nanometers. A metal oxide containing one or both of hafnium and zirconium can have ferroelectricity even when having a minute area. Accordingly, the use of a metal oxide containing one or both of hafnium and zirconium enables miniaturization of the semiconductor device. Examples of the metal oxide containing one or both of hafnium and zirconium include hafnium oxide, zirconium oxide, and hafnium zirconium oxide. Typical examples of the hafnium zirconium oxide include HfZrO_{X} (X is a real number greater than 0). A metal oxide obtained by adding Y (yttrium) to HfZrO_{X} (X is a real number greater than 0) can also be used. By adding Y (yttrium) to HfZrO_{X} (X is a real number greater than 0), the ferroelectricity can be increased.

As described later, the metal oxide containing one or both of hafnium and zirconium can also be a material of an insulating layer having a function of capturing or fixing hydrogen. Thus, when a metal oxide containing one or both of hafnium and zirconium is used for at least part of the gate insulating layer, hydrogen contained in the oxide semiconductor layer can be captured or fixed, so that the hydrogen concentration in the oxide semiconductor layer can be reduced. Furthermore, the transistor including the gate insulating layer can function as a ferroelectric field effect transistor (FeFET).

Note that in this specification and the like, the material that can have ferroelectricity processed into a layered shape is referred to as a ferroelectric layer, a metal oxide film, or a metal nitride film in some cases. Furthermore, a device including such a ferroelectric layer, a metal oxide film, or a metal nitride film is sometimes referred to as a ferroelectric device in this specification and the like.

It is said that ferroelectricity is exhibited by displacement of oxygen or nitrogen of a crystal included in a ferroelectric layer due to an external electric field. Ferroelectricity is presumably exhibited depending on the crystal structure of a crystal included in a ferroelectric layer. Thus, in order that the insulating layer can exhibit ferroelectricity, the insulating layer 121 needs to include a crystal. In particular, the insulating layer preferably includes a crystal having an orthorhombic crystal structure, in which case ferroelectricity is exhibited. A crystal included in the insulating layer may have one or more of crystal structures selected from tetragonal, orthorhombic, monoclinic, and hexagonal crystal structures. Alternatively, the insulating layer may have an amorphous structure. In that case, the insulating layer may have a composite structure including an amorphous structure and a crystal structure.

Addition of a Group 3 element in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

Any of the materials with a high relative permittivity is preferably used for the insulating layer 121. Using such a material with a high relative permittivity for the insulating layer 121 allows the insulating layer 121 to be thick enough to inhibit a leakage current and the capacitor 100 to have a sufficiently high capacitance.

It is preferable to use stacked insulating layers each including such a material with a high relative permittivity for the insulating layer 121. A stacked-layer structure using a material with a high relative permittivity and a material having higher dielectric strength than the material with a high relative permittivity is preferably used. For example, as the insulating layer 121, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulating layer having relatively high dielectric strength, such as aluminum oxide, can increase the dielectric strength and inhibit electrostatic breakdown of the capacitor 100.

Moreover, any of the above-described materials that can have ferroelectricity may be used for the insulating layer 121.

A metal oxide containing one or both of hafnium and zirconium is preferable as the insulating layer 121 because the metal oxide can have ferroelectricity even when being a thin film of several nanometers as described above. The thickness of the insulating layer 121 is preferably less than or equal to 100 nm, further preferably less than or equal to 50 nm, still further preferably less than or equal to 20 nm, yet still further preferably less than or equal to 10 nm (typically greater than or equal to 2 nm and less than or equal to 9 nm). For example, the thickness of the insulating layer 121 is preferably greater than or equal to 8 nm and less than or equal to 12 nm. With the use of the ferroelectric layer that can have a small thickness, the capacitor 100 can be combined with a miniaturized semiconductor element such as a transistor to constitute part of a semiconductor device.

A metal oxide containing one or both of hafnium and zirconium is preferable as the insulating layer 121 because the metal oxide can have ferroelectricity even with a minute area. For example, the metal oxide can exhibit ferroelectricity even with an area (occupied area) of a ferroelectric layer of less than or equal to 100 μm², less than or equal to 10 μm², less than or equal to 1 μm², or less than or equal to 0.1 μm² in a plan view. Furthermore, even with an area of less than or equal to 10000 nm² or less than or equal to 1000 nm², the metal oxide can have ferroelectricity in some cases. With a small-area ferroelectric layer, the area occupied by the capacitor 100 can be reduced.

The ferroelectric refers to an insulator having properties of causing internal polarization by application of an electric field from the outside and maintaining the polarization even after the electric field is made zero. Thus, with the use of a capacitor that includes this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is connected to one terminal of the ferroelectric capacitor. Thus, in the case of using a ferroelectric capacitor as the capacitor 100, the semiconductor device described in this embodiment functions as a ferroelectric memory.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide, a metal nitride such as aluminum nitride or silicon nitride, a metal nitride oxide such as silicon nitride oxide can be used.

Specific examples of the material for the insulating layer having a function of inhibiting passage of oxygen and impurities such as water and hydrogen include a metal oxide such as aluminum oxide, magnesium oxide, gallium oxide, germanium oxide, yttrium oxide, zirconium oxide, lanthanum oxide, neodymium oxide, hafnium oxide, tantalum oxide, and an oxide containing aluminum and hafnium (hafnium aluminate). Furthermore, nitrides such as aluminum nitride, aluminum titanium nitride, and silicon nitride can be given, for example. Moreover, a nitride oxide such as silicon nitride oxide can be given.

An insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, oxygen vacancies in the oxide semiconductor layer can be reduced. Examples of a material for an insulating layer in which a region containing excess oxygen is easily formed include silicon oxide, silicon oxynitride, and porous silicon oxide.

As the insulating layer in contact with the oxide semiconductor layer or the insulating layer provided in the vicinity of the oxide semiconductor layer, a hydrogen-barrier insulating layer is preferably used. When the insulating layer has a barrier property against hydrogen, diffusion of hydrogen into the oxide semiconductor layer can be inhibited.

Examples of a material for an insulating layer having a function of capturing or fixing hydrogen include metal oxides such as an oxide containing hafnium, an oxide containing magnesium, an oxide containing aluminum, an oxide containing aluminum and hafnium (hafnium aluminate), and an oxide containing hafnium and silicon (hafnium silicate). Furthermore, these metal oxides may further contain zirconium, and an example of such a metal oxide is an oxide containing hafnium and zirconium.

The insulating layer having a function of capturing or fixing hydrogen preferably has an amorphous structure. In a metal oxide having an amorphous structure, some oxygen atoms have a dangling bond, which allows the metal oxide to have a high property of capturing or fixing hydrogen. Thus, when the insulating layer has an amorphous structure, the function of capturing or fixing hydrogen can be enhanced. For example, the amorphous structure of the metal oxide may be achieved by addition of silicon. For example, an oxide containing hafnium and silicon (hafnium silicate) is preferably used.

When the insulating layer has an amorphous structure, formation of a crystal grain boundary can be inhibited. Inhibiting formation of a crystal grain boundary can increase the planarity of the insulating layer. This enables the insulating layer to have uniform thickness distribution and the number of extremely thin portions to be reduced, so that the withstand voltage of the insulating layer can be increased. In addition, the thickness distribution of the film provided over the insulating layer can be uniform. Furthermore, inhibiting formation of a crystal grain boundary in the insulating layer can reduce a leakage current due to the defect states in the crystal grain boundary. Thus, the insulating layer can function as an insulating film with a low leakage current.

In addition, the insulating layer may partly include one or both of a crystal region and a crystal grain boundary.

A function of capturing or fixing a target substance can also be referred to as a property that does not easily allow diffusion of a target substance. Thus, a function of capturing or fixing a target substance can be rephrased as a barrier property.

In this specification and the like, a barrier insulating layer refers to an insulating layer having a barrier property. In addition, the barrier property refers to a property that does not easily allow diffusion of a target substance (also referred to as a property that does not easily allow passage of a target substance, a property with low permeability of a target substance, or a function of inhibiting diffusion of a target substance). In addition, hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

Examples of a material for a hydrogen-barrier insulating layer include aluminum oxide, magnesium oxide, hafnium oxide, gallium oxide, silicon nitride, and silicon nitride oxide.

Examples of a material for an oxygen-barrier insulating layer include an oxide containing one or both of aluminum and hafnium, magnesium oxide, gallium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The insulating layer 180, the insulating layer 111, the insulating layer 163, the insulating layer 164, the insulating layer 187, and het insulating layer 188 each function as an interlayer film and thus is preferably formed using the above-described material with a low relative permittivity. In the case where a material with a low relative permittivity is used for an interlayer film, the parasitic capacitance generated between wirings can be reduced.

As the insulating layer 188, a hydrogen-barrier insulating layer is preferably used. When the insulating layer 188 provided below the oxide semiconductor layer 230 has a barrier property against hydrogen, diffusion of hydrogen into the oxide semiconductor layer 230 from below the transistor 200 can be inhibited. For example, a silicon nitride film is preferably used as the insulating layer 188.

The concentration of impurities such as hydrogen or water in the insulating layer 188 is preferably reduced. This can inhibit entry of impurities such as hydrogen or water into the channel formation region of the oxide semiconductor layer 230.

Providing the insulating layer 188 over the insulating layer 187 can widen the range of choices for the material of the insulating layer 187 that fills the region between the capacitors 100. For example, a material which allows deposition at a deposition rate higher than the deposition rate of the insulating layer 188 can be used for the insulating layer 187. For example, in the case where a silicon nitride film is used as the insulating layer 188, a silicon oxide film can be used as the insulating layer 187. Note that in the case where the insulating layer 188 is not provided, a silicon oxide film or a silicon nitride film may be used as the insulating layer 187, for example.

The insulating layer 280 functions as an interlayer film and thus is preferably formed using any of the above-described materials with a low relative permittivity. In the case where a material with a low relative permittivity is used for an interlayer film, the parasitic capacitance generated between wirings can be reduced. For example, silicon oxide or silicon oxynitride can be used for the insulating layer 280.

The concentrations of impurities such as hydrogen or water in the insulating layer 280 are preferably reduced. This can inhibit entry of impurities such as hydrogen or water into the channel formation region of the oxide semiconductor layer 230.

For example, the insulating layer including a region containing excess oxygen can be formed by a sputtering method in an oxygen-containing atmosphere. Since a molecule containing hydrogen is not used as a film formation gas in the sputtering method, the concentration of hydrogen in the insulating layer 280 can be reduced. When at least one layer in the insulating layer 280 is formed by a sputtering method in this manner, oxygen can be supplied from the insulating layer 280 to the channel formation region of the oxide semiconductor layer 230, so that oxygen vacancies and V_{O}H therein can be reduced.

In addition, since the thickness of the insulating layer 280 over the conductive layer 220a or the conductive layer 220b affects the channel length of the transistor 200, the thickness of the insulating layer 280 is set as appropriate depending on the design value of the channel length of the transistor 200.

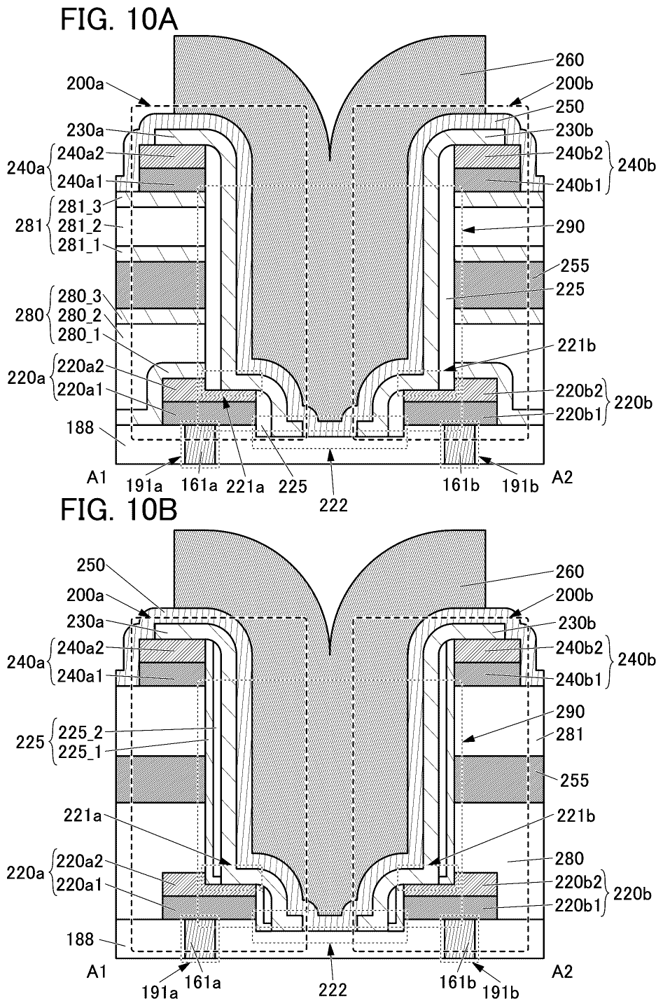

For example, FIG. 5A illustrates an example in which the insulating layer 280 has a single-layer structure. The insulating layer 280 can have a stacked-layer structure of two or more layers. FIG. 10A illustrates an example in which the insulating layer 280 illustrated in FIG. 5A has a three-layer structure of an insulating layer 280_1, an insulating layer 280_2 over the insulating layer 280_1, and an insulating layer 280_3 over the insulating layer 280_2. In this case, it is preferable that the above-described material with a low relative permittivity be used as the insulating layer 280_2 and oxygen-barrier insulating layers be used as the insulating layer 280_1 and the insulating layer 280_3. Thus, the conductive layer 220 and the conductive layer 255 can be inhibited from being oxidized and having an increased resistance.

For example, it is preferable that a silicon nitride film or an aluminum oxide film be used as each of the insulating layer 280_1 and the insulating layer 280_3 and a silicon oxide film be used as the insulating layer 280_2. Note that each of the insulating layer 280_1 and the insulating layer 280_3 may have a stacked-layer structure of two or more layers.

For the insulating layer 281, an insulating material usable for the insulating layer 280 can be used. Incidentally, the insulating layer 187 may have a structure similar to the structure applicable to the insulating layer 280.

For example, FIG. 5A illustrates an example in which the insulating layer 281 has a single-layer structure. The insulating layer 281 can have a stacked-layer structure of two or more layers. For example, as illustrated in FIG. 10A, the insulating layer 281 can have a three-layer structure of an insulating layer 281_1, an insulating layer 281_2 over the insulating layer 281_1, and an insulating layer 281_3 over the insulating layer 281_2. In this case, it is preferable that any of the above-described materials with a low relative permittivity be used as the insulating layer 281_2 and oxygen-barrier insulating layers be used as the insulating layer 281_1 and the insulating layer 281_3. Thus, the conductive layer 255 and the conductive layer 240 can be inhibited from being oxidized and having an increased resistance.

For example, it is preferable that a silicon nitride film or an aluminum oxide film be used as each of the insulating layers 281_1 and 281_3 and a silicon oxide film be used as the insulating layer 281_2. Each of the insulating layer 281_1 and the insulating layer 281_3 may have a stacked-layer structure of two or more layers.

As the insulating layer 250, a hydrogen-barrier insulating layer is preferably used. When the insulating layer 250 provided over the oxide semiconductor layer 230 has a barrier property against hydrogen, diffusion of hydrogen contained in the conductive layer 260 into the oxide semiconductor layer 230 can be inhibited. For example, a silicon nitride film is suitable as the insulating layer 250 because of its high barrier property against hydrogen.

Since the insulating layer 250 is in contact with the oxide semiconductor layer 230, an insulating layer having a function of capturing or fixing hydrogen is preferably used as the insulating layer 250. In this case, hydrogen contained in the oxide semiconductor layer 230 can be captured or fixed more effectively. Thus, the hydrogen concentration in the oxide semiconductor layer 230 (in particular, the hydrogen concentration in the channel formation region of the transistor) can be reduced. Accordingly, V_{O}H in the channel formation region can be reduced, so that the channel formation region can be an i-type or substantially i-type region.

As the insulating layer 250, an insulating layer including a region containing excess oxygen is preferably used. Accordingly, oxygen can be supplied from the insulating layer 250 to the oxide semiconductor layer 230, so that oxygen vacancies in the oxide semiconductor layer 230 can be reduced. A silicon oxide film, a silicon oxynitride film, or the like has a thermally stable structure and thus is suitable for the insulating layer 250.

FIG. 5A illustrates an example where the insulating layer 250 has a single-layer structure. In addition, the insulating layer 250 may have a stacked-layer structure of two or more layers. In that case, the insulating layer 250 is preferably formed of two or more kinds of films. When the insulating layer 250 is formed of two or more kinds of films, the insulating layer 250 can have a plurality of functions. Examples of the functions of the insulating layer 250 include a function of extracting hydrogen from the oxide semiconductor layer 230 and a function of inhibiting diffusion of hydrogen into the oxide semiconductor layer 230.

For example, the insulating layer 250 can have a two-layer structure of a first insulating layer and a second insulating layer over the first insulating layer. In this case, the first insulating layer is in contact with the oxide semiconductor layer 230. For example, an insulating layer having a function of capturing or fixing hydrogen is preferably used as the first insulating layer, and a hydrogen-barrier insulating layer is preferably used as the second insulating layer. With such a structure, the hydrogen concentration in the oxide semiconductor layer 230 can be reduced and diffusion of hydrogen into the oxide semiconductor layer 230 can be inhibited. Thus, the transistor can have high reliability. For example, a hafnium oxide film or a hafnium silicate film can be used as the first insulating layer, and a silicon nitride film can be used as the second insulating layer.

Alternatively, for example, an insulating layer including a region containing excess oxygen is preferably used as the first insulating layer, and a hydrogen-barrier insulating layer is preferably used as the second insulating layer. Alternatively, for example, an insulating layer including a region containing excess oxygen is preferably used as the first insulating layer, and an insulating layer having a function of capturing or fixing hydrogen is preferably used as the second insulating layer. With such a structure, the amount of oxygen vacancies and the hydrogen concentration in the oxide semiconductor layer 230 can be reduced, so that diffusion of hydrogen into the oxide semiconductor layer 230 can be inhibited. Thus, the transistor can have high reliability.

The insulating layer 250 can include a third insulating layer between the oxide semiconductor layer 230 and the first insulating layer, for example. In other words, the insulating layer 250 can have a three-layer structure of the third insulating layer, the first insulating layer over the third insulating layer, and the second insulating layer over the first insulating layer.

For example, an insulating layer including a region containing excess oxygen or an insulating layer containing a material with a low relative permittivity is preferably used as the third insulating layer, an insulating layer having a function of capturing or fixing hydrogen is preferably used as the first insulating layer, and an insulating layer having a barrier property against hydrogen and oxygen is preferably used as the second insulating layer. A silicon oxide film or a silicon oxynitride film is preferably used as the third insulating layer. When an oxide film is used as the third insulating layer in contact with the oxide semiconductor layer 230, oxygen can be supplied to the oxide semiconductor layer 230. Providing the second insulating layer can inhibit oxygen contained in the third insulating layer from diffusing into the conductive layer 260 and inhibit the conductive layer 260 from being oxidized. Furthermore, a reduction in the amount of oxygen supplied from the third insulating layer to the oxide semiconductor layer 230 can be inhibited.

The insulating layer 250 can include a fourth insulating layer between the oxide semiconductor layer 230 and the third insulating layer, for example. In other words, the insulating layer 250 can have a four-layer structure of the fourth insulating layer, the third insulating layer over the fourth insulating layer, the first insulating layer over the third insulating layer, and the second insulating layer over the first insulating layer.

As the fourth insulating layer, an insulating layer having a barrier property against oxygen is preferably used. Note that the first to third insulating layers can have a structure similar to that of the layers used in the above three-layer structure. The fourth insulating layer is in contact with the oxide semiconductor layer 230 and the conductive layer 240. When the fourth insulating layer has a barrier property against oxygen, release of oxygen from the oxide semiconductor layer 230 can be inhibited. This inhibits formation of an oxide film on the side surface of the conductive layer 240 due to oxidization of the side surface. It is thus possible to inhibit a reduction in the on-state current or field-effect mobility of the transistor 200.

As the fourth insulating layer, an aluminum oxide film is preferably used, for example. An aluminum oxide film has a function of capturing or fixing hydrogen, and thus is suitably used as the fourth insulating layer in contact with the oxide semiconductor layer 230. Specifically, the insulating layer 250 preferably has a four-layer structure where an aluminum oxide film, a silicon oxide film, a hafnium oxide film, and a silicon nitride film are stacked in this order from the oxide semiconductor layer 230 side.

The insulating layer 250 is preferably thin. For example, when the insulating layer 250 has a thickness greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in a subthreshold region when a drain voltage is constant and a drain current is changed by one order of magnitude.

The thickness of each layer included in the insulating layer 250 is preferably greater than or equal to 0.1 nm and less than or equal to 10 nm, further preferably greater than or equal to 0.1 nm and less than or equal to 5 nm, further preferably greater than or equal to 0.5 nm and less than or equal to 5 nm, further preferably greater than or equal to 1 nm and less than 5 nm, further preferably greater than or equal to 1 nm and less than or equal to 3 nm. Additionally, each layer included in the insulating layer 250 at least partly preferably includes a region with the above-described thickness.

Typically, the thicknesses of the fourth insulating layer, the third insulating layer, the first insulating layer, and the second insulating layer are 1 nm, 2 nm, 2 nm, and 1 nm, respectively. Such a structure enables the transistor to have favorable electrical characteristics even when the transistor is miniaturized or highly integrated.

In addition, it is acceptable that the second insulating layer is not provided in the insulating layer 250 having the four-layer structure. For example, an insulating layer having a barrier property against oxygen can be used as the fourth insulating layer, an insulating layer including a material with a low relative permittivity can be used as the third insulating layer, and an insulating layer having a function of capturing or fixing hydrogen can be used as the first insulating layer. Specifically, it is possible to employ a three-layer structure where an aluminum oxide film, a silicon oxide film, and a hafnium oxide film are stacked in this order from the oxide semiconductor layer 230 side.

Moreover, in formation of the insulating layer 250 having a stacked-layer structure of a plurality of insulating films, an atomic layer deposition (ALD) process is preferably performed twice or more. For example, two or more kinds of the insulating films included in the insulating layer 250 are preferably formed through an ALD process. When at least two kinds of insulating films are formed through an ALD process, the coverage with the insulating layer 250 and the thickness uniformity of the insulating layer 250 can be improved. When two or more kinds of films, e.g., two or more kinds of insulating films are successively formed through an ALD process, the productivity can be increased.

The insulating layer 225 can be formed using an insulating material usable for the insulating layer 250.

As described above, oxygen vacancies and impurities are preferably reduced as much as possible in the channel formation region of the oxide semiconductor layer. It is particularly preferable that hydrogen be reduced as much as possible in the channel formation region of the oxide semiconductor layer.

In view of this, a hydrogen-barrier insulating layer is preferably used as the insulating layer 225 provided outside the oxide semiconductor layer 230. Accordingly, diffusion of hydrogen into the oxide semiconductor layer 230 can be inhibited, and the reliability of the transistor 200 can be improved. For example, as the insulating layer 225, a silicon nitride film, a silicon nitride oxide film, or an aluminum oxide film is preferably used, and a silicon nitride film is further preferably used.

Note that a silicon nitride film also has a barrier property against oxygen. Thus, using a silicon nitride film as the insulating layer 225 can inhibit extraction of oxygen from the oxide semiconductor layer 230, and accordingly can inhibit formation of oxygen vacancies in the oxide semiconductor layer 230. Furthermore, when a silicon nitride film is used as the insulating layer 225, excess oxygen can be prevented from being supplied to the oxide semiconductor layer 230. Thus, the channel formation region of the oxide semiconductor layer 230 can be prevented from containing excess oxygen, whereby the reliability of the transistor 200 can be improved. The insulating layer 225 is in contact with the side surface of the conductive layer 240a and the side surface of the conductive layer 240b in the opening portion 290 in some cases. In this case, the use of a silicon nitride film as the insulating layer 225 can inhibit oxidation of the side surface of the conductive layer 240a and the side surface of the conductive layer 240b in the opening portion 290 and formation of oxide films on the side surfaces. It is thus possible to inhibit a reduction in the on-state current or the field-effect mobility of the transistor 200.

A silicon nitride film included in the insulating layer 225 is preferably formed by a plasma-enhanced ALD (PEALD). This can improve the coverage of the sidewall of the opening portion 290 with the insulating layer 225, so that the insulating layer 225 with a uniform thickness can be formed.

For the insulating layer 225, any of the above-described materials that can have ferroelectricity can also be used.

For example, FIG. 5A illustrates an example in which the insulating layer 225 has a single-layer structure. The insulating layer 225 can have a stacked-layer structure of two or more layers. FIG. 10B illustrates an example in which the insulating layer 225 has a two-layer structure of an insulating layer 225_1 and an insulating layer 225_2.

FIG. 10B illustrates an example in which the insulating layer 225 includes two layers of the insulating layer 225_1 and the insulating layer 225_2; the insulating layer 225_1 is in contact with the conductive layer 220, the insulating layer 280, the conductive layer 255, the insulating layer 281, and the conductive layer 240; and the insulating layer 225_2 is positioned between the insulating layer 225_1 and the oxide semiconductor layer 230. The insulating layer 225 illustrated in FIG. 10B has a two-layer structure of the insulating layer 225_1 and the insulating layer 225_2 over the insulating layer 225_1.

The insulating layer 225_1 provided in contact with the side surface of the insulating layer 280 in the opening portion 290 is preferably formed using a hydrogen-barrier insulating layer, and the insulating layer 225_2 provided in contact with the oxide semiconductor layer 230 is preferably formed using an insulating layer having a function of capturing or fixing hydrogen. This structure enables the hydrogen concentration in the oxide semiconductor layer 230 to be reduced. Accordingly, the electrical characteristics and reliability of the transistor can be improved. For example, it is preferable that a silicon nitride film be used as the insulating layer 225_1 and a hafnium oxide film, a hafnium silicate film, or an aluminum oxide film be used as the insulating layer 225_2. Here, the insulating layer 225_1 contains silicon and nitrogen, and the insulating layer 225_2 contains oxygen and one or both of hafnium and aluminum.

The insulating layer 2251 can be formed using a hydrogen-barrier insulating layer, and the insulating layer 225_2 can be formed using an insulating layer including a region containing excess oxygen. This structure enables one or both of oxygen vacancies and hydrogen in the oxide semiconductor layer 230 to be reduced. Accordingly, the electrical characteristics and reliability of the transistor can be improved. For example, it is preferable that a silicon nitride film be used as the insulating layer 225_1 and a silicon oxide film, a silicon oxynitride film, or an aluminum oxide film be used as the insulating layer 2252. Here, the insulating layer 225_1 contains silicon and nitrogen, and the insulating layer 225_2 contains oxygen and one or both of silicon and aluminum. In particular, when a silicon oxide film is used as the insulating layer 225_2, the insulating layer 225_2 contains silicon and oxygen.

Typically, a silicon nitride film and a silicon oxide film can be used as the insulating layer 225_1 and the insulating layer 225_2, respectively. The thicknesses of the insulating layer 225_1 and the insulating layer 2252 are each 2 nm.

As described above, the hydrogen-barrier insulating layer encloses the periphery of the oxide semiconductor layer 230 in a ring shape, and an insulating layer having a function of capturing or fixing hydrogen or an insulating layer including a region containing excess oxygen is provided in the vicinity of the oxide semiconductor layer 230, in which case one or both of oxygen vacancies and impurities in the oxide semiconductor layer 230 can be reduced. Accordingly, the electrical characteristics and reliability of the transistors can be improved.

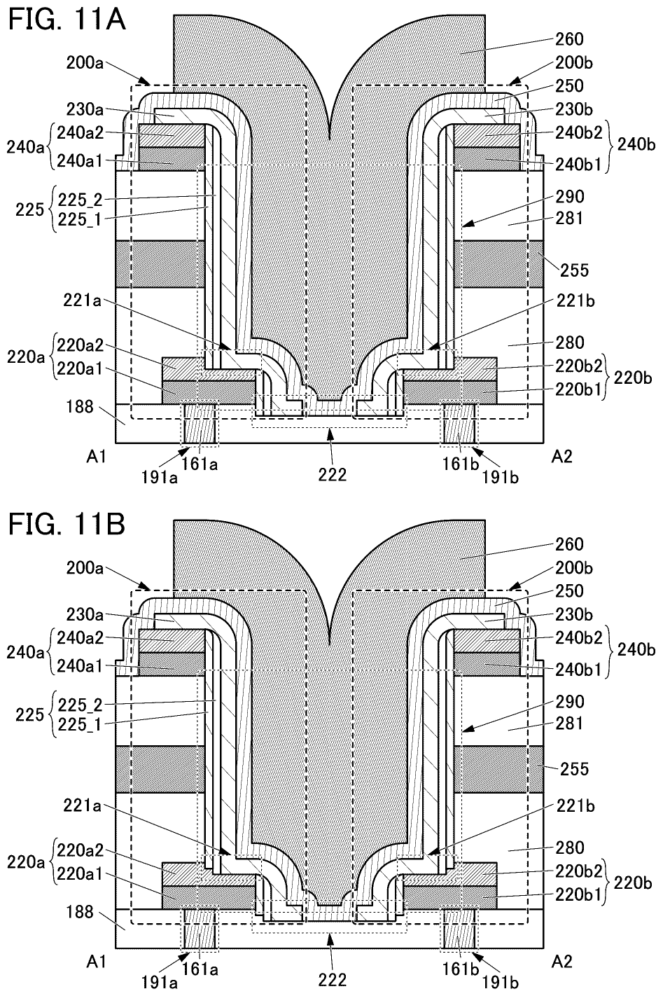

Here, another structure example of the insulating layer 225 illustrated in FIG. 10B is illustrated in FIGS. 11A and 11B. FIG. 11A illustrates an example in which the bottom surface of the insulating layer 225_2 includes a region in contact with the bottom portion of the depressed portion 221a, a region in contact with the bottom portion of the depressed portion 221b, and a region in contact with the bottom portion of the depressed portion 222.

In the example illustrated in FIG. 11B, the conductive layer 220a2 and the conductive layer 220b2 each include a first depressed portion and a second depressed portion positioned outside the first depressed portion. In the example illustrated in FIG. 11B, the insulating layer 188 includes a third depressed portion and a fourth depressed portion positioned outside the third depressed portion. The depth of the first depressed portion is greater than that of the second depressed portion, and the depth of the third depressed portion is greater than that of the fourth depressed portion. In the formation of the opening portion 290, the second depressed portion is provided in the conductive layer 220a2 and the conductive layer 220b2, and the fourth depressed portion is provided in the insulating layer 188. After that, at the time of processing the insulating layer 225_1, the first depressed portion is provided in the conductive layer 220a2 and the conductive layer 220b2, and the third depressed portion is provided in the insulating layer 188.

In the example illustrated in FIG. 11B, the insulating layer 225_1 is provided in contact with the bottom portion and the sidewall of the second depressed portion and the bottom portion and the sidewall of the fourth depressed portion. The insulating layer 225_2 is provided in contact with the bottom portion and the sidewall of the first depressed portion and the bottom portion and the sidewall of the third depressed portion.

For example, the insulating layer 2251 is formed in contact with the sidewall of the opening portion 290, the side surface of the conductive layer 220a, and the side surface of the conductive layer 220b. After that, an insulating film to be the insulating layer 225_2 is formed and processed, so that the insulating layer 225 having the structure illustrated in FIG. 11A or 11B can be formed. The contact area between the insulating layer 225_1 and the oxide semiconductor layer 230 can be reduced, compared with the transistor 200 illustrated in FIG. 10B, and thus the insulating layer 225_2 can be in contact with the oxide semiconductor layer 230.

The insulating layer 225 can have a three-layer structure of a first insulating layer, a second insulating layer, and a third insulating layer. For example, it is preferable that one of the first to third insulating layers be formed using a hydrogen-barrier insulating layer, another be formed using an insulating layer having a function of capturing or fixing hydrogen, and the other be formed using an insulating layer including a region containing excess oxygen. This structure enables the electrical characteristics and reliability of the transistor to be improved.

Moreover, the insulating layer 225 can have a four-layer structure of the first insulating layer, the second insulating layer, the third insulating layer, and a fourth insulating layer. For example, it is preferable that one of the first to fourth insulating layers be formed using a hydrogen-barrier insulating layer, another be formed using an insulating layer having a function of capturing or fixing hydrogen, another be formed using an insulating layer including a region containing excess oxygen, and the other be formed using an insulating layer having a barrier property against oxygen. This structure can inhibit a reduction in the amount of on-state current or a reduction in the field-effect mobility of the transistor 200.

For the stacked-layer structure of the first to fourth insulating layers in the insulating layer 225, the stacked-layer structure of the first to fourth insulating layers in the insulating layer 250 can be referred to. In addition, the stacking order in the insulating layer 225 is preferably reverse from the stacking order in the insulating layer 250. For example, in the case where the insulating layer 225 has a three-layer structure, the insulating layer 225 can have a three-layer structure of the second insulating layer in contact with the conductive layer 255, the first insulating layer over the second insulating layer, and the third insulating layer over the first insulating layer. In this case, the third insulating layer is in contact with the oxide semiconductor layer 230.

### [Conductive Layer]

For each of the conductive layers (the conductive layers 110, 115, 120, 161, 220, 240, 260, 255, and the like) included in the semiconductor device, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as In—Sn oxide or ITO), indium tin oxide containing titanium oxide, indium tin oxide containing silicon (also referred to as ITSO), indium zinc oxide (also referred to as In—Zn oxide or IZO (a registered trademark)), and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A plurality of conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

For example, a conductive material with high conductivity such as tungsten can be used for the conductive layer 110. With the use of a conductive material with high conductivity, the conductive layer 110 can have an improved conductivity and functions well as the wiring CAL.

For the conductive layer 115, a single layer or stacked layers of a conductive material that is less likely to be oxidized, a conductive material having a function of inhibiting diffusion of oxygen, or the like is preferably used. For example, titanium nitride, ITSO, or the like may be used. Alternatively, a structure in which titanium nitride is stacked over tungsten may be used, for example. Alternatively, for example, a structure in which tungsten is stacked over first titanium nitride and second titanium nitride is stacked over the tungsten may be used. This structure can inhibit the conductive layer 115 from being oxidized by the insulating layer 121 when an oxide is used for the insulating layer 121. This structure can also inhibit the conductive layer 115 from being oxidized by the insulating layer 163 or the insulating layer 164 when an oxide is used for at least one of the insulating layer 163 and the insulating layer 164.

Each of the conductive layers 220 and 240 is in contact with the oxide semiconductor layer 230. Thus, each of the conductive layers 220 and 240 is preferably formed using a conductive material that is not easily oxidized, a conductive material that maintains its low electric resistance even after being oxidized, a metal oxide that has conductivity (also referred to as an oxide conductor), or a conductive material that has a function of inhibiting diffusion of oxygen. Examples of the conductive material include a conductive material containing nitrogen and a conductive material containing oxygen. Thus, a decrease in conductivity of each of the conductive layers 220 and 240 can be inhibited.

When a conductive material containing oxygen is used for the conductive layer 220, the conductive layer 220 can maintain its conductivity even when after absorbing oxygen. Similarly, when a conductive material containing oxygen is used for the conductive layer 240, the conductive layer 240 can maintain its conductivity even after absorbing oxygen. For each of the conductive layers 220 and 240, ITO, ITSO, In—Zn oxide, or the like is preferably used, for example.

In the case where the conductive layer 220 and the conductive layer 240 each have a stacked-layer structure, a conductive material containing oxygen is preferably used for a layer having the largest contact area with the oxide semiconductor layer 230 in the stacked-layer structure, in which case the contact resistance between the conductive layer 220 and the oxide semiconductor layer 230 and the contact resistance between the conductive layer 240 and the oxide semiconductor layer 230 can be reduced.

For example, the conductive layer 220a illustrated in FIG. 5A has a two-layer structure of the conductive layer 220a1 and the conductive layer 220a2 over the conductive layer 220a1. Similarly, the conductive layer 220b has a two-layer structure of the conductive layer 220b1 and the conductive layer 220b2 over the conductive layer 220b1. In this case, for the conductive layers 220a2 and 220b2, a conductive material that is less likely to be oxidized, a conductive material that maintains low electric resistance even when oxidized, a conductive metal oxide, or a conductive material having a function of inhibiting diffusion of oxygen is preferably used. For the conductive layer 220a2 and the conductive layer 220b2, a conductive material containing oxygen is preferably used, for example. A material having conductivity higher than those for the conductive layer 220a2 and the conductive layer 220b2 is preferably used for each of the conductive layer 220a1 and the conductive layer 220b1. Specifically, it is preferable that an oxide conductor (e.g., ITO, ITSO, or In—Zn oxide) be used for the conductive layer 220a2 and the conductive layer 220b2 and tungsten be used for the conductive layer 220a1 and the conductive layer 220b1. For the conductive layer 220a1 and the conductive layer 220b1, ruthenium, titanium nitride, tantalum nitride, or the like may be used. When an oxide conductor is used as the conductive layer 220a2 mainly in contact with the oxide semiconductor layer 230a, the contact resistance with the oxide semiconductor layer 230a can be reduced. Similarly, when an oxide conductor is used as the conductive layer 220b2 mainly in contact with the oxide semiconductor layer 230b, the contact resistance with the oxide semiconductor layer 230b can be reduced. When a material having higher conductivity than an oxide conductor is used for the layer included in the conductive layer 220a and the layer included in the conductive layer 220b, the conductivity of the conductive layer 220a and the conductive layer 220b can be increased.

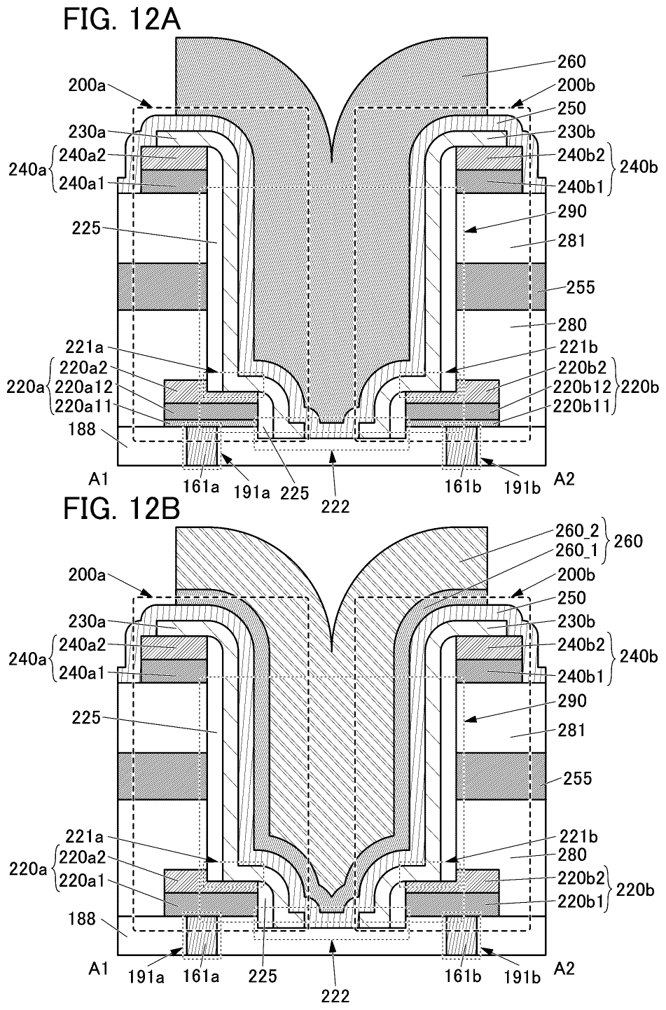

For example, FIG. 5A illustrates an example in which the conductive layer 220al, the conductive layer 220b1, the conductive layer 220a2, and the conductive layer 220b2 each have a single-layer structure. Note that one or both of the conductive layers 220a1 and 220a2 may have a stacked-layer structure of two or more layers. Similarly, one or both of the conductive layers 220b1 and 220b2 may have a stacked-layer structure of two or more layers. FIG. 12A illustrates an example in which the conductive layer 220a1 has a two-layer structure of a conductive layer 220a1 and a conductive layer 220a12 over the conductive layer 220a11 and the conductive layer 220b1 has a two-layer structure of a conductive layer 220b11 and a conductive layer 220b12 over the conductive layer 220b11. In this case, the conductive layer 220a has a three-layer structure of the conductive layer 220a11, the conductive layer 220a12 over the conductive layer 220a11, and the conductive layer 220a2 over the conductive layer 220a12. Similarly, the conductive layer 220b has a three-layer structure of the conductive layer 220b11, the conductive layer 220b12 over the conductive layer 220b11, and the conductive layer 220b2 over the conductive layer 220b12.

For example, a conductive material that is less likely to be oxidized or a conductive material having a function of inhibiting diffusion of oxygen is preferably used for the conductive layers 220a11 and 220b11. A material having high conductivity is preferably used for the conductive layers 220a12 and 220b12. Moreover, a conductive material containing oxygen (preferably, an oxide conductor) is preferably used for the conductive layers 220a2 and 220b2. Specifically, titanium nitride is preferably used for the conductive layers 220a11 and 220b11, tungsten is preferably used for the conductive layers 220a12 and 220b12, and an oxide conductor (e.g., ITO, ITSO, or In—Zn oxide) is preferably used for the conductive layers 220a2 and 220b2. In this case, the titanium nitride film is in contact with the insulating layer 188, and the oxide conductive film is in contact with the oxide semiconductor layer 230a and the oxide semiconductor layer 230b, for example. In addition, an oxide conductor is used for a layer closest to the channel formation region of the oxide semiconductor layer 230a and a layer closest to the channel formation region of the oxide semiconductor layer 230b. Since the oxide conductor has a lower contact resistance with the oxide semiconductor layer 230a than tungsten, the current path between the source and the drain can be shortened and the on-state currents of the transistors 200a and 200b can be increased. Such a structure enables the conductivity to be maintained even when the conductor layer 220a is in contact with the oxide semiconductor layer 230a and the conductive layer 220b is in contact with the oxide semiconductor layer 230b. When a metal material (here, tungsten) having higher conductivity than the oxide conductor and titanium nitride is used for the conductive layers 220a12 and 220b12, the conductivities of the conductive layers 220a and 220b can be increased.

For example, the conductive layer 240a illustrated in FIG. 5A has a two-layer structure of the conductive layer 240a1 and the conductive layer 240a2 over the conductive layer 240a1. Similarly, for example, the conductive layer 240b illustrated in FIG. 5A has a two-layer structure of the conductive layer 240b1 and the conductive layer 240b2 over the conductive layer 240b1. In this case, a conductive material containing oxygen is preferably used for the conductive layers 240a2 and 240b2, for example. For the conductive layers 240a1 and 240b1, a material having higher conductivity than the material for the conductive layers 240a2 and 240b2 is preferably used. Specifically, it is preferable that an oxide conductor (e.g., ITO, ITSO, or In—Zn oxide) be used for the conductive layers 240a2 and 240b2 and tungsten be used for the conductive layers 240a1 and 240b1. For the conductive layers 240a1 and 240b1, ruthenium, titanium nitride, tantalum nitride, or the like may be used. When an oxide conductor is used for the conductive layer 240a2 mainly in contact with the oxide semiconductor layer 230a, the contact resistance with the oxide semiconductor layer 230a can be reduced. Similarly, when an oxide conductor is used for the conductive layer 240b2 mainly in contact with the oxide semiconductor layer 230b, the contact resistance with the oxide semiconductor layer 230b can be reduced. When a material having higher conductivity than the oxide conductor is used for a layer included in the conductive layer 240a and a layer included in the conductive layer 240b, the conductivities of the conductive layers 240a and 240b can be increased.

In addition, a conductive material containing oxygen can be used for the conductive layers 240a1 and 240b1, and a material having higher conductivity than the material for the conductive layers 240a1 and 240b1 can be used for the conductive layers 240a2 and 240b2. In this case, the material having higher conductivity is used for the layers of the conductive layers 240a and 240b which are closest to the channel formation regions of the oxide semiconductor layers 230a and 230b. Thus, the current path between the source and the drain can be shortened, so that the on-state currents of the transistors 200a and 200b can be increased.

The conductive layer 255 includes a region functioning as one of the wiring WOL and the wiring BGL. The conductive layer 255 is preferably formed using a material having high conductivity such as tungsten. For the conductive layer 255, a conductive material that is not easily oxidized, a conductive material having a function of inhibiting diffusion of oxygen, or the like is preferably used. As described above, examples of the conductive material include a conductive material containing nitrogen (e.g., titanium nitride or tantalum nitride) and a conductive material containing oxygen (e.g., ruthenium oxide). Thus, a decrease in conductivity of the conductive layer 255 can be inhibited.

It is preferable to use, for the conductive layer 255, a conductive material containing oxygen and a metal element contained in the metal oxide where a channel is formed. Alternatively, a conductive material containing the above metal element and nitrogen (e.g., titanium nitride or tantalum nitride) may be used. One or more of ITO, indium oxide containing tungsten oxide, indium zinc oxide containing tungsten oxide, indium oxide containing titanium oxide, indium tin oxide containing titanium oxide, In—Zn oxide, and ITSO may be used. Indium gallium zinc oxide containing nitrogen may also be used. With the use of such a material, hydrogen contained in the metal oxide where a channel is formed can be captured in some cases. Hydrogen entering from a surrounding insulating layer or the like can also be captured in some cases.

FIG. 5A illustrates an example where the conductive layer 255 has a single-layer structure, for example. The conductive layer 255 can have a stacked-layer structure of two or more layers.

As described above, the channel lengths of the transistor 200a and the transistor 200b can be determined by the thickness or the like of the conductive layer 255. Thus, the conductive layer 255 has a thickness corresponding to a desired channel length. The thickness of the conductive layer 255 can be, for example, greater than or equal to 2 nm and less than or equal to 50 nm, greater than or equal to 3 nm and less than or equal to 30 nm, greater than or equal to 4 nm and less than or equal to 20 nm, or greater than or equal to 5 nm and less than or equal to 15 nm.

For the conductive layer 260, a conductive material usable for the conductive layer 255 can be used.

FIG. 5A illustrates an example where the conductive layer 260 has a single-layer structure, for example. In addition, the conductive layer 260 can have a stacked-layer structure of two or more layers. FIG. 12B illustrates an example in which the conductive layer 260 illustrated in FIG. 5A has a two-layer structure of a conductive layer 260_1 and a conductive layer 260_2 over the conductive layer 260_1. In this case, in a preferable example, a titanium nitride film is preferably used as the conductive layer 260_1, and a tungsten film is preferably used as the conductive layer 2602. In another preferable example, a tantalum nitride film is preferably used as the conductive layer 260_1, and a copper film is preferably used as the conductive layer 2602. Such a structure can increase the conductivity of the conductive layer 260.

Alternatively, the conductive layer 260 may have a stacked-layer structure of three or more layers. The conductive layer 260 may have a three-layer structure of a tantalum nitride film, a titanium nitride film over the tantalum nitride film, and a tungsten film over the titanium nitride film, for example.

### [Substrate]

As a substrate where a semiconductor device is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. An insulator substrate provided with a conductor or a semiconductor, a semiconductor substrate provided with a conductor or an insulator, a conductor substrate provided with a semiconductor or an insulator, or the like is also given. Alternatively, these substrates provided with elements may be used. Examples of the element provided for the substrate include a capacitor, a resistor, a switching element, a light-emitting element, and a memory element.

The above is the description of materials that can be used for the semiconductor device of this embodiment.

The semiconductor device of one embodiment of the present invention may include an insulating layer over the transistor 200. Specifically, an insulating layer may be provided over the conductive layer 260 and the insulating layer 250.

As the insulating layer, a hydrogen-barrier insulating layer is preferably used. Such a structure can inhibit diffusion of hydrogen from above the transistor 200 into the oxide semiconductor layer 230.

Although FIG. 5A illustrates a structure example where the side surface of the conductive layer 240 in the opening portion 290 and the side surface of the insulating layer 280 in the opening portion 290 are aligned or substantially aligned with each other, the present invention is not limited to the structure. For example, the side surface of the conductive layer 240 in the opening portion 290 and the side surface of the insulating layer 280 in the opening portion 290 may be discontinuous. The inclination of the side surface of the conductive layer 240 in the opening portion 290 and the inclination of the side surface of the insulating layer 280 in the opening portion 290 may be different from each other. At this time, part of the sidewall of the opening portion 290 has a tapered shape.

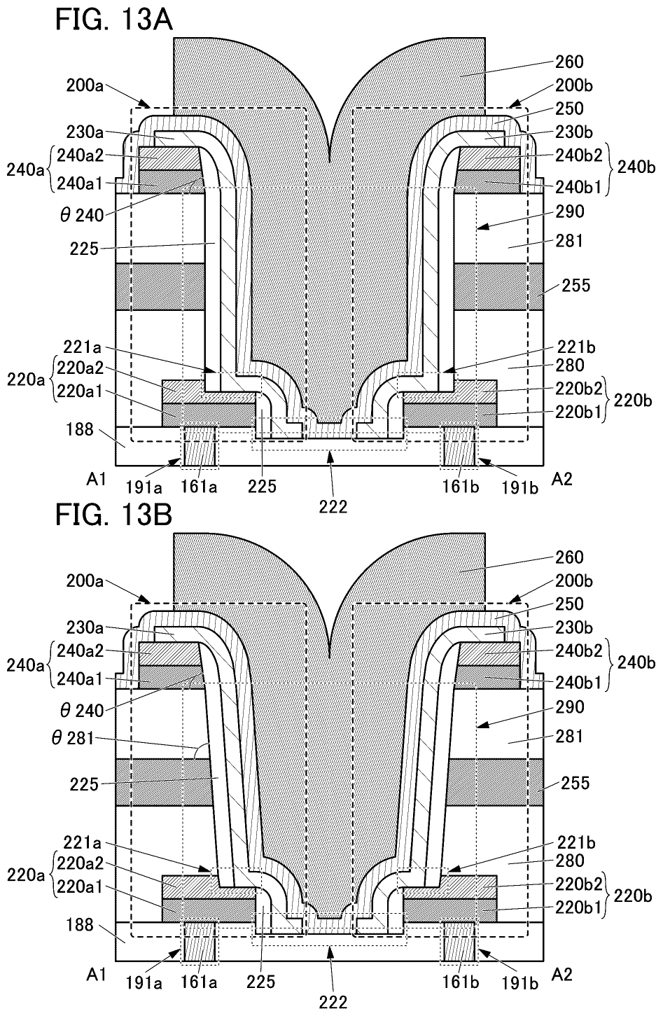

FIGS. 13A and 13B each illustrate an example where at least part of the sidewall of the opening portion 290 has a tapered shape. FIG. 13A illustrates an example where the side surfaces of the conductive layer 240a and the conductive layer 240b in the opening portion 290 each have a tapered shape, and FIG. 13B illustrates an example where the side surfaces of the conductive layer 240a, the conductive layer 240b, the insulating layer 281, the conductive layer 255, and the insulating layer 280 in the opening portion 290 each have a tapered shape.

When the sidewall of the opening portion 290 has a tapered shape, the coverage with the insulating layer 225, the oxide semiconductor layer 230a, the oxide semiconductor layer 230b, the insulating layer 250, and the like can be improved, so that defects such as voids can be reduced. In the case where the sidewall of the opening portion 290 has a tapered shape, for example, a taper angle (an angle θ240) of the side surface of the conductive layer 240a in the opening portion 290, a taper angle of the side surface of the conductive layer 240b in the opening portion 290, and a taper angle (an angle θ281) of the side surface of the insulating layer 281 in the opening portion 290 are each preferably greater than or equal to 450 and less than 90°. Specifically, the taper angles are preferably greater than or equal to 800 and less than 90°, in which case the semiconductor device can be miniaturized or highly integrated as described above. Moreover, the taper angles are preferably greater than or equal to 450 or greater than or equal to 500 and less than 80°, less than or equal to 75°, less than or equal to 70°, less than or equal to 65°, or less than or equal to 60°, in which case the coverage with a film to be formed in the opening portion 290 is improved.

For example, the angle θ240 is preferably smaller than the angle θ281. With such a structure, the coverage of the side surface of the conductive layer 240a in the opening portion 290 with the insulating layer 225, the oxide semiconductor layer 230a, and the like is improved, so that defects such as voids can be reduced. In the case where the insulating layer 280 has a stacked-layer structure, the inclinations of the side surfaces of the layers in the opening portion 290 may be different from each other. Similarly, in the case where the conductive layers 240a and 240b have a stacked-layer structure, the inclinations of the side surfaces of the layers in the opening portion 290 may be different from each other.

As described above, the oxide semiconductor layer 230 can have a stacked-layer structure of two or more layers.

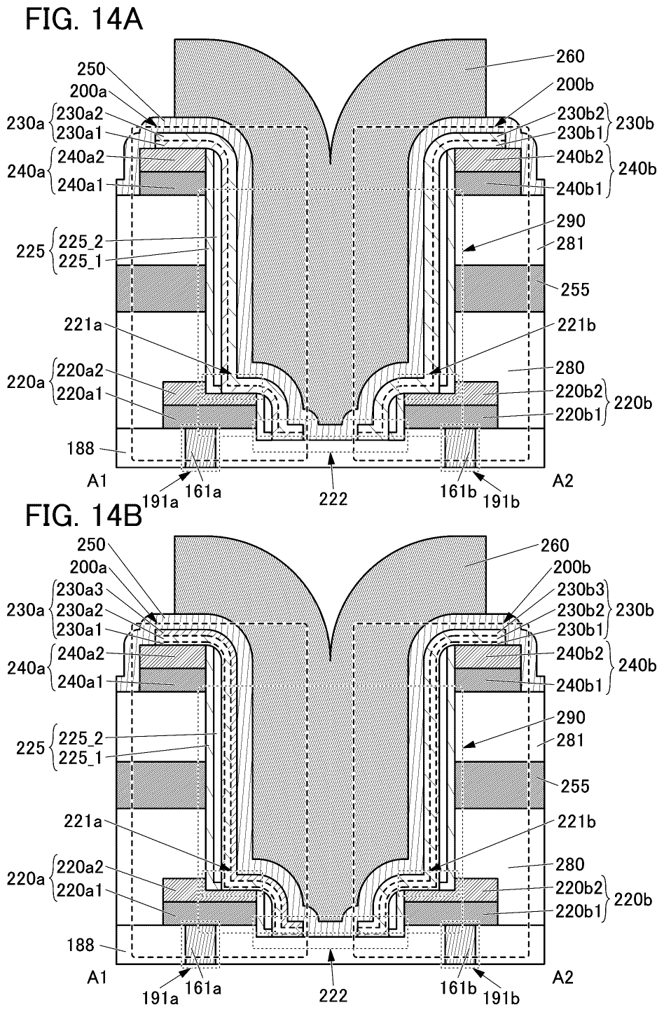

FIG. 14A illustrates an example in which the oxide semiconductor layer 230 included in the semiconductor device illustrated in FIG. 10B has a two-layer structure. The oxide semiconductor layer 230a illustrated in FIG. 14A can have a two-layer structure of an oxide semiconductor layer 230a1 and an oxide semiconductor layer 230a2 over the oxide semiconductor layer 230al. Similarly, the oxide semiconductor layer 230b illustrated in FIG. 14A can have a two-layer structure of an oxide semiconductor layer 230b1 and an oxide semiconductor layer 230b2 over the oxide semiconductor layer 230b1.

FIG. 14B illustrates an example in which the oxide semiconductor layer 230 included in the semiconductor device illustrated in FIG. 10B has a three-layer structure. The oxide semiconductor layer 230a illustrated in FIG. 14B can have a three-layer structure of the oxide semiconductor layer 230a1, the oxide semiconductor layer 230a2 over the oxide semiconductor layer 230a1, and an oxide semiconductor layer 230a3 over the oxide semiconductor layer 230a2. Similarly, the oxide semiconductor layer 230b illustrated in FIG. 14B can have a three-layer structure of the oxide semiconductor layer 230b1, the oxide semiconductor layer 230b2 over the oxide semiconductor layer 230b1, and an oxide semiconductor layer 230b3 over the oxide semiconductor layer 230b2.

Note that the boundary (or the interface) between the oxide semiconductor layer 230a1 and the oxide semiconductor layer 230a2 and the boundary (or the interface) between the oxide semiconductor layer 230a2 and the oxide semiconductor layer 230a3 cannot be clearly observed in some cases. Similarly, the boundary (or the interface) between the oxide semiconductor layer 230b1 and the oxide semiconductor layer 230b2 and the boundary (or the interface) between the oxide semiconductor layer 230b2 and the oxide semiconductor layer 230b3 cannot be clearly observed in some cases. Thus, the boundaries are denoted by dashed lines in FIG. 14A and FIG. 14B.

For the oxide semiconductor layers usable for the oxide semiconductor layers 230a1 to 230a3 and the oxide semiconductor layers 230b1 to 230b3, the description in Embodiment 2 can be referred to.

For example, FIG. 5A illustrates a structure in which the end portion of the oxide semiconductor layer 230a in the opening portion 290 is positioned inside the end portion of the conductive layer 220a on the opening portion 290 side (the end portion of the oxide semiconductor layer 230a in the opening portion 290 is positioned closer to the side surface of the conductive layer 220b in the opening portion 290 than the end portion of the conductive layer 220a on the opening portion 290 side is). FIG. 5A also illustrates an example in which the end portion of the oxide semiconductor layer 230b in the opening portion 290 is positioned inward from the end portion of the conductive layer 220b on the opening portion 290 side (the end portion of the oxide semiconductor layer 230b in the opening portion 290 is positioned closer to the side surface of the conductive layer 220a in the opening portion 290 than the end portion of the conductive layer 220b on the opening portion 290 side is). In the opening portion 290, the oxide semiconductor layer 230a and the oxide semiconductor layer 230b are in contact with the top surface of the insulating layer 188 in the illustrated example. When the end portion of the oxide semiconductor layer 230a and the end portion of the oxide semiconductor layer 230b in the opening portion 290 are positioned over the insulating layer 188, the oxide semiconductor film to be the oxide semiconductor layer 230a and the oxide semiconductor layer 230b can be processed relatively easily.

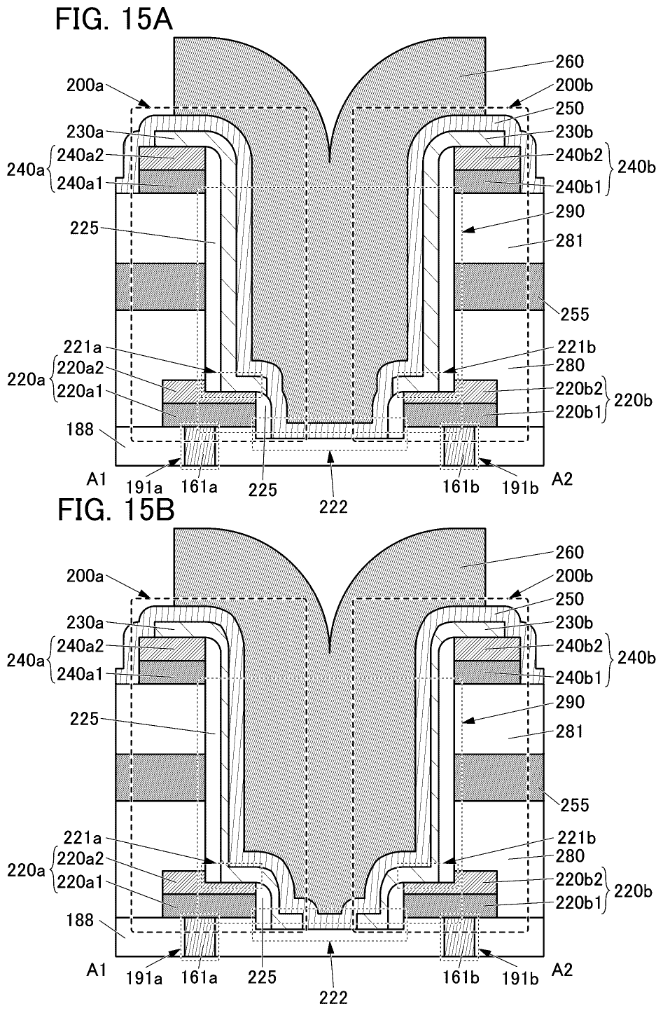

Note that the present invention is not limited to the above-described structures, as long as the opening portion 290 includes a region where the oxide semiconductor layer 230a and the conductive layer 220a are in contact with each other and a region where the oxide semiconductor layer 230b and the conductive layer 220b are in contact with each other. FIG. 15A illustrates an example in which the oxide semiconductor layer 230a and the oxide semiconductor layer 230b in the opening portion 290 illustrated in FIG. 5A are not in contact with the top surface of the insulating layer 188. When the transistor 200a and the transistor 200b have the structure illustrated in FIG. 15A, the distance (corresponding to the distance Hab illustrated in FIG. 5B) between the oxide semiconductor layer 230a and the oxide semiconductor layer 230b can be increased without reductions in the contact area between the conductive layer 220a and the oxide semiconductor layer 230a and the contact area between the conductive layer 220b and the oxide semiconductor layer 230b. Accordingly, the distance between the conductive layer 220a and the conductive layer 220b can be shortened, so that the semiconductor device can be miniaturized or highly integrated.

FIG. 15B illustrates an example in which the thickness of a portion of the oxide semiconductor layer 230a illustrated in FIG. 5A that is formed over the top surface of the conductive layer 240a or the conductive layer 220a (hereinafter the thickness is referred to as a first thickness) is different from the thickness of a portion of the oxide semiconductor layer 230a that is formed over the sidewall of the opening portion 290 (hereinafter the thickness is referred to as a second thickness). For example, in the case where part of the oxide semiconductor layer 230a is formed by a sputtering method, the first thickness and the second thickness of the oxide semiconductor layer 230a are different in some cases. For example, as illustrated in FIG. 15B, the ratio of the second thickness to the first thickness is lower than 1, lower than 0.8, or lower than 0.5 in some cases. In particular, as the angle θ281 illustrated in FIG. 13B is closer to 90°, the ratio of the second thickness to the first thickness of the oxide semiconductor layer 230a tends to be smaller. The above description of the first thickness and the second thickness can apply to the oxide semiconductor layer 230b.

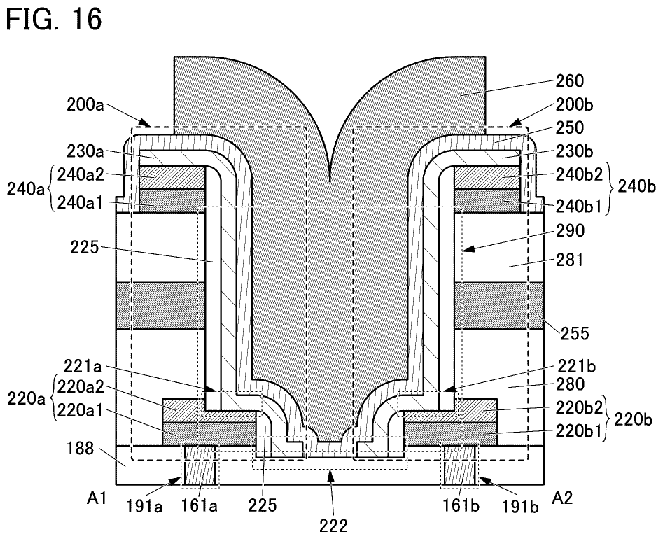

FIG. 16 illustrates an example in which in the outside of the opening portion 290 illustrated in FIG. 5A, the end portion of the oxide semiconductor layer 230 is aligned or substantially aligned with the end portion of the conductive layer 240 on the opposite side to the opening portion 290 in a plan view. In the structure illustrated in FIG. 16, the formation steps of the conductive layers 240a and 240b and the formation steps of the oxide semiconductor layers 230a and 230b can be partly shared. This leads to a reduction in the number of steps.

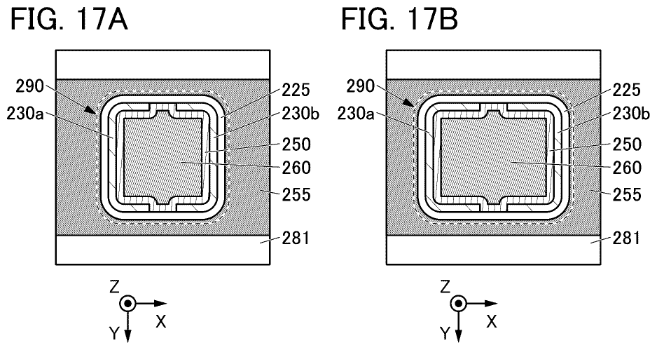

FIGS. 17A and 17B are plan views each illustrating an example where the shape of the opening portion 290 in the plan view is a substantially quadrangular shape with rounded corners. FIG. 17A illustrates an example in which the opening portion 290 has a substantially square shape with rounded corners in the plan view. FIG. 17B illustrates an example in which the opening portion 290 has a substantially rectangular shape with rounded corners in the plan view. Although in the example illustrated in FIG. 17B, the shape of the opening portion 290 in the plan view is a substantially rectangle having the long sides extending in the X direction, the shape of the opening portion 290 in the plan view may be a substantially rectangle having the long sides extending in the Y direction. In the case where the opening portion 290 has a substantially quadrangular shape in the plan view, the sides of the quadrangular shape may be non-parallel to the X direction and the Y direction.

When the shape of the opening portion 290 in the plan view is the shape illustrated in FIG. 17A or FIG. 17B, the channel width per unit area of each of the transistor 200a and the transistor 200b can be increased. This can increase on-state currents of the transistor 200a and the transistor 200b.

### Structure Example 2 of Semiconductor Device

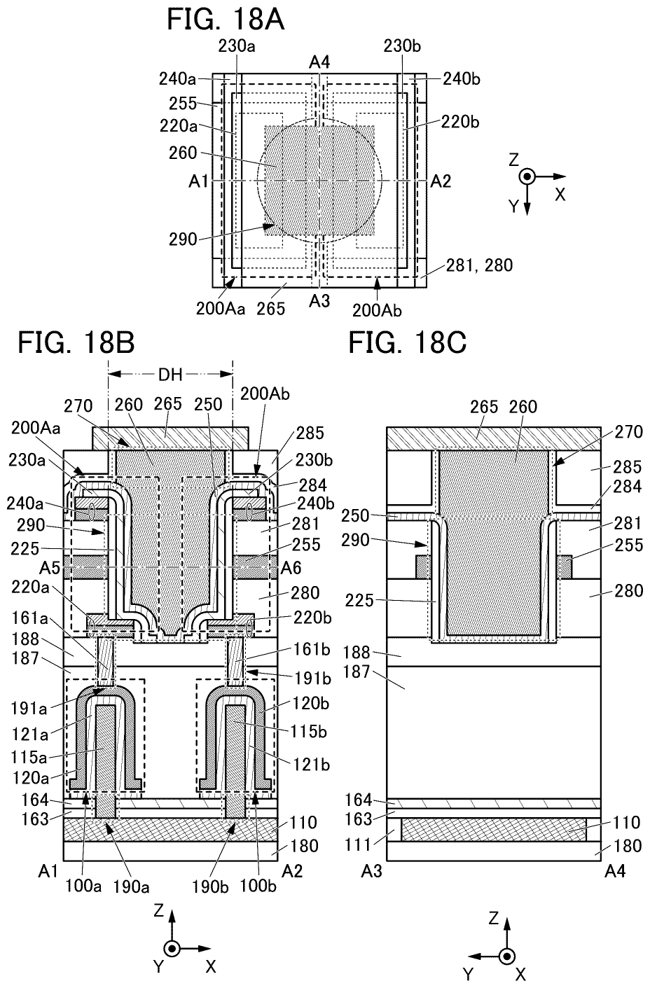

A structure example of the semiconductor device that is different from the structure illustrated in FIG. 1A to FIG. 3A is described below. Semiconductor devices illustrated in FIG. 18A to FIG. 21D each include the capacitor 100 and a transistor whose structure is partly different from that of the transistor 200. Note that description of the portions already described is omitted and only different portions are described in detail. Even when positions or shapes of components are different from those in the above example, the same reference numerals are used as long as the components have the same functions as those in the above example, and detailed description thereof is omitted in some cases.

### [Transistor 200A]

FIG. 18A is a plan view of a semiconductor device including a transistor 200Aa and a transistor 200Ab. FIG. 18B is a cross-sectional view taken along a dashed-dotted line A1-A2 in FIG. 18A. FIG. 18C is a cross-sectional view taken along a dashed-dotted line A3-A4 in FIG. 18A. For the sake of clarity of the drawing, the conductive layer 260 is shown with a hatching pattern in FIG. 18A. FIG. 3B can be referred to for a cross-sectional view along a dashed-dotted line A5-A6 in FIG. 18B. Hereinafter, the transistor 200Aa and the transistor 200Ab are collectively referred to as a transistor 200A in some cases.

The semiconductor device illustrated in FIGS. 18A to 18C includes the insulating layer 180; the conductive layer 110; the insulating layer 111; the insulating layer 163; the insulating layer 164; the insulating layer 187; the insulating layer 188; the conductive layer 161a; the conductive layer 161b; the capacitor 100a; and the capacitor 100b; the transistor 200Aa and the transistor 200Ab over the insulating layer 188, the conductive layer 161a, and the conductive layer 161b; the insulating layer 280 over the insulating layer 188; the insulating layer 281 over the insulating layer 280; an insulating layer 284; an insulating layer 285 over the insulating layer 284; and a conductive layer 265 over the transistor 200Aa, the transistor 200Ab, the insulating layer 284, and the insulating layer 285. The insulating layer 284 includes a region positioned between the conductive layer 260 and the insulating layer 285. The insulating layer 284 and the insulating layer 285 function as interlayer films.

The semiconductor device illustrated in FIGS. 18A to 18C is different from the semiconductor device illustrated in FIG. 1A to FIG. 3A in including the conductive layer 265, the insulating layer 284, and the insulating layer 285.

In the example illustrated in FIGS. 18A to 18C, the conductive layer 265 is provided to extend in the Y direction. The conductive layer 265 functions as the other of the wiring WOL and the wiring BGL. Alternatively, the conductive layer 265 may be provided to extend in the X direction.

For the conductive layer 265, a material usable for the conductive layer 260 can be used. For example, a high-melting-point material that has both heat resistance and conductivity, such as tungsten or molybdenum, can be used for the conductive layer 265. Alternatively, a low-resistance conductive material such as aluminum or copper can be used. The use of a low-resistance conductive material can reduce wiring resistance.

The transistor 200Aa includes the conductive layer 220a, the conductive layer 255, the conductive layer 240a, the insulating layer 225, the oxide semiconductor layer 230a, the insulating layer 250, and the conductive layer 260. The transistor 200Ab includes the conductive layer 220b, the conductive layer 255, the conductive layer 240b, the insulating layer 225, the oxide semiconductor layer 230b, the insulating layer 250, and the conductive layer 260. The conductive layer 265 includes a region in contact with the conductive layer 260. In addition, the conductive layer 265 may be regarded as a component of each of the transistor 200Aa and the transistor 200Ab. The insulating layer 284 is provided over the insulating layer 250.

As illustrated in FIGS. 18B and 18C, the insulating layer 284 is positioned over the insulating layer 250. The insulating layer 284 is provided with an opening portion 270 reaching the insulating layer 250 at a position overlapping with the opening portion 290. At least part of the conductive layer 260 is provided in the opening portion 270. The conductive layer 260 is in contact with the insulating layer 250 in the opening portion 270.

The conductive layer 260 is provided to fill the opening portion 290 and the opening portion 270. The conductive layer 260 includes a portion facing the oxide semiconductor layer 230 with the insulating layer 250 therebetween in the opening portion 290 and a portion positioned in the opening portion 270.

A portion of the conductive layer 265 not overlapping with the opening portion 290 is mainly positioned over the insulating layer 285. Thus, the conductive layer 265 mainly overlaps with the conductive layer 240a and the conductive layer 240b with the insulating layers 284 and 285 therebetween. Accordingly, the distance between the conductive layer 265 and the conductive layer 240a and the distance between the conductive layer 265 and the conductive layer 240b can be increased. Thus, parasitic capacitance generated between the conductive layer 265 and the conductive layer 240a and parasitic capacitance generated between the conductive layer 265 and the conductive layer 240b can be reduced. In particular, the insulating layer 285 preferably has a large thickness, for example, a thickness larger than the thickness of the insulating layer 284, in which case the distance between the conductive layer 265 and the conductive layer 240a and the distance between the conductive layer 265 and the conductive layer 240b can be increased. In addition, the conductive layers 240a and 240b may include a portion overlapping with the conductive layer 265 without the insulating layer 285 therebetween.

FIG. 18B illustrates an example where the width of the opening portion 270 is smaller than the width DH of the opening portion 290. The smaller the width of the opening portion 270 is, the larger the distance between the conductive layer 240a and the conductive layer 260 and the distance between the conductive layer 265 and the conductive layer 240b can be. This is preferable, in which case parasitic capacitance generated between the conductive layer 240a and the conductive layer 260 and parasitic capacitance generated between the conductive layer 240b and the conductive layer 260 can be reduced. For example, the width of the opening portion 270 is preferably smaller than or equal to that of the opening portion 290.

The top surface of the conductive layer 260 and the top surface of the insulating layer 285 or the insulating layer 284 are preferably level with or substantially level with each other. The conductive layer 265 is provided over the insulating layer 285, the insulating layer 284, and the conductive layer 260, and is in contact with the top surface of the conductive layer 260. It can be said that the conductive layer 260 and the conductive layer 265 are connected to each other.

That is, the transistor 200A has a structure where the parasitic capacitance generated between the other of the source and drain electrodes and a gate wiring is reduced. Accordingly, the frequency characteristics of a circuit including the transistor can be improved.

Although this embodiment describes the example where the opening portion 270 has a circular shape in the plan view, the present invention is not limited thereto. Any of the above-described shapes that can be employed for the opening portion 290 can be employed for the shape of the opening portion 270.

The width of the opening portion 270 varies in the depth direction in some cases. Here, the maximum width of the opening portion 270 provided in the insulating layer 284 in the cross-sectional view is specifically used as the width of the opening portion 270.

An insulating layer having a function of capturing or fixing hydrogen is preferably used as the insulating layer 284. With such a structure, diffusion of hydrogen from above the insulating layer 284 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 284, an aluminum oxide film, a hafnium oxide film, a hafnium silicate film, or the like can be used.

As the insulating layer 284, a hydrogen-barrier insulating layer can be used. In this case, diffusion of hydrogen from above the insulating layer 284 into the oxide semiconductor layer 230 can be inhibited. A silicon nitride film and a silicon nitride oxide film can be suitably used for the insulating layer 284 because they release few impurities (e.g., water and hydrogen) and are less likely to transmit oxygen and hydrogen.

In the case where a silicon nitride film is used for the insulating layer 284, the silicon nitride film is preferably formed by a sputtering method. A deposition gas in a sputtering method need not include molecules containing hydrogen; thus, the hydrogen concentration in the insulating layer 284 can be reduced. When the insulating layer 284 is formed by a sputtering method, a high-density silicon nitride film can be obtained.

The insulating layer 284 may have a stacked-layer structure of an insulating layer having a function of capturing or fixing hydrogen and a hydrogen-barrier insulating layer. For example, a stack of an aluminum oxide film and a silicon nitride film over the aluminum oxide film may be used as the insulating layer 284.

The insulating layer 285 functions as an interlayer film and thus is preferably formed using any of the above-described materials with a low relative permittivity. For example, the insulating layer 285 preferably includes a silicon oxide film.

The above is the description of the semiconductor device including the transistor 200Aa and the transistor 200Ab in addition to the capacitor 100a and the capacitor 100b.

### [Transistor 200B]

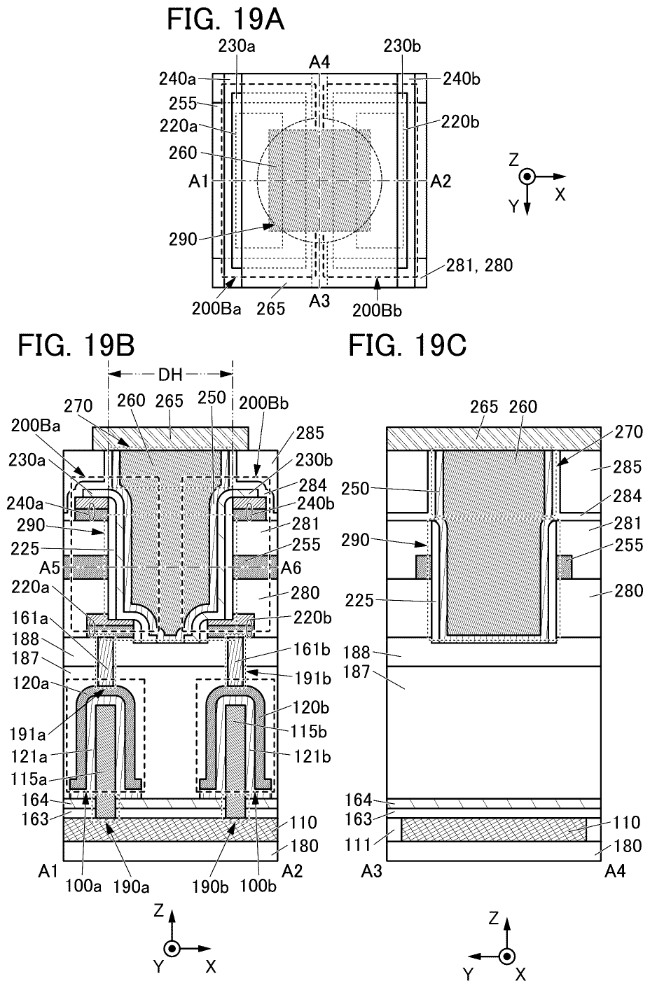

FIG. 19A is a plan view of a semiconductor device including a transistor 200Ba and a transistor 200Bb. FIG. 19B is a cross-sectional view taken along a dashed-dotted line A1-A2 in FIG. 19A. FIG. 19C is a cross-sectional view taken along a dashed-dotted line A3-A4 in FIG. 19A. For the sake of clarity of the drawing, the conductive layer 260 is shown with a hatching pattern in FIG. 19A. FIG. 3B can be referred to for a cross-sectional view along a dashed-dotted line A5-A6 in FIG. 19B. The description of portions similar to those in FIGS. 18A to 18C is omitted below, and only differences are described in detail. Hereinafter, the transistor 200Ba and the transistor 200Bb are collectively referred to as a transistor 200B in some cases.

The semiconductor device illustrated in FIGS. 19A to 19C is different from the semiconductor device illustrated in FIGS. 18A to 18C in that the insulating layer 250 includes a portion in contact with the side surface of the insulating layer 284 in the opening portion 270, for example.

The insulating layer 250 is in contact with the oxide semiconductor layer 230 and the insulating layer 284 in the opening portion 270. A portion of the insulating layer 250 which is provided in the opening portion 270 reflects the shape of the opening portion 270. Specifically, the insulating layer 250 is provided along the sidewall of the opening portion 270 (the side surface of the insulating layer 284). The conductive layer 260 is provided to fill at least part of a depressed portion of the insulating layer 250 reflecting the shape of the opening portion 270.

In the semiconductor device illustrated in FIGS. 19A to 19C, the conductive layer 260 overlaps with neither the top surface of the conductive layer 240a nor the top surface of the conductive layer 240b. Thus, parasitic capacitance generated between the conductive layer 240a and the conductive layer 260 and parasitic capacitance generated between the conductive layer 240b and the conductive layer 260 can be reduced.

As illustrated in FIG. 19B, the maximum width of the conductive layer 260 is smaller than a width DH of the opening portion 290 in the cross-sectional view. As described above, the maximum width of the conductive layer 260 is preferably smaller than the width DH of the opening portion 290, in which case parasitic capacitance generated between the conductive layer 260 and the conductive layer 240a and parasitic capacitance generated between the conductive layer 260 and the conductive layer 240b can be reduced. For example, as in FIG. 19B, the relation in magnitude between the two widths in the semiconductor device of one embodiment of the present invention can be observed in one cross section parallel to the Z direction.

FIG. 19B illustrates an example where the width of the opening portion 270 is smaller than the width DH of the opening portion 290. The width of the opening portion 270 is preferably smaller than or equal to that of the opening portion 290. In this case, the conductive layer 260 overlaps with neither the top surface of the conductive layer 240a nor the top surface of the conductive layer 240b. This is preferable because parasitic capacitance generated between the conductive layer 260 and the conductive layer 240a and parasitic capacitance generated between the conductive layer 260 and the conductive layer 240b can be reduced.

Although this embodiment mainly describes the example where the conductive layer 260 overlaps with neither the top surface of the conductive layer 240a nor the top surface or the conductive layer 240b, the conductive layer 260 may include a portion overlapping with the top surface of the conductive layer 240a and a portion overlapping with the top surface or the conductive layer 240b. The overlapping portions are preferably smaller, in which case the parasitic capacitance between the conductive layer 260 and the conductive layer 240a and the parasitic capacitance between the conductive layer 260 and the conductive layer 240b can be reduced. For example, the width of the opening portion 270 is preferably smaller than the short-side width of the conductive layer 265 (the maximum width of the conductive layer 265 in FIG. 19B).

That is, in the transistor 200B, the parasitic capacitance generated between the other of the source electrode and the drain electrode and the gate electrode and the parasitic capacitance generated between the other of the source electrode and the drain electrode and the gate wiring are reduced. Accordingly, the frequency characteristics of a circuit including the transistor can be improved.

### [Transistor 200C]

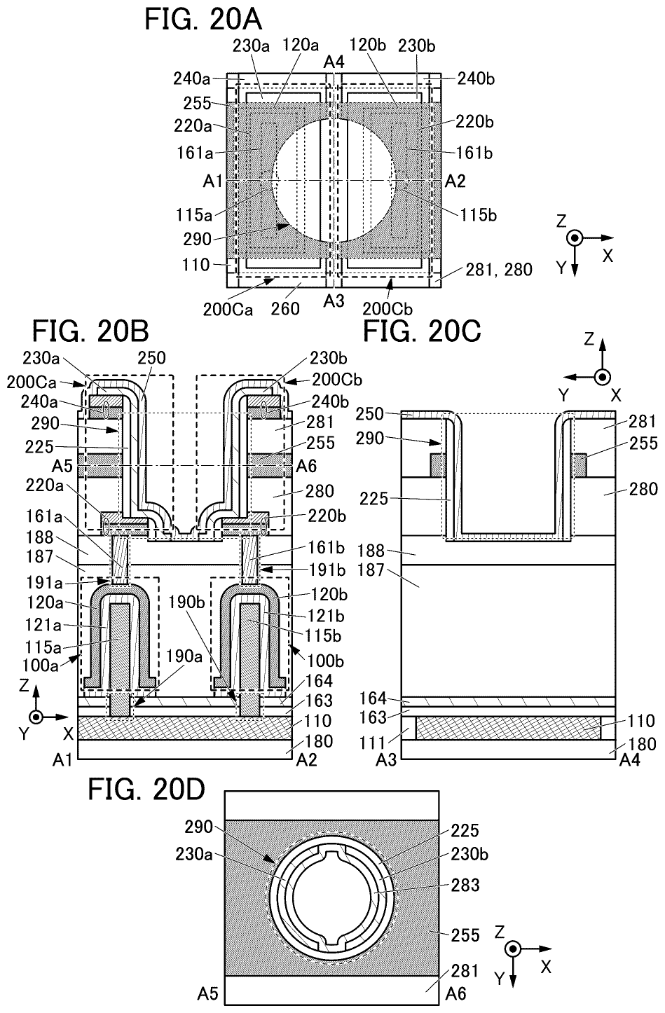

FIG. 20A is a plan view of a semiconductor device including a transistor 200Ca and a transistor 200Cb. FIG. 20B is a cross-sectional view taken along a dashed-dotted line A1-A2 in FIG. 20A. FIG. 20C is a cross-sectional view taken along a dashed-dotted line A3-A4 in FIG. 20A. FIG. 20D is a cross-sectional view taken along a dashed-dotted line A5-A6 in FIG. 20B. For the sake of clarity of the drawing, the conductive layer 255 is shown with a hatching pattern in FIG. 20A. Hereinafter, the transistor 200Ca and the transistor 200Cb are collectively referred to as a transistor 200C in some cases. FIG. 20D is also referred to as a plan view.

The semiconductor device illustrated in FIGS. 20A to 20D is different from the semiconductor device illustrated in FIG. 1A to FIG. 3B in that an insulating layer 283 is provided but the conductive layer 260 and the insulating layer 250 are not provided.

In each of the transistor 200Ca and the transistor 200Cb, the conductive layer 255 functions as a gate electrode, and the insulating layer 225 functions as a gate insulating layer. The transistor 200Ca and the transistor 200Cb are single-gate transistors. Here, the conductive layer 255 includes a region functioning as the wiring WOL illustrated in FIG. 3C.

As the insulating layer 283, a hydrogen-barrier insulating layer is preferably used. Such a structure can inhibit diffusion of hydrogen from above the transistor 200 into the oxide semiconductor layer 230.

In addition, the insulating layer 283 can be formed using an insulating material usable for the insulating layer 250.

An insulating layer can be provided over the insulating layer 283 to fill the opening portion 290. As the insulating layer, a single layer or stacked layers of any of the insulators described in the above-section [insulator] can be used.

The structure not including the conductive layer 260 can lead to a reduction of the manufacturing cost. Furthermore, the area occupied by the semiconductor device can be reduced, and miniaturization or high integration of the semiconductor device can be achieved. Meanwhile, by providing the conductive layer 260, a dual-gate transistor can be provided in the semiconductor device. This enables control of the threshold voltage Vth of the transistor, for example. Thus, the transistors included in the semiconductor device can have favorable electric characteristics.

### [Transistor 200D]

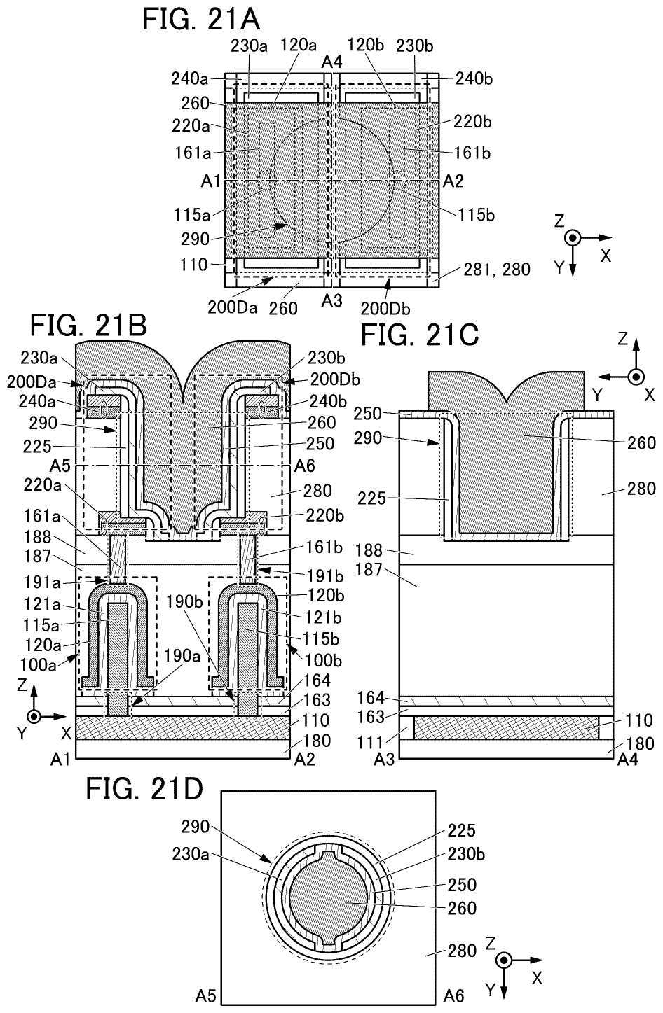

FIG. 21A is a plan view of a semiconductor device including a transistor 200Da and a transistor 200Db. FIG. 21B is a cross-sectional view taken along a dashed-dotted line A1-A2 in FIG. 21A. FIG. 21C is a cross-sectional view taken along a dashed-dotted line A3-A4 in FIG. 21A. FIG. 21D is a cross-sectional view taken along a dashed-dotted line A5-A6 in FIG. 21B. For the sake of clarity of the drawing, the conductive layer 260 is shown with a hatching pattern in FIG. 21A. Hereinafter, the transistor 200Da and the transistor 200Db are collectively referred to as a transistor 200D in some cases. FIG. 21D is also referred to as a plan view.

The semiconductor device illustrated in FIGS. 21A to 21D is different from the semiconductor device illustrated in FIG. 1A to FIG. 3B in that the conductive layer 255 and the insulating layer 281 are not provided.

In each of the transistor 200Da and the transistor 200Db, the conductive layer 260 functions as a gate electrode, and the insulating layer 250 functions as a gate insulating layer. The transistor 200Da and the transistor 200Db are single-gate transistors. Here, the conductive layer 260 includes a region functioning as the wiring WOL illustrated in FIG. 3C.

FIGS. 21A to 21C illustrate an example in which the conductive layer 260 is provided to extend in the X direction. Alternatively, the conductive layer 260 may be provided to extend in the Y direction, for example.

The structure including neither the conductive layer 255 nor the insulating layer 281 can lead to a reduction the manufacturing cost of the semiconductor device. Furthermore, the area occupied by the semiconductor device can be reduced, and miniaturization or high integration of the semiconductor device can be achieved. Meanwhile, by the conductive layer 255 and the insulating layer 281, a dual-gate transistor can be provided in the semiconductor device. This enables control of the threshold voltage Vₜh of the transistor, for example. Thus, the transistors included in the semiconductor device can have favorable electric characteristics.

Incidentally, the above-described structures of the transistor 200 can also be employed for the transistor 200A to the transistor 200D.

### Structure Example 3 of Semiconductor Device

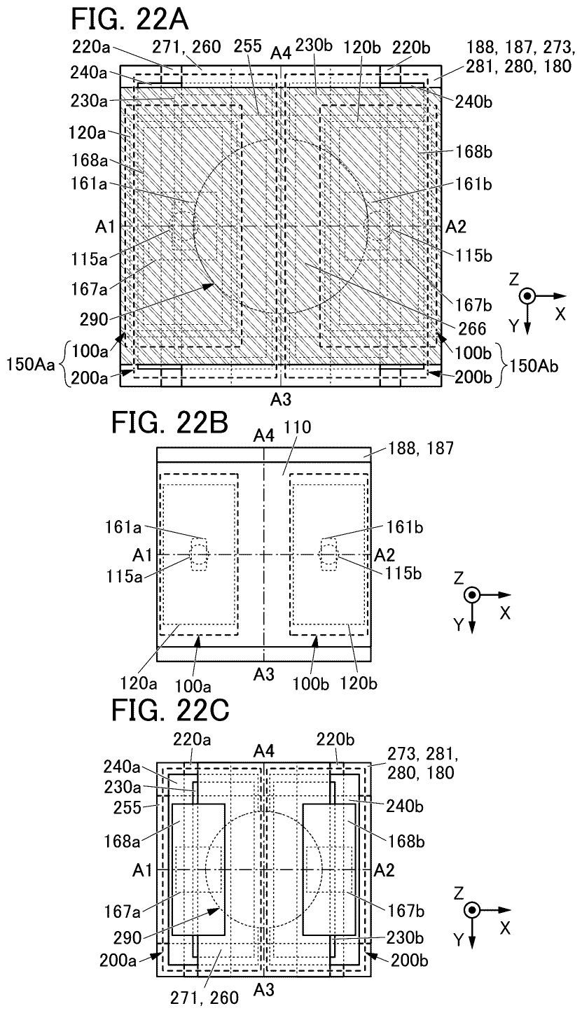

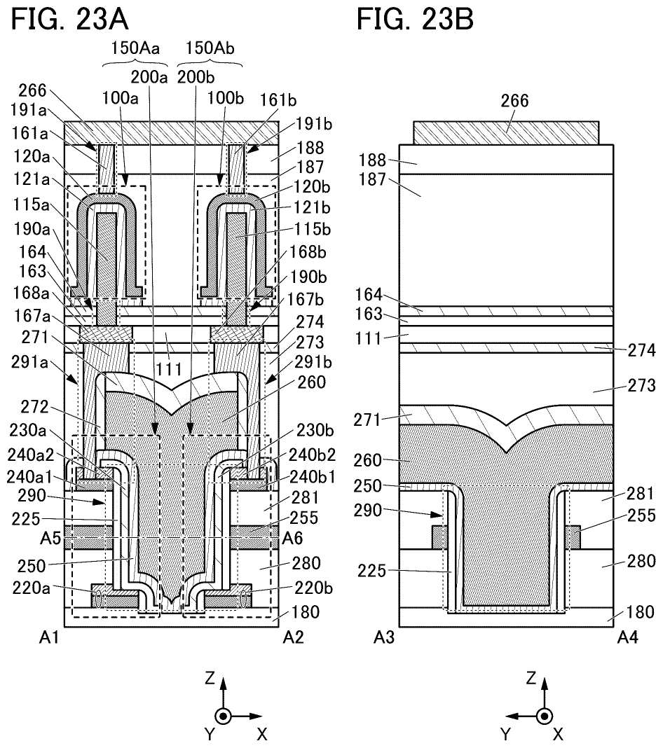

A structure example of a semiconductor device that is different from that illustrated in FIG. 1A to FIG. 2B is described below with reference to FIG. 22A to FIG. 23B. Here, memory cells included in the semiconductor device illustrated in FIG. 22A to FIG. 23B are referred to as a memory cell 150Aa and a memory cell 150Ab. Note that description of the portions already described is omitted and only different portions are described in detail. Even when positions or shapes of components are different from those in the above example, the same reference numerals are used as long as the components have the same functions as those in the above example, and detailed description thereof is omitted in some cases.

FIG. 22A is a plan view illustrating an example of a semiconductor device of one embodiment of the present invention and illustrates the capacitor 100a, the capacitor 100b, the transistor 200a, and the transistor 200b. FIG. 22B is a plan view illustrating examples of the capacitor 100a and the capacitor 100b. FIG. 22C is a plan view illustrating examples of the transistor 200a and the transistor 200b.

FIG. 23A is a cross-sectional view taken along a dashed-dotted line A1-A2 in FIG. 22A, for example. FIG. 23B is a cross-sectional view taken along a dashed-dotted line A3-A4 in FIG. 22A, for example. FIG. 3B can be referred to for a cross-sectional view along a dashed-dotted line A5-A6 in FIG. 23A.

The semiconductor device illustrated in FIG. 22A to FIG. 23B includes the insulating layer 180 over a substrate (not illustrated), the memory cell 150Aa and the memory cell 150Ab over the insulating layer 180, the insulating layer 280, the insulating layer 281, an insulating layer 271, an insulating layer 272, an insulating layer 273, an insulating layer 274, a conductive layer 167a, a conductive layer 167b, the insulating layer 111, a conductive layer 168a, a conductive layer 168b, the insulating layer 163, the insulating layer 164, the insulating layer 187, the insulating layer 188, the conductive layer 161a, the conductive layer 161b, and a conductive layer 266. Here, the top surface of the conductive layer 168a, the top surface of the conductive layer 168b, and the top surface of the insulating layer 111 can be level or substantially level with each other. In FIG. 22A, the conductive layer 266 is shown with a hatching pattern.

The memory cell 150Aa includes the transistor 200a over the insulating layer 180 and the capacitor 100a over the transistor 200a. Similarly, the memory cell 150Ab includes the transistor 200b over the insulating layer 180 and the capacitor 100b over the transistor 200b.

The insulating layer 280 is provided over the conductive layer 220a, the conductive layer 220b, and the insulating layer 180. The insulating layer 281 is provided over the conductive layer 255 and the insulating layer 280. The insulating layer 271 is provided over the conductive layer 260. The insulating layer 272 is provided over the insulating layer 250 to cover the side surface of the conductive layer 260 and the side surface of the insulating layer 271. The insulating layer 273 is provided over the insulating layer 271, the insulating layer 272, and the insulating layer 250. Over the insulating layer 273, the insulating layer 274 is provided. The insulating layer 111 is provided over the insulating layer 274.

An opening portion 291a reaching the conductive layer 240a1 is provided in the insulating layer 274, the insulating layer 273, the insulating layer 250, and the conductive layer 240a2. Furthermore, an opening portion 291b reaching the conductive layer 240b1 is provided in the insulating layer 274, the insulating layer 273, the insulating layer 250, and the conductive layer 240b2. The conductive layer 167a is provided in the opening portion 291a, and the conductive layer 167b is provided in the opening portion 291b. The conductive layer 168a is provided over the conductive layer 167a, and the conductive layer 168b is provided over the conductive layer 167b.

The insulating layer 163 is provided over the conductive layer 168a, the conductive layer 168b, and the insulating layer 111, and the insulating layer 164 is provided over the insulating layer 163. The opening portion 190a reaching the conductive layer 168a and the opening portion 190b reaching the conductive layer 168b are provided in the insulating layer 163 and the insulating layer 164. The conductive layer 115a includes a region in contact with the top surface of the conductive layer 168a in the opening portion 190a. The conductive layer 115b includes a region in contact with the top surface of the conductive layer 168b in the opening portion 190b.

The conductive layer 240a1 and the conductive layer 240a2 are connected to the conductive layer 115a through the conductive layer 167a and the conductive layer 168a. Thus, the source electrode or the drain electrode of the transistor 200a is connected to the lower electrode of the capacitor 100a. Similarly, the conductive layer 240b1 and the conductive layer 240b2 are connected to the conductive layer 115b through the conductive layer 167b and the conductive layer 168b. Thus, the source electrode or the drain electrode of the transistor 200b is connected to the lower electrode of the capacitor 100b. The conductive layer 167a can be in contact with the top surface of the conductive layer 240a1 and the side surface of the conductive layer 240a2. The conductive layer 167b can be in contact with the top surface of the conductive layer 240b1 and the side surface of the conductive layer 240b2. The conductive layer 168a can be in contact with the top surface of the conductive layer 167a. The conductive layer 168b can be in contact with the top surface of the conductive layer 167b.

The conductive layer 266 is provided over the conductive layer 161a, the conductive layer 161b, and the insulating layer 188. The conductive layer 266 can be in contact with the top surface of the conductive layer 161a and the top surface of the conductive layer 161b.

In the example illustrated in FIG. 22A to FIG. 23B, the conductive layer 220a and the conductive layer 220b are provided to extend in the Y direction. The conductive layer 255 is provided to extend in the X direction. The conductive layer 260 is provided to extend in the Y direction. The conductive layer 266 is provided to extend in the X direction.

The conductive layer 220a functions as the wiring BILa. The conductive layer 220b functions as the wiring BILb. The conductive layer 255 functions as one of the wiring WOL and the wiring BGL. The conductive layer 260 functions as the other of the wiring WOL and the wiring BGL. The conductive layer 266 functions as the wiring CAL.

The insulating layer 271, the insulating layer 272, the insulating layer 273, and the insulating layer 274 can be formed to have a single-layer structure or a stacked-layer structure using the insulating material described in the above section [insulating layer]. Here, as each of the insulating layer 271, the insulating layer 272, and the insulating layer 274, an oxygen-barrier insulating layer is preferably used; in this case, the conductive layer 260 can be inhibited from being oxidized and having an increased resistance, for example. For example, it is preferable that silicon nitride be used for the insulating layer 271, the insulating layer 272, and the insulating layer 274. The material that can be used for the insulating layer 187 can be used for the insulating layer 273, for example. For the insulating layer 273, silicon oxide can be used, for example.

The conductive layer 167a, the conductive layer 167b, the conductive layer 168a, the conductive layer 168b, and the conductive layer 266 can be formed to have a single-layer structure or a stacked-layer structure using the conductive material described in the above section [conductive layer]. For the conductive layer 167a, the conductive layer 167b, the conductive layer 168a, and the conductive layer 168b, the materials that can be used for the conductive layer 161a and the conductive layer 161b can be used, for example. The conductive layer 266 can be formed using the material that can be used for the conductive layer 265, for example.

In the semiconductor device including the memory cell 150Aa and the memory cell 150Ab, at least part of the opening portion 290 overlaps with the region between the capacitor 100a and the capacitor 100b, as in the semiconductor device including the memory cell 150a and the memory cell 150b. Thus, the transistor 200a can be provided to include a region overlapping with the capacitor 100a. The transistor 200b can be provided to include a region overlapping with the capacitor 100b. Accordingly, the area occupied by one memory cell 150 can be reduced. Thus, the semiconductor device can be miniaturized or highly integrated.

In the semiconductor device including the memory cell 150Aa and the memory cell 150Ab, the channel formation regions of the transistor 200a and the transistor 200b are provided in the same opening portion 290, as in the semiconductor device including the memory cell 150a and the memory cell 150b. With this structure, the area occupied by the memory cell 150 can be reduced as compared with the case where only one channel formation region of one transistor is provided in a single opening portion 290, for example. Thus, the semiconductor device can be miniaturized or highly integrated.

Furthermore, in the semiconductor device including the memory cell 150Aa and the memory cell 150Ab, the transistor 200a and the transistor 200b are provided to each include a region overlapping with the pillar capacitor, which can have high capacitance even when miniaturized, as in the semiconductor device including the memory cell 150a and the memory cell 150b. That is, both the capacitors and the transistors are easily miniaturized or highly integrated. Accordingly, the semiconductor device can be favorably miniaturized or highly integrated.

### <Example of Method for Manufacturing Semiconductor Device>

Next, a method for manufacturing a semiconductor device of one embodiment of the present invention is described. As for a material and a formation method of each component, portions similar to those described in the above embodiment are not described in some cases.

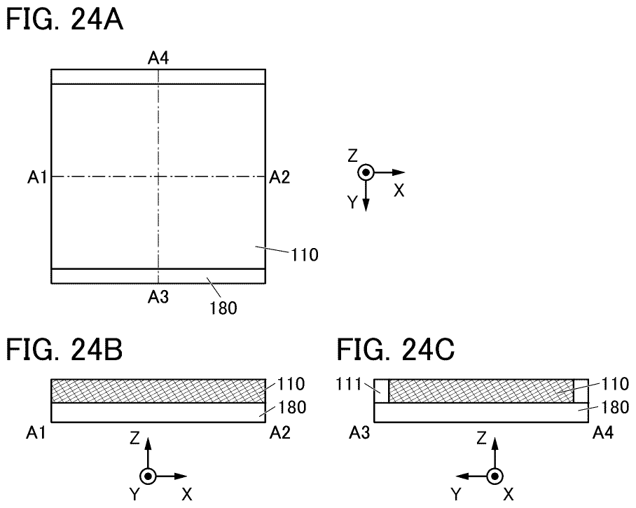

Out of FIG. 24A to FIG. 42C, each of the drawings denoted with A is a plan view, each of the drawings denoted with B is a cross-sectional view taken along a dashed-dotted line A1-A2 in the corresponding drawing, and each of the drawings denoted with C is a cross-sectional view taken along a dashed-dotted line A3-A4 in the corresponding drawing.

Thin films included in the semiconductor device (e.g., insulating films, semiconductor films, and conductive films) can be formed by a sputtering method, a chemical vapor deposition (CVD) method, a vacuum evaporation method, a molecular beam epitaxy (MBE) method, a pulsed laser deposition (PLD) method, an ALD method, or the like.

Examples of the sputtering method include an RF sputtering method in which a high-frequency power source is used for a sputtering power source, a DC sputtering method in which a DC power source is used, and a pulsed DC sputtering method in which voltage applied to an electrode is changed in a pulsed manner. The RF sputtering method is mainly used for forming an insulating film, and the DC sputtering method is mainly used for forming a metal conductive film. A pulsed DC sputtering method is mainly employed in the case where a compound such as an oxide, a nitride, or a carbide is deposited by a reactive sputtering method.

In addition, CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A wiring, an electrode, an element (e.g., a transistor or a capacitor), or the like included in a semiconductor device might be charged up by receiving charge from plasma, for example. In that case, the accumulated charge might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during film formation.

As the ALD method, a thermal ALD method, in which reaction between a precursor and a reactant progresses with only a thermal energy, a PEALD method, in which a reactant excited by plasma is used, or the like can be used.

Moreover, some precursors used in the ALD method contain an element such as carbon or chlorine. Thus, a film formed by the ALD method sometimes contains an element such as carbon or chlorine in a larger quantity than a film formed by another film formation method. Note that these elements can be quantified by XPS or SIMS. The formation method of a metal oxide of one embodiment of the present invention, which employs an ALD method and one or both of a deposition condition with a high substrate temperature and impurity removal treatment, can form a film with smaller quantities of carbon and chlorine than a method employing an ALD method but neither the deposition condition with a high substrate temperature nor the impurity removal treatment in some cases.

Differently from a film formation method in which particles ejected from a target or the like are deposited, a film is formed by reaction at a surface of an object to be processed in an ALD method. Thus, the ALD method can give good step coverage, almost regardless of the shape of an object to be processed. In particular, the ALD method allows excellent step coverage and excellent thickness uniformity and thus can be suitably used to cover a surface of an opening portion with a high aspect ratio, for example.

A CVD method and an ALD method differ from a sputtering method in which particles ejected from a target or the like are deposited. Thus, the CVD method and the ALD method can give good step coverage, almost regardless of the shape of an object to be processed. In particular, the ALD method allows excellent step coverage and excellent thickness uniformity and thus can be suitably used to cover a surface of an opening portion with a high aspect ratio, for example. However, the ALD method has a relatively low film formation rate; hence, in some cases, the ALD method is preferably combined with another film formation method with a high film formation rate, such as a CVD method.

By a CVD method, a film with a desired composition can be formed by adjusting the flow rate ratio of the source gases. For example, a CVD method enables formation of a film whose composition is continuously changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method in which a plurality of kinds of precursors are introduced at the same time enables formation of a film with a desired composition. In the case where a plurality of kinds of precursors are introduced, the number of cycles for each precursor is controlled, whereby a film with a desired composition can be formed.

Alternatively, thin films included in the semiconductor device (e.g., insulating films, semiconductor films, and conductive films) can be formed by a wet process such as a spin coating method, a dip coating method, a spray coating method, an inkjet method, dispensing, screen printing, offset printing, doctor blade coating, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. EUV, X-rays, or an electron beam is preferably used to enable extremely minute processing. When exposure is performed by scanning with a beam such as an electron beam, a photomask is not needed.

For etching of thin films, a dry etching method, a wet etching method, a sandblast method, or the like can be used.

An example of a method for manufacturing the semiconductor device illustrated in FIG. 1A and FIGS. 2A and 2B is described with reference to some drawings.

First, as illustrated in FIGS. 24A to 24C, the insulating layer 180 is formed over a substrate (not illustrated), and the conductive layer 110 and the insulating layer 111 are formed over the insulating layer 180. For example, after the insulating layer 111 is formed over the insulating layer 180, an opening portion reaching the insulating layer 180 is formed in the insulating layer 111. Next, a conductive film to be the conductive layer 110 later is formed to fill the opening portion. After that, planarization treatment is performed on the conductive film until the top surface of the insulating layer 111 is exposed. In this manner, the conductive layer 110 and the insulating layer 111 can be formed. As the planarization treatment, treatment using a chemical mechanical polishing (CMP) method (also referred to as CMP treatment) is suitable.

The conductive layer 110 may be formed by a photolithography method. In that case, the insulating layer 111 is not necessarily formed.

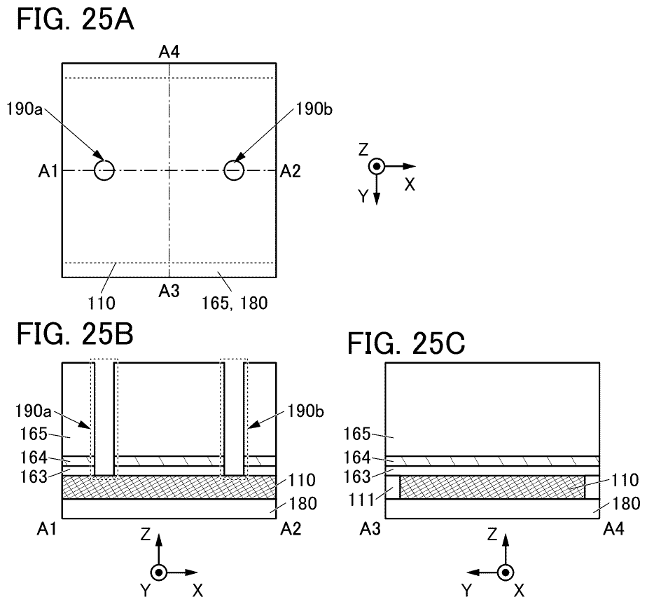

Next, as illustrated in FIGS. 25A to 25C, the insulating layer 163 is formed over the conductive layer 110 and the insulating layer 111, the insulating layer 164 is formed over the insulating layer 163, and a sacrificial layer 165 is formed over the insulating layer 164. Then, as illustrated in FIGS. 25A to 25C, the sacrificial layer 165, the insulating layer 164, and the insulating layer 163 are processed to form the opening portion 190a and the opening portion 190b reaching the conductive layer 110. In order to form the opening portion 190a and the opening portion 190b each having a high aspect ratio, the sacrificial layer 165, the insulating layer 164, and the insulating layer 163 are preferably processed by anisotropic etching. It is particularly preferable to use a dry etching method because it is suitable for microfabrication.

Although the details will be described later, the height H1 illustrated in FIG. 4A is determined by the thickness of the sacrificial layer 165. Therefore, the thickness of the sacrificial layer 165 is preferably large in order to increase the capacitance of the capacitors that are being formed. Specifically, the thickness of the sacrificial layer 165 is preferably larger than the thickness of the insulating layer 163 and the thickness of the insulating layer 164. Meanwhile, in the case where the thickness of the sacrificial layer 165 is too large compared with the total thickness of the insulating layer 163 and the insulating layer 164, the conductive layer 115a and the conductive layer 115b might fall down after the conductive layer 115a and the conductive layer 115b are embedded in the opening portion 190a and the opening portion 190b and the sacrificial layer 165 is removed in later steps. Therefore, in order to increase the manufacturing yield of the semiconductor device, it is preferable that the thickness of the sacrificial layer 165 not be too large compared with the total thickness of the insulating layer 163 and the insulating layer 164.

Any of the materials that can be used for the insulating layer 163 can be used for the sacrificial layer 165, for example. For the sacrificial layer 165, any of the materials that can be used for the insulating layer 111 or the insulating layer 180 may be used. Meanwhile, the insulating layer 164 functions as an etching stop film at the time of removing the sacrificial layer 165 in a later step, which will be described in detail later. Thus, a material different from that for the insulating layer 164 is used for the sacrificial layer 165. Specifically, a material having high etching selectivity with respect to the insulating layer 164 is used for the sacrificial layer 165. For example, in the case where silicon nitride is used for the insulating layer 164, silicon oxide is preferably used for the sacrificial layer 165.

In the case where the insulating layer 163 is formed under the insulating layer 164, the height H2 illustrated in FIG. 4A can be increased as compared with the case where the insulating layer 163 is not formed. Thus, the above-described conductive layers 115a and 115b can be prevented from falling down in a later step while the height H1 is increased. Thus, a semiconductor device with a high manufacturing yield and a stable read operation can be manufactured. Note that formation of the insulating layer 163 may be omitted if an enough height H2 can be ensured to prevent the conductive layer 115a and the conductive layer 115b from falling down without the insulating layer 163. In that case, the number of manufacturing steps of the semiconductor device can be reduced as compared with case where the insulating layer 163 is formed.

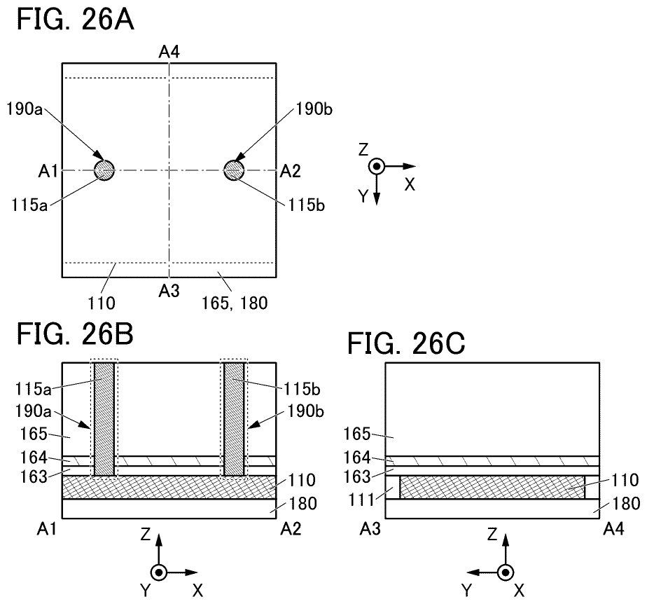

Next, as illustrated in FIGS. 26A to 26C, the conductive layer 115a is formed to fill the opening portion 190a, and the conductive layer 115b is formed to fill the opening portion 190b. For example, a conductive film to be the conductive layer 115a and the conductive layer 115b later is formed over the sacrificial layer 165 and the conductive layer 110. Then, planarization treatment is performed on the conductive film until the top surface of the sacrificial layer 165 is exposed. As the planarization treatment, CMP treatment is suitable. In the above-described manner, the conductive layer 115a and the conductive layer 115b can be formed. The conductive layer 115a and the conductive layer 115b are formed in contact with the conductive layer 110.

The conductive film to be the conductive layer 115a and the conductive layer 115b is formed in the opening portion 190a and the opening portion 190b each having a high aspect ratio. Thus, the conductive film is preferably formed by a film formation method offering favorable coverage, and is further preferably formed by a CVD method or an ALD method.

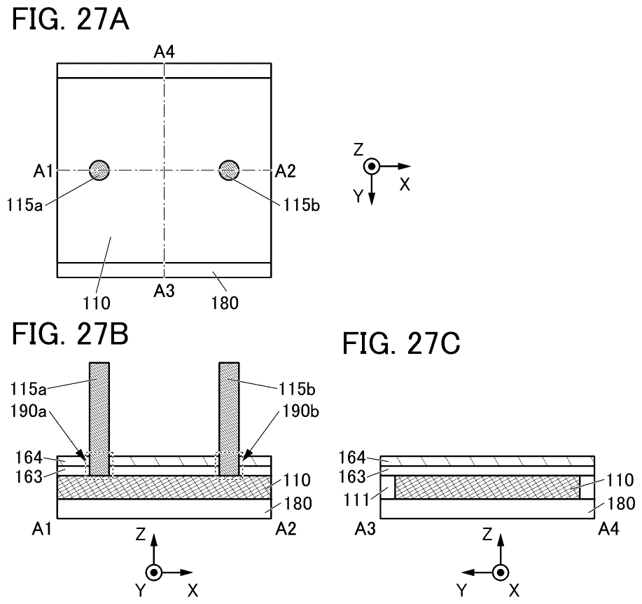

Next, as illustrated in FIGS. 27A to 27C, the sacrificial layer 165 is removed. The sacrificial layer 165 can be removed by an etching method, for example, specifically a wet etching method. Here, in the case where a material having high etching selectivity with respect to the sacrificial layer 165 is used for the insulating layer 164, the insulating layer 164 functions as an etching stop film. This can inhibit removal of at least part of the insulating layer 164. Thus, a decrease in the height H2 illustrated in FIG. 4A can be inhibited, which leads to an increase in the manufacturing yield of the semiconductor device.

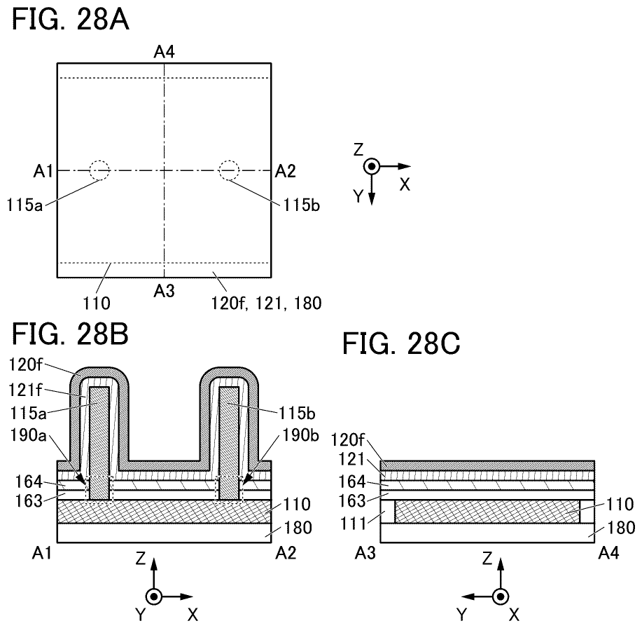

Next, as illustrated in FIGS. 28A to 28C, an insulating film 121f to be the insulating layer 121a and the insulating layer 121b later is formed to cover the conductive layer 115a and the conductive layer 115b. Then, a conductive film 120f to be the conductive layer 120a and the conductive layer 120b later is formed over the insulating film 121f. The insulating film 121f and the conductive film 120f are formed to cover the conductive layer 115a and the conductive layer 115b each having a high aspect ratio. Thus, the insulating film 121f and the conductive film 120f are preferably formed by a film formation method offering favorable coverage, further preferably by a CVD method, an ALD method, or the like.

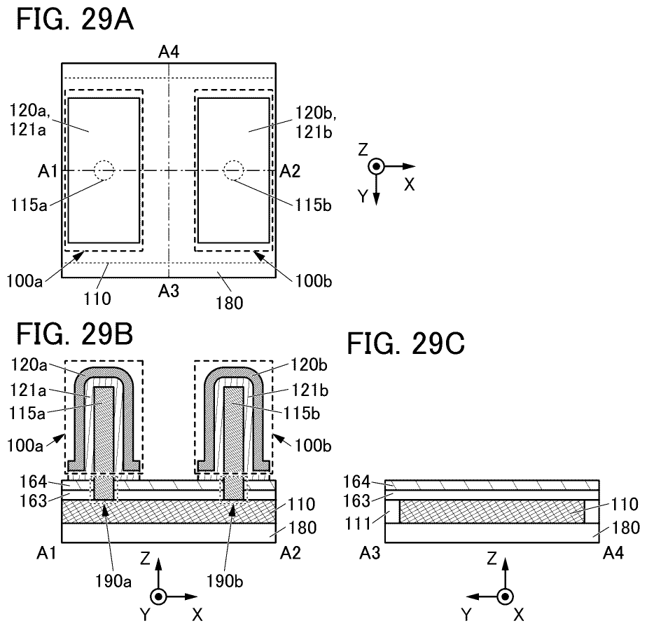

Next, as illustrated in FIGS. 29A to 29C, the insulating film 121f and the conductive film 120f are processed. The insulating film 121f is processed to form the insulating layer 121a and the insulating layer 121b. The conductive film 120f is processed to form the conductive layer 120a and the conductive layer 120b. In the above-described manner, the capacitor 100a and the capacitor 100b can be formed.

As described above, after the sacrificial layer 165 is removed, the conductive layer 120a is formed to cover a region of the conductive layer 115a that had been covered with the sacrificial layer 165, for example. Therefore, the height H1 illustrated in FIG. 4A is determined by the thickness of the sacrificial layer 165.

The conductive film 120f and the insulating film 121f can be processed by a photolithography method. Here, the conductive film 120f and the insulating film 121f are preferably processed using the same photomask, in which case the number of steps can be reduced as compared with the case where the conductive film 120f and the insulating film 121f are processed using different photomasks. Note that in the case of manufacturing the semiconductor device illustrated in FIGS. 6A and 6B, the insulating film 121f is not processed, whereby the insulating film 121f can be the insulating layer 121 illustrated in FIGS. 6A and 6B.

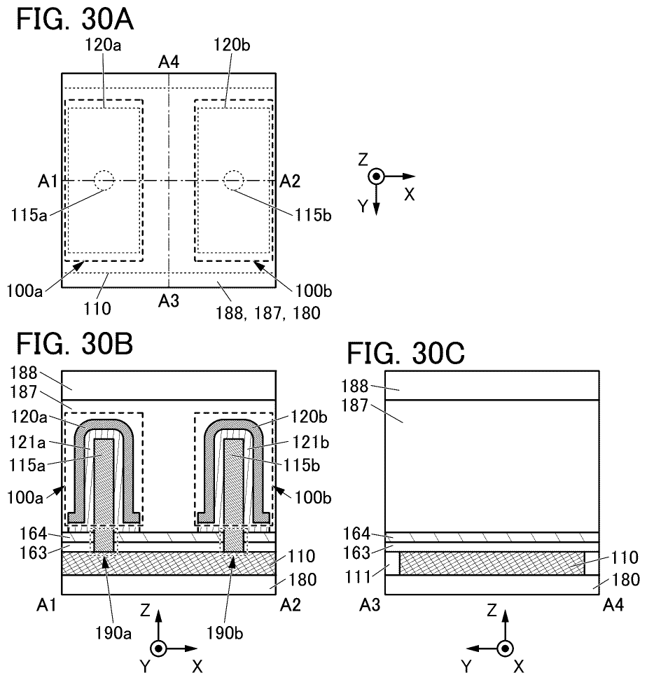

Next, as illustrated in FIGS. 30A to 30C, the insulating layer 187 is formed to cover the capacitor 100a and the capacitor 100b, and the insulating layer 188 is formed over the insulating layer 187. The insulating layer 187 is formed over the conductive layer 120a, the conductive layer 120b, and the insulating layer 164 to fill the region between the capacitors 100.

After the formation of the insulating layer 187, planarization treatment is preferably performed by a CMP method or the like to planarize the top surface of the insulating layer 187. In the case where the planarization treatment is performed on the insulating layer 187, the top surface of the insulating layer 188 can be formed to be planar, which allows the formation surface of the transistor 200a and the transistor 200b formed over the insulating layer 188 in a later step to be planar. This facilitates formation of the transistor 200a and the transistor 200b in later steps. For example, disconnection of the conductive layer 220a, the conductive layer 220b, the oxide semiconductor layer 230a, the oxide semiconductor layer 230b, and the insulating layer 250 that are formed in later steps can be prevented. Accordingly, a method for manufacturing a semiconductor device with high yield can be provided. Note that without planarization treatment on the insulating layer 187, planarization treatment may be performed on the insulating layer 188. Alternatively, both the planarization treatment on the insulating layer 187 and the planarization treatment on the insulating layer 188 may be omitted.

The insulating layer 187 is preferably formed using a material which allows deposition at a deposition rate higher than the deposition rate of the insulating layer 188. The insulating layer 188 is preferably formed using a material that can inhibit entry of impurities into the transistor 200a and the transistor 200b that are formed in later steps. The insulating layer 188 is preferably formed using a material having a barrier property against hydrogen, for example. For example, it is preferable that a silicon oxide film be formed as the insulating layer 187 and a silicon nitride film be formed as the insulating layer 188.

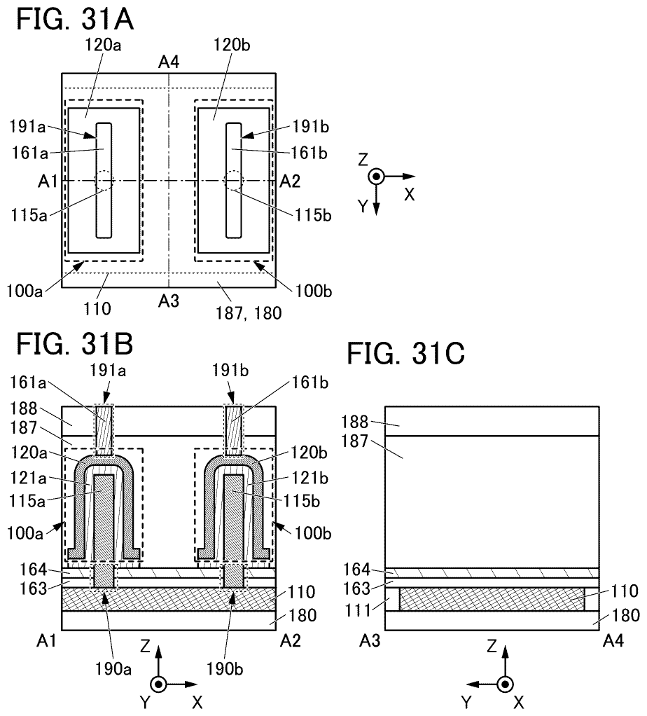

Next, as illustrated in FIGS. 31A to 31C, the opening portion 191a reaching the conductive layer 120a and the opening portion 191b reaching the conductive layer 120b are formed in the insulating layer 188 and the insulating layer 187. Then, the conductive layer 161a is formed to fill the opening portion 191a, and the conductive layer 161b is formed to fill the opening portion 191b. For example, a conductive film to be the conductive layer 161a and the conductive layer 161b later is formed over the conductive layer 120a, the conductive layer 120b, and the insulating layer 188. Next, planarization treatment is performed on the conductive film until the top surface of the insulating layer 188 is exposed. As the planarization treatment, CMP treatment is suitable. In the above-described manner, the conductive layer 161a and the conductive layer 161b can be formed. The conductive layer 161a is formed in contact with the conductive layer 120a, and the conductive layer 161b is formed in contact with the conductive layer 120b.

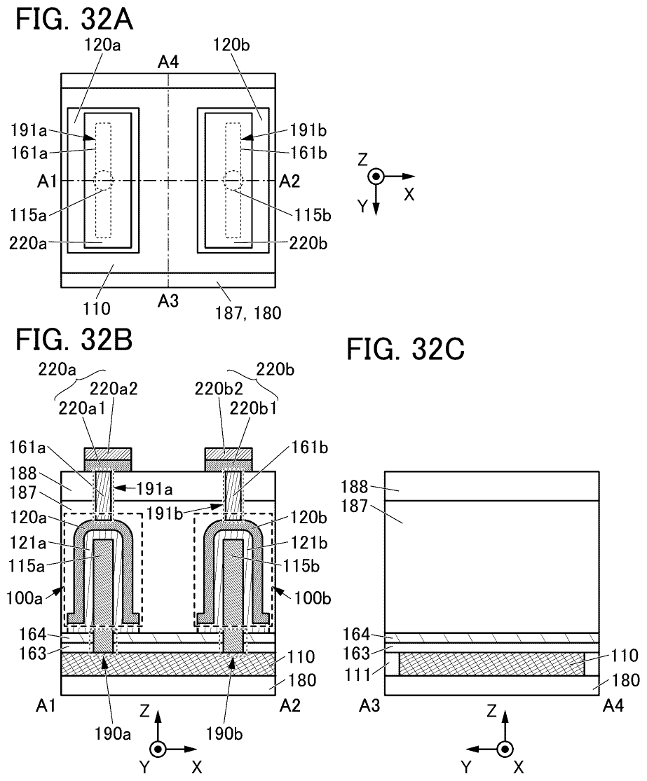

Then, as illustrated in FIGS. 32A to 32C, the conductive layer 220a is formed over the conductive layer 161a and the insulating layer 188, and the conductive layer 220b is formed over the conductive layer 161b and the insulating layer 188. For example, a first conductive film to be the conductive layer 220a1 and the conductive layer 220b1 later is formed, and a second conductive film to be the conductive layer 220a2 and the conductive layer 220b2 later is formed over the first conductive film. Then, the first conductive film and the second conductive film are processed so that the conductive layer 220a including the conductive layer 220a1 and the conductive layer 220a2 and the conductive layer 220b including the conductive layer 220b1 and the conductive layer 220b2 can be formed. The conductive layer 220a is formed to include a region in contact with the top surface of the conductive layer 161a. The conductive layer 220b is formed to include a region in contact with the top surface of the conductive layer 161b.

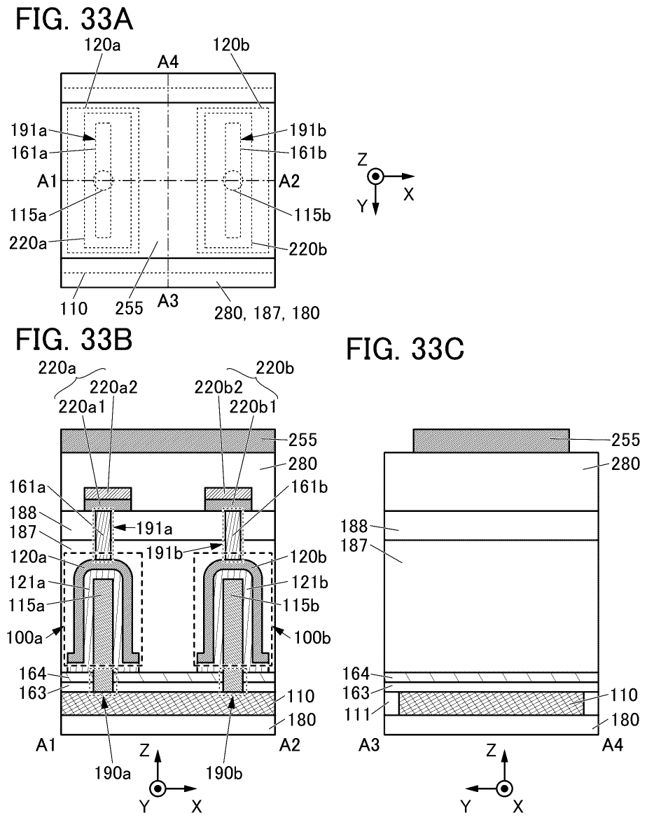

Next, as illustrated in FIGS. 33A to 33C, the insulating layer 280 is formed over the conductive layer 220a, the conductive layer 220b, and the insulating layer 188. Planarization treatment by a CMP method or the like is preferably performed after formation of the insulating layer 280 to planarize the top surface of the insulating layer 280. By the planarization treatment of the insulating layer 280, a surface over which the conductive layer 255 functioning as a wiring is to be formed can be made flat, whereby disconnection of the conductive layer 255 can be inhibited. Incidentally, it is acceptable that the planarization treatment is not performed, in which case the manufacturing cost can be reduced.

Next, as illustrated in FIGS. 33A to 33C, the conductive layer 255 is formed over the insulating layer 280. The conductive layer 255 is preferably formed by a sputtering method, for example. By using a sputtering method that does not need to use a molecule containing hydrogen as a deposition gas, the hydrogen concentration in the conductive layer 255 can be reduced and entry of hydrogen into the oxide semiconductor layer 230 can be inhibited.

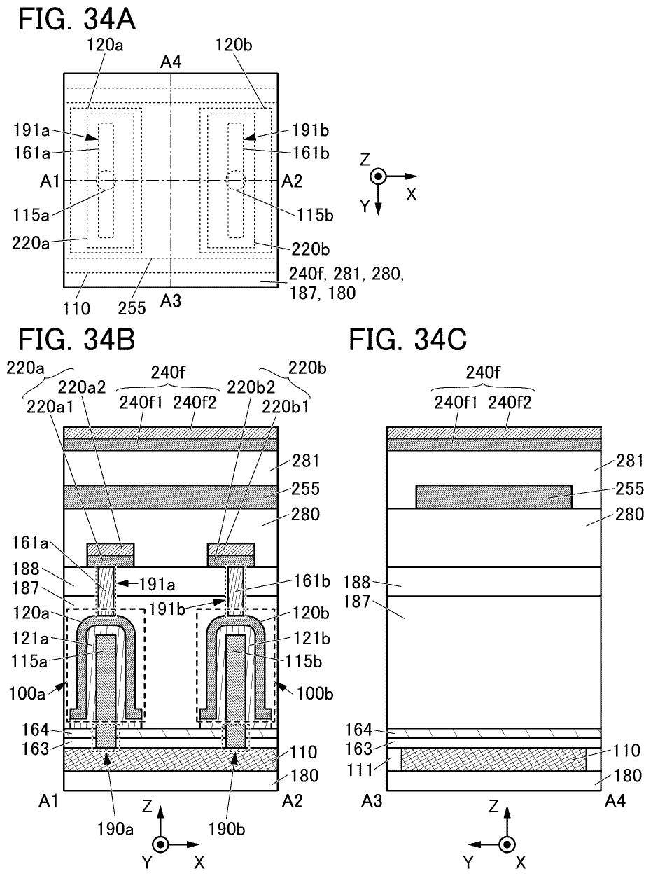

Next, as illustrated in FIGS. 34A to 34C, the insulating layer 281 is formed over the conductive layer 255 and the insulating layer 280. Planarization treatment by a CMP method or the like is preferably performed after formation of the insulating layer 281 to planarize the top surface of the insulating layer 281. By the planarization treatment of the insulating layer 281, surfaces over which the conductive layers 240a and 240b are to be formed can be made flat, whereby disconnection of each of the conductive layers 240a and 240b can be inhibited. Incidentally, it is acceptable that the planarization treatment is not performed, in which case the manufacturing cost can be reduced.

Next, as illustrated in FIGS. 34A to 34C, a conductive film 240f1 is formed over the insulating layer 281, and a conductive film 240f2 is formed over the conductive film 240f1. The conductive film 240f1 is a conductive film to be the conductive layer 240a1 and the conductive layer 240b1 later. The conductive film 240f2 is a conductive film to be the conductive layer 240a2 and the conductive layer 240b2 later. Hereinafter, the conductive film 240f1 and the conductive film 240f2 may be collectively referred to as a conductive film 240f.

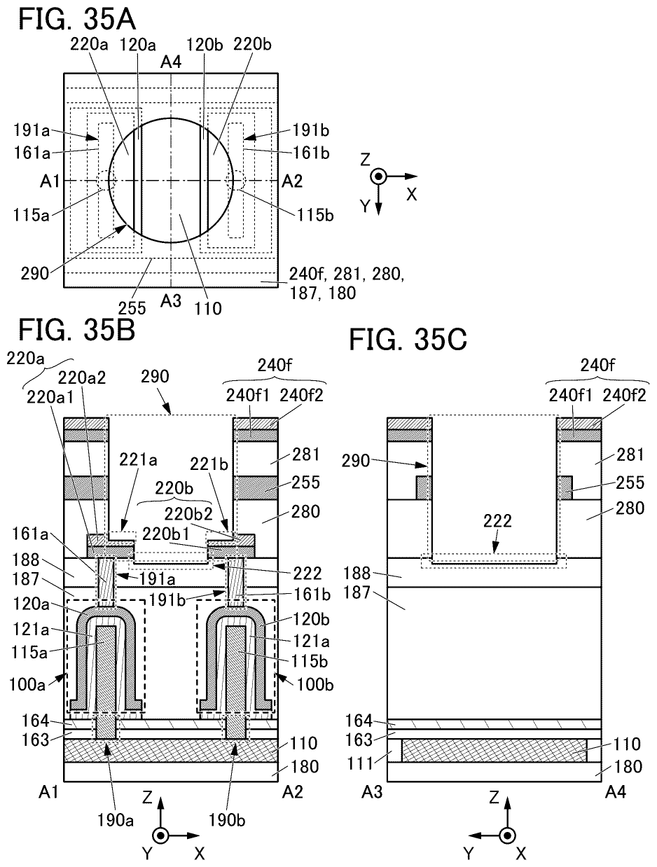

Then, as illustrated in FIGS. 35A to 35C, the opening portion 290 is formed in the conductive film 240f, the insulating layer 281, the conductive layer 255, and the insulating layer 280. The opening portion 290 is formed so that at least part of the top surface of each of the conductive layer 220a2, the conductive layer 220b2, and the insulating layer 188 is exposed. In this case, the depressed portion 221a and the depressed portion 221b are preferably provided at respective positions of the conductive layer 220a2 and the conductive layer 220b2 overlapping with the opening portion 290. By forming the opening portion 290, the bottom portion and the sidewall of each of the depressed portion 221a and the depressed portion 221b are preferably exposed. In the insulating layer 188, the depressed portion 222 is provided at a position that overlaps with the opening portion 290 and is between the conductive layer 220a and the conductive layer 220b in some cases.

For microfabrication and a reduction in transistor size, in forming the opening portion 290, parts of the conductive layer 220a2 and the conductive layer 220b2, part of the insulating layer 280, part of the conductive layer 255, and part of the conductive film 240f are preferably processed using anisotropic etching. It is particularly preferable to use a dry etching method, which is suitable for microfabrication. The opening portion 290 may be formed under processing conditions different between layers. Depending on the materials, processing conditions, and the like of the conductive layers 220a2 and 220b2, the insulating layer 280, the conductive layer 255, the insulating layer 281, the conductive film 240f1, and the conductive film 240f2, the inclinations of the side surfaces of the conductive layers 220a2 and 220b2, the inclination of the side surface of the insulating layer 280, the inclination of the side surface of the conductive layer 255, the inclination of the side surface of the insulating layer 281, the inclination of the side surface of the conductive film 240f1, and the inclination of the side surface of the conductive film 240f2 may be different from each other in the opening portion 290.

In the formation step of the opening portion 290 or the like, a region containing a halogen element is sometimes provided in at least one of the bottom portions and the sidewalls of the depressed portion 221a and the depressed portion 221b, the side surface of the insulating layer 280, the side surface of the conductive layer 255, the side surface of the insulating layer 281, the side surface of the conductive film 240f1, and the top surface and the side surface of the conductive film 240f2. Examples of the region include a region containing fluorine, a region containing chlorine, and a region containing fluorine and chlorine. In some cases, a halogen element originating from an etching gas used in dry etching remains in the region, for example.

Subsequently, heat treatment is preferably performed. The heat treatment is performed, for example, at higher than or equal to 250° C. and lower than or equal to 650° C., preferably higher than or equal to 300° C. and lower than or equal to 500° C., further preferably higher than or equal to 320° C. and lower than or equal to 450° C.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as hydrogen or water contained in the insulating layer 280 or the like can be reduced before the oxide semiconductor layer 230 is formed.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the insulating layer 280 or the like as much as possible.

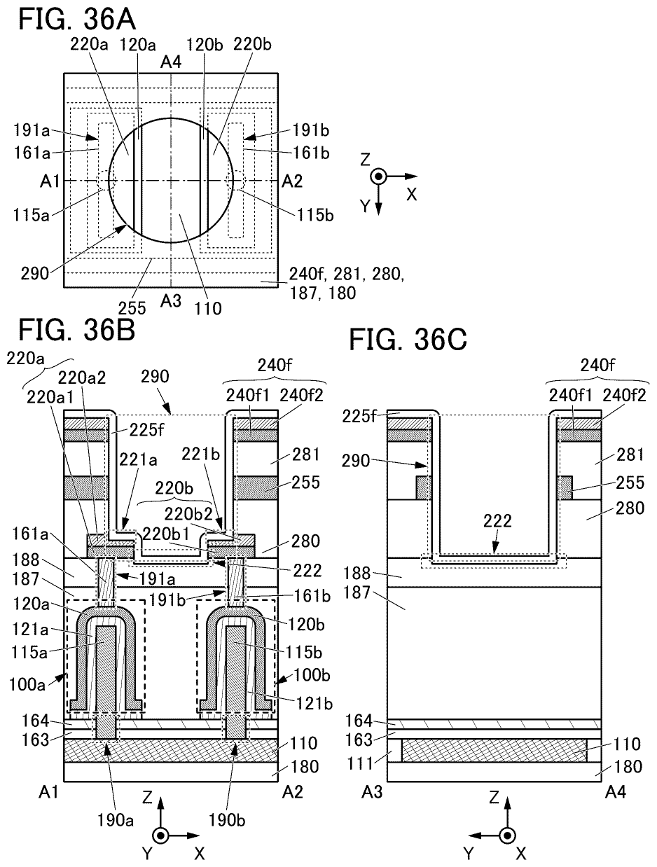

Next, as illustrated in FIGS. 36A to 36C, an insulating film 225f to be the insulating layer 225 later is formed to cover the opening portion 290. The insulating film 225f is formed in contact with an exposed part of the top surface of the insulating layer 188 (the bottom portion and the sidewall of the depressed portion 222 in the case where the insulating layer 188 includes the depressed portion 222 at a position overlapping with the opening portion 290), the bottom portions and the sidewalls of the depressed portion 221a and the depressed portion 221b, the side surface of the insulating layer 280, the side surface of the conductive layer 255, the side surface of the insulating layer 281, the side surface of the conductive film 240f1, and the top surface and the side surface of the conductive film 240f2.

Because the insulating film 225f is provided in the opening portion 290, the insulating film 225f is preferably formed by a CVD method or an ALD method, further preferably formed by an ALD method. In this manner, the insulating film 225f can be formed with good coverage.

In this embodiment, a first insulating film and a second insulating film are formed in this order as the insulating film 225f by an ALD method. For example, a silicon nitride film is formed by a PEALD method as the first insulating film, and a silicon oxide film is formed by a PEALD method as the second insulating film. In that case, the first insulating film and the second insulating film are preferably successively formed without exposure to the air. Forming the first insulating film and the second insulating film successively without exposure to the air can lead to an increase in productivity. Furthermore, impurities (typically, moisture or the like) that would be taken into the interface between the first insulating film and the second insulating film and the vicinity thereof can be reduced.

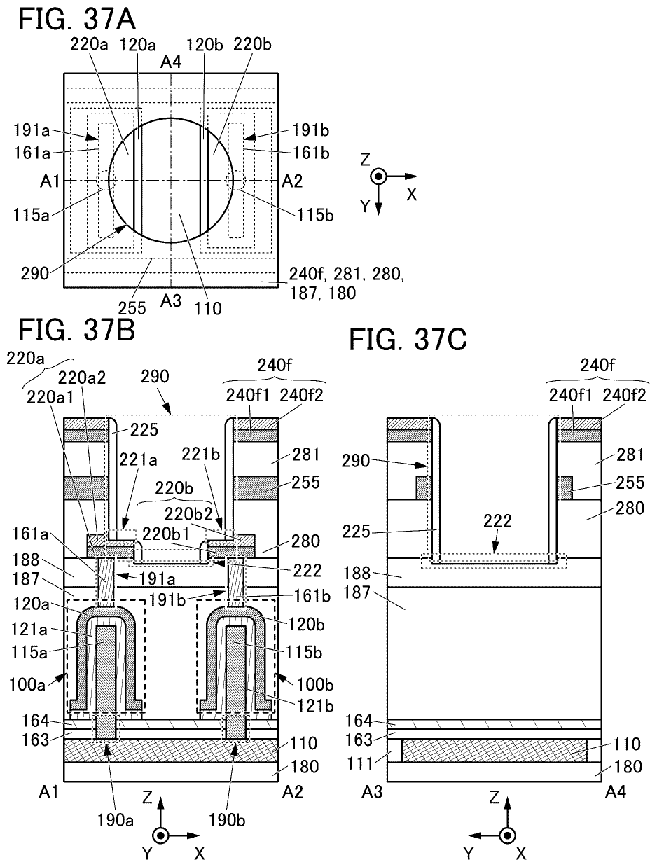

Then, as illustrated in FIGS. 37A to 37C, the insulating film 225f is processed so that the top surface of the conductive film 240f2 is exposed, and the conductive layer 220a2, the conductive layer 220b2, and the insulating layer 188 are exposed in the opening portion 290. In the opening portion 290, the bottom portion of the depressed portion 221a and the bottom portion of the depressed portion 221b are preferably exposed.

By processing the insulating film 225f by anisotropic etching, a region of the insulating film 225f that is positioned on the top surface of the conductive film 240f2 and a region of the insulating film 225f that is positioned on the bottom portion of the opening portion 290 are removed. In this manner, the insulating film 225f can remain only on the side surface of the opening portion 290. In the opening portion 290, the insulating layer 225 formed in this manner includes a region in contact with the top surface of the conductive layer 220a, a region in contact with the top surface of the conductive layer 220b, a region in contact with the side surface of the insulating layer 280, a region in contact with the side surface of the conductive layer 255, a region in contact with the side surface of the insulating layer 281, and a region in contact with the side surface of the conductive film 240f, a region in contact with the top surface of the insulating layer 188, a region in contact with the side surface of the conductive layer 220al, and a region in contact with the side surface of the conductive layer 220b1, for example. The insulating film 225f is preferably processed by anisotropic etching using a dry etching method.

As described with reference to FIG. 7B, in processing of the insulating film 225f, parts of the conductive layers 220a2 and 220b2 may be removed, and thus, depressed portions (the above-described first depressed portions) may be provided in the conductive layers 220a2 and 220b2.

It is preferable to perform oxygen supply before processing the insulating film 225f that has been formed (see FIGS. 36A to 36C). Accordingly, oxygen can be supplied to the second insulating film, and oxygen can be supplied from the second insulating film to the oxide semiconductor layer 230 owing to heat to be applied after the formation of the oxide semiconductor layer 230, for example. Providing the first insulating film having a barrier property against oxygen can inhibit diffusion of oxygen into the conductive layer 220 and the conductive layer 240 to prevent reductions in conductivities of the conductive layer 220 and the conductive layer 240. Accordingly, the range of choices for the materials of the conductive layer 220 and the conductive layer 240 can be widened.

Alternatively, oxygen may be supplied after the insulating film 225f is processed (see FIGS. 37A to 37C). Accordingly, oxygen can be supplied to the second insulating film, and oxygen can be supplied from the second insulating film to the oxide semiconductor layer 230 owing to heat to be applied after the formation of the oxide semiconductor layer 230, for example. Furthermore, the use of oxide conductors for the conductive layer 220a2, the conductive layer 220b2, and the conductive film 240f2 can inhibit reductions in the conductivities of the conductive layer 220a2, the conductive layer 220b2, and the conductive film 240f2 even when oxygen is supplied after the second insulating film is processed.

Examples of the treatment for supplying oxygen include heat treatment in an oxygen-containing atmosphere and plasma treatment in an oxygen-containing atmosphere (including microwave plasma treatment). Alternatively, an oxide film (preferably a metal oxide film) may be formed by a sputtering method in an oxygen-containing atmosphere to supply oxygen to the second insulating film. The formed oxide film may be removed immediately or left as it is. In the case where the formed oxide film is left as it is, the oxide film can be used as part of the oxide semiconductor layer. An oxygen-containing atmosphere can include not only an oxygen gas (O₂) but also a gas of an oxygen-containing compound such as ozone (O₃) or dinitrogen monoxide (N₂O). The substrate temperature in the plasma treatment is higher than or equal to room temperature (25° C.) and lower than or equal to 450° C.

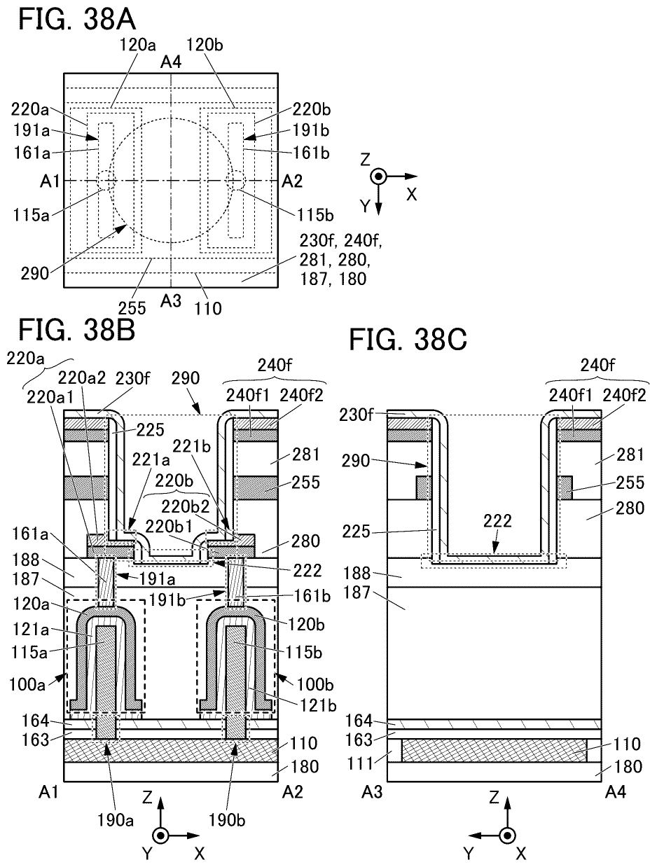

Then, as illustrated in FIGS. 38A to 38C, an oxide semiconductor film 230f to be the oxide semiconductor layers 230a and 230b later is formed to cover the opening portion 290. The oxide semiconductor film 230f is provided in contact with the bottom portion and the sidewall of the depressed portion 221a, the bottom portion and the sidewall of the depressed portion 221b, the exposed part of the top surface of the insulating layer 188, the side surface of the insulating layer 225, the side surface of the conductive film 240f1, and the top surface and the side surface of the conductive film 240f2.

The description in Embodiment 2 can be referred to for the formation method of the oxide semiconductor film 230f.

As the oxide semiconductor film 230f, a first oxide semiconductor film, a second oxide semiconductor film, and a third oxide semiconductor film can be formed in this order, for example. The first oxide semiconductor film is an oxide semiconductor film to be the oxide semiconductor layers 230a1 and 230b1 illustrated in FIG. 14B, the second oxide semiconductor film is an oxide semiconductor film to be the oxide semiconductor layers 230a2 and 230b2 illustrated in FIG. 14B, and the third oxide semiconductor film is an oxide semiconductor film to be the oxide semiconductor layer 230a3 and 230b3 illustrated in FIG. 14B.

For example, an In—Ga—Zn oxide film is formed by a thermal ALD method as the first oxide semiconductor film. An indium oxide film is formed by a thermal ALD method as the second oxide semiconductor film. An In—Ga—Zn oxide film is formed by a sputtering method as the third oxide semiconductor film.

The first oxide semiconductor film and the second oxide semiconductor film are preferably successively formed without exposure to the air. When the first oxide semiconductor film and the second oxide semiconductor film are successively formed without exposure to the air, the productivity can be increased. Furthermore, impurities (typically, moisture or the like) taken into the interface between the first oxide semiconductor film and the second oxide semiconductor film and the vicinity of the interface can be reduced.

After formation of the second oxide semiconductor film, oxygen may be supplied to the second oxide semiconductor film. Accordingly, oxygen can be supplied to the oxide semiconductor layer 230 by heat or the like to be applied after the treatment. For the details of the treatment for supplying oxygen, the above description can be referred to.

Next, heat treatment is preferably performed. The heat treatment temperature is, for example, preferably higher than or equal to 100° C. and lower than or equal to 650° C., further preferably higher than or equal to 250° C. and lower than or equal to 600° C., still further preferably higher than or equal to 350° C. and lower than or equal to 550° C. For the details of the heat treatment, the above description can be referred to.

The gas used in the above heat treatment is preferably highly purified. The heat treatment using a highly purified gas can, for example, prevent entry of moisture or the like into the oxide semiconductor layer 230 as much as possible.

By the heat treatment, impurities such as carbon, hydrogen, or water in the oxide semiconductor layer 230 can be reduced. Impurities in the film are reduced in this manner, whereby the crystallinity of the oxide semiconductor layer 230 can be improved and a highly dense structure can be obtained. Accordingly, the crystal region in the oxide semiconductor layer 230 can be increased, and an in-plane variation in the crystal region in the oxide semiconductor layer 230 can be reduced. Thus, in-plane variation in the electrical characteristics of the transistors can be reduced.

In the case where the second insulating film in the insulating layer 225 contains oxygen, oxygen is preferably supplied from an insulating layer containing the oxygen to the channel formation region of the oxide semiconductor layer 230 by the heat treatment. Accordingly, oxygen vacancies and V_{O}H can be reduced.

As described above, excess oxygen is sometimes supplied from the insulating layer in contact with the oxide semiconductor layer 230 to the oxide semiconductor layer 230. Since excess oxygen has a function of trapping electrons, a negative charge is likely to be formed. Accordingly, the threshold voltage of the transistor can be shifted positively to enable the transistor to have normally-off characteristics.

Note that microwave plasma treatment may be performed after formation of the second oxide semiconductor film or the third oxide semiconductor film. The microwave plasma treatment can reduce the concentration of impurities such as hydrogen or water contained in the oxide semiconductor layer 230. In addition, the crystal region of the oxide semiconductor layer 230 grows in some cases. The details of the microwave plasma treatment will be described in Embodiment 2.

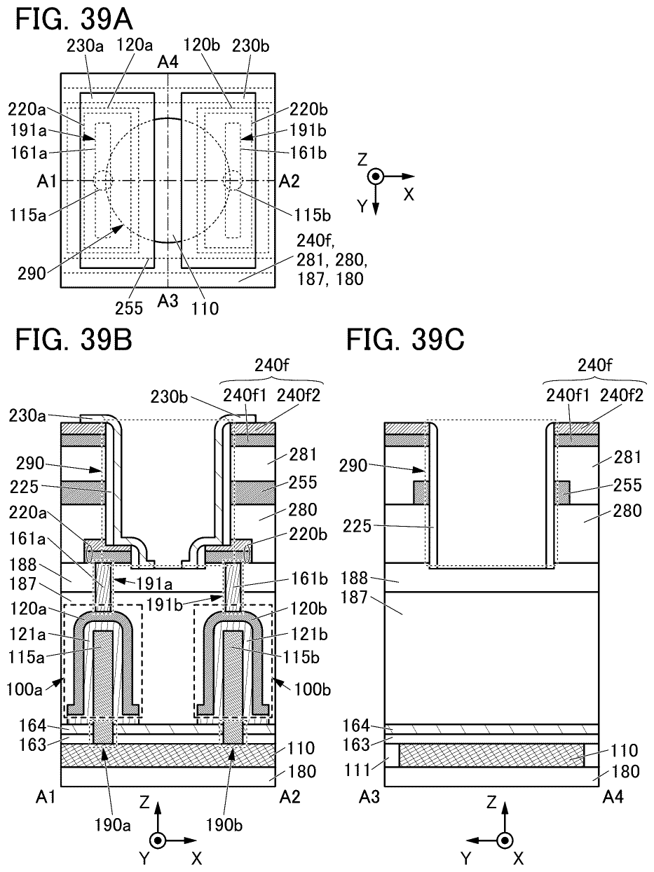

Next, as illustrated in FIGS. 39A to 39C, the oxide semiconductor film 230f is processed into an island shape to expose part of the top surface of the conductive film 240f2 and part of the top surface of the insulating layer 188 at a position overlapping with the opening portion 290. Through this processing, the oxide semiconductor layer 230a and the oxide semiconductor layer 230b are formed.

As illustrated in FIGS. 39A to 39C, the above processing is preferably performed so that only the top surface of the insulating layer 188 and the insulating layer 225 are exposed in the opening portion 290. In other words, the processing is preferably performed so that the conductive layer 220a and the conductive layer 220b are not exposed in the opening portion 290. Accordingly, only the insulating layer 188 serves as a base film at the time of the above processing, in which case the oxide semiconductor film 230f can be processed relatively easily.

In order to remove impurities and the like attached to the surface of the oxide semiconductor layer 230 in the processing, cleaning treatment is preferably performed. Examples of the cleaning method include wet cleaning using a cleaning solution or the like (which can also be referred to as wet etching treatment), plasma treatment using plasma, and cleaning by heat treatment, and any of these cleaning methods may be combined as appropriate.

The wet cleaning may be performed using an aqueous solution in which one or more of ammonia water, oxalic acid, phosphoric acid, and hydrofluoric acid are diluted with carbonated water or pure water. The wet cleaning may be performed using pure water, carbonated water, or the like. Alternatively, ultrasonic cleaning using such an aqueous solution, pure water, or carbonated water may be performed, or such cleaning methods may be performed in combination as appropriate.

Note that in this specification and the like, in some cases, an aqueous solution in which hydrofluoric acid is diluted with pure water or carbonated water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

A frequency greater than or equal to 200 kHz is preferably used for the ultrasonic cleaning, and a frequency greater than or equal to 900 kHz is further preferably used. Employing such a frequency can reduce damage to the oxide semiconductor layer 230 and the like.

The cleaning treatment may be performed multiple times, and the cleaning solution may be changed in every cleaning treatment. For example, the first cleaning treatment may use diluted hydrofluoric acid or diluted ammonia water and the second cleaning treatment may use pure water or carbonated water.

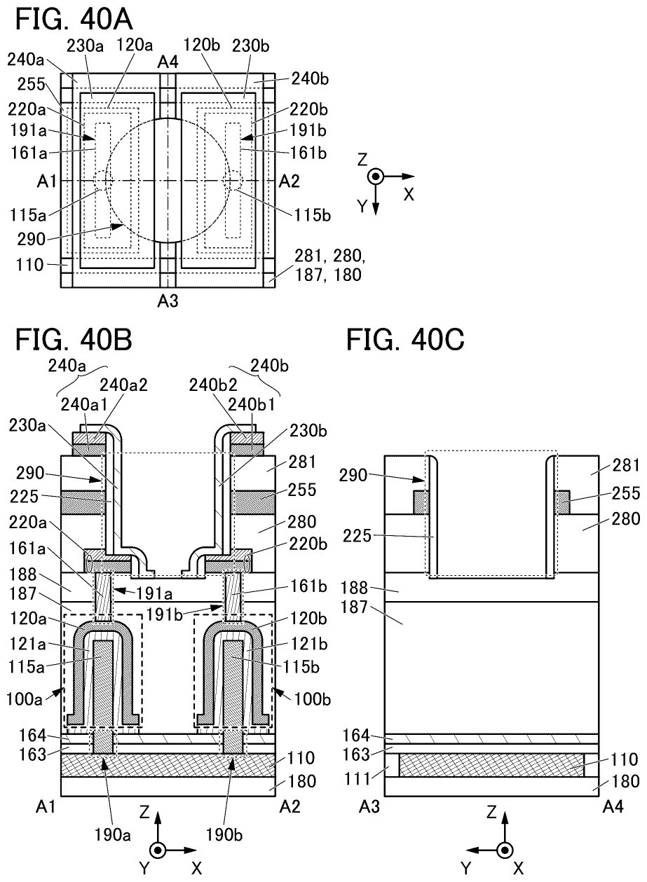

Next, as illustrated in FIGS. 40A to 40C, the conductive film 240f is processed to form the conductive layer 240a (the conductive layers 240a1 and 240a2) and the conductive layer 240b (the conductive layers 240b1 and 240b2). Specifically, the conductive layers 240a2 and the 240b2 are formed from the conductive film 240f2, and the conductive layers 240a1 and 240b1 are formed from the conductive film 240f1.

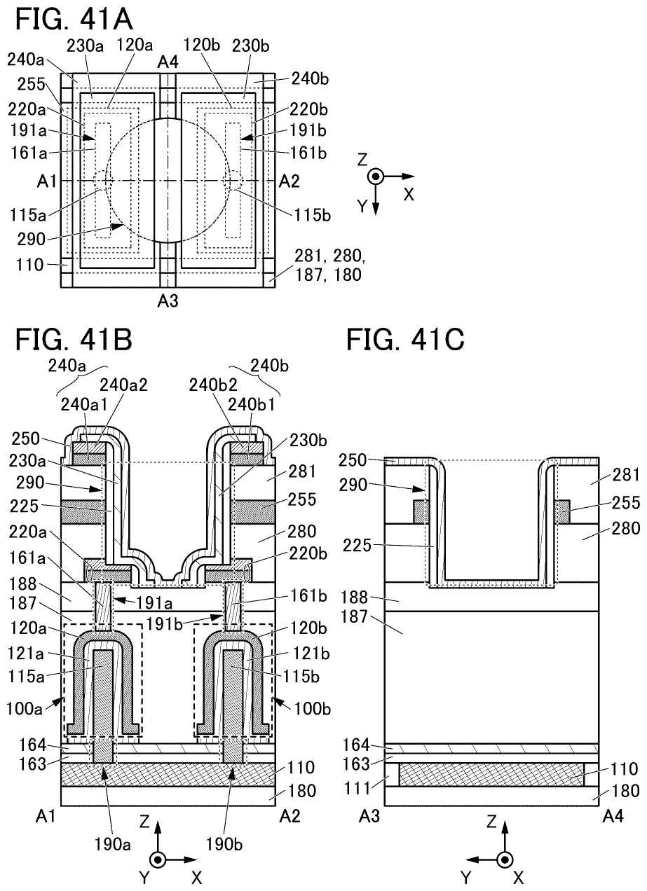

Next, as illustrated in FIGS. 41A to 41C, the insulating layer 250 is formed to cover the opening portion 290. The insulating layer 250 is provided in contact with the oxide semiconductor layer 230. The insulating layer 250 is formed in the opening portion 290 having a high aspect ratio. Thus, the insulating layer 250 is preferably formed by a film formation method that provides favorable coverage, further preferably formed by a CVD method, an ALD method, or the like.

After formation of the insulating layer 250, microwave plasma treatment is preferably performed. The microwave plasma treatment can reduce the concentration of impurities such as hydrogen or water contained in the oxide semiconductor layer 230. In addition, the crystal region of the oxide semiconductor layer 230 grows in some cases. The details of the microwave plasma treatment will be described in Embodiment 2.

In the case where the insulating layer 250 has the four-layer structure of the fourth insulating layer, the third insulating layer over the fourth insulating layer, the first insulating layer over the third insulating layer, and the second insulating layer over the first insulating layer, microwave plasma treatment may be performed after formation of the third insulating layer. Furthermore, microwave plasma treatment may be performed again after formation of the first insulating layer. As described above, the microwave plasma treatment in an oxygen-containing atmosphere may be performed multiple times (at least twice).

After formation of the third insulating layer, oxygen may be supplied to the third insulating layer. Accordingly, oxygen can be supplied to the oxide semiconductor layer 230. The above description can be referred to for the details of the treatment for supplying oxygen.

In this embodiment, as the insulating layer 250, an aluminum oxide film, a silicon oxide film, a hafnium oxide film, and a silicon nitride film are formed in this order by an ALD method.

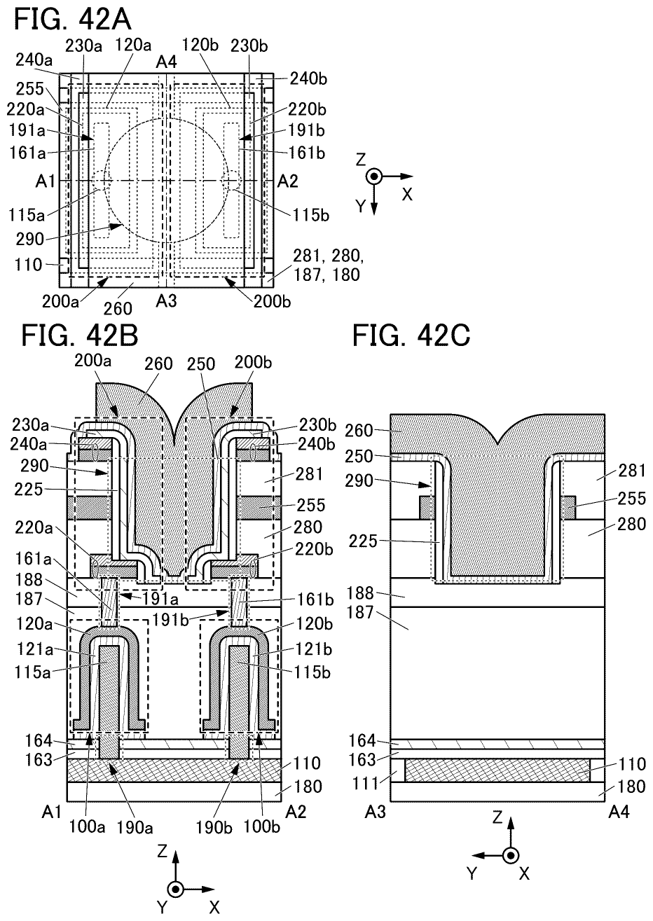

Next, as illustrated in FIGS. 42A to 42C, the conductive layer 260 is formed over the insulating layer 250. The conductive layer 260 is preferably provided to fill the opening portion 290.

The conductive layer 260 is formed in the opening portion 290 having a high aspect ratio. Thus, the conductive layer 260 is preferably formed by a film formation method that provides favorable coverage, further preferably formed by a CVD method, an ALD method, or the like.

Through the above steps, the semiconductor device of one embodiment of the present invention can be manufactured.

This embodiment can be combined with any of the other embodiments as appropriate. In this specification, in the case where a plurality of structure examples are shown in one embodiment, the structure examples can be combined as appropriate.

### Embodiment 2

In this embodiment, an oxide semiconductor layer that can be used as a semiconductor layer of a transistor will be described. As the oxide semiconductor layer of one embodiment of the present invention, a single layer or stacked layers including a metal oxide can be used. Note that in an oxide semiconductor layer having a stacked-layer structure, a boundary between stacked films is sometimes difficult to observe as described later.

### [Metal Oxide]

The metal oxide of one embodiment of the present invention preferably contains at least indium (In) or zinc (Zn), particularly preferably contains indium as its main component. The metal oxide preferably contains two or three selected from indium, an element M, and zinc, and particularly preferably contains indium and zinc as its main components. Here, the metal oxide contains indium and zinc as its main components, and can further contain the element M. The element M is a metal element or a metalloid element that has a high bonding energy with oxygen, e.g., a metal element or a metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above-described elements, further preferably one or more selected from aluminum, gallium, tin, and yttrium, still further preferably one or more selected from gallium and tin. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

Examples of the metal oxide of one embodiment of the present invention include indium zinc oxide (also referred to as In—Zn oxide or IZO (registered trademark)), indium tin oxide (also referred to as In—Sn oxide or ITO), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide or IGTO), indium aluminum zinc oxide (also referred to as In—Al—Zn oxide or IAZO), indium tin zinc oxide (also referred to as In—Sn—Zn oxide), indium titanium zinc oxide (In—Ti—Zn oxide), indium gallium zinc oxide (also referred to as In—Ga—Zn oxide or IGZO), indium tin oxide containing silicon (ITSO), indium gallium tin zinc oxide (also referred to as In—Ga—Sn—Zn oxide or IGZTO), and indium gallium aluminum zinc oxide (also referred to as In—Ga—Al—Zn oxide, IGAZO, or IAGZO). Alternatively, it is possible to use, for example, gallium zinc oxide (also referred to as Ga—Zn oxide or GZO), aluminum zinc oxide (also referred to as Al—Zn oxide or AZO), gallium tin oxide (Ga—Sn oxide), or aluminum tin oxide (Al—Sn oxide). As the metal oxide of one embodiment of the present invention, indium oxide can be used. Alternatively, as the metal oxide of one embodiment of the present invention, gallium oxide, zinc oxide, or the like can be used.

When the indium content percentage in the metal oxide is increased, the transistor can have a high on-state current and excellent frequency characteristics.

Instead of indium, the metal oxide may contain one or more kinds of metal elements with a large period number in the periodic table. Alternatively, in addition to indium, the metal oxide may contain one or more kinds of metal elements with a large period number in the periodic table. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Incidentally, lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A metal oxide having a high zinc content percentage has high crystallinity, whereby diffusion of impurities in the metal oxide can be inhibited. Consequently, a change in electrical characteristics of the transistor is suppressed, and the transistor can have high reliability.

A high content percentage of the element M in a metal oxide can inhibit formation of oxygen vacancies in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

Here is described a structure example of an oxide semiconductor layer that enables the field-effect mobility of a transistor to be increased. For example a stacked-layer structure of indium oxide and IGZO is preferably used. Specifically, the oxide semiconductor layer preferably contains indium oxide and IGZO over the indium oxide. Moreover, IGZO containing nitrogen is preferably used as the oxide semiconductor layer. For example, IGZO containing nitrogen can be formed by performing N₂O plasma treatment during or after the deposition of IGZO. For the oxide semiconductor layer, at least one of indium oxide, In—Ga oxide, In—Zn oxide, and IGZTO is preferably used.

In this embodiment, In-M-Zn oxide is sometimes described as an example of the metal oxide.

The oxide semiconductor layer of one embodiment of the present invention preferably includes a metal oxide having crystallinity. Examples of the structure of a metal oxide having crystallinity include a c-axis-aligned crystalline (CAAC) structure, a polycrystalline structure, and a nanocrystalline (nc) structure. By using a metal oxide having crystallinity for the oxide semiconductor layer, the density of defect states in the oxide semiconductor layer can be reduced. This can improve the reliability of a transistor including the oxide semiconductor layer of one embodiment of the present invention, thereby improving the reliability of a semiconductor device including the transistor.

Note that there is no particular limitation on the crystallinity of the metal oxide included in the oxide semiconductor layer. The oxide semiconductor layer sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions). The oxide semiconductor layer having crystallinity can inhibit deterioration of the transistor characteristics in some cases.

The crystallinity of the oxide semiconductor layer can be analyzed with an X-ray diffraction (XRD) pattern, a transmission electron microscope (TEM) image, or an electron diffraction (ED) pattern, for example. Alternatively, these methods may be combined to be employed for analysis.

The oxide semiconductor layer of one embodiment of the present invention preferably includes a metal oxide having a CAAC structure. The CAAC structure is a crystal structure where a plurality of microcrystals (typically, a plurality of microcrystals each having a hexagonal crystal structure) have c-axis alignment and are connected on the a-b plane without alignment. According to a high-resolution TEM image (also referred to as a multi-wavelength interference image) of a cross section of an oxide semiconductor layer having the CAAC structure, metal atoms are arranged in a layered manner in crystal parts. Thus, the oxide semiconductor layer having the CAAC structure can be regarded as having a structure including the layered crystal parts.

The CAAC structure is formed such that the c-axis is perpendicular or substantially perpendicular to a formation surface or a surface of an oxide semiconductor layer, for example. In the CAAC structure, metal atoms are arranged in a layered manner in the direction parallel or substantially parallel to the formation surface. In a region having the CAAC structure, an angle subtended by the c-axis and the formation surface is preferably within 900±20° (greater than or equal to 700 and less than or equal to 1100), further preferably within 900±150 (greater than or equal to 750 and less than or equal to 105°), still further preferably within 900±100 (greater than or equal to 80° and less than or equal to 100°), yet further preferably within 900±5° (greater than or equal to 850 and less than or equal to 95°).

In the case where the oxide semiconductor layer has the CAAC structure, a group of bright spots (specifically, bright spots arranged in a layered manner) reflecting a layered arrangement of metal atoms is observed in a cross-sectional TEM image of the oxide semiconductor layer. Specifically, a state where bright spots are arranged in a layered manner in the direction parallel or substantially parallel to the formation surface is observed.

When the oxide semiconductor layer having the CAAC structure is subjected to electron diffraction, spots indicating c-axis alignment (bright spots) are observed in the electron diffraction pattern.

A fast Fourier transform (FFT) pattern obtained by FFT processing on a TEM image reflects reciprocal lattice space information similar to that of an electron diffraction pattern.

When the cross-sectional TEM image of the oxide semiconductor layer having the CAAC structure is obtained and each region in the cross-sectional TEM image is subjected to FFT processing to form an FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle subtended by the crystal axis direction calculated from the FFT pattern and the formation surface is preferably greater than or equal to 700 and less than or equal to 1100 (within 900±20°), further preferably greater than or equal to 750 and less than or equal to 1050 (within 900±15°), still further preferably greater than or equal to 800 and less than or equal to 1000 (within 900±10°), yet further preferably greater than or equal to 850 and less than or equal to 950 (within 900±5°) can be regarded as having the CAAC structure.

When the oxide semiconductor layer having the CAAC structure is observed from the direction perpendicular to the formation surface by using the TEM image, a triangular or hexagonal atomic arrangement and crystallinity are observed in the a-b plane.

### [Composition of Metal Oxide]

The metal oxide of one embodiment of the present invention preferably contains indium (In), and further preferably has a high In content percentage. The use of a metal oxide having a high In content percentage as the oxide semiconductor layer can increase the on-state current of the transistor and improve the frequency characteristics of the transistor. For example, indium oxide is preferably used as the oxide semiconductor layer.

The metal oxide of one embodiment of the present invention can contain zinc. The metal oxide containing zinc has high crystallinity, e.g., has the CAAC structure. For example, In—Zn oxide can be used for the oxide semiconductor layer. Specifically, it is possible to use a metal oxide having an atomic ratio of In:Zn=1:1 or the neighborhood thereof, In:Zn=2:1 or the neighborhood thereof, or In:Zn=4:1 or the neighborhood thereof. Note that the neighborhood of the atomic ratio includes ±30% of an intended atomic ratio.

The metal oxide of one embodiment of the present invention can contain the element M. When the metal oxide contains the element M, formation of oxygen vacancies in the metal oxide can be inhibited. Thus, the reliability of the transistor including the oxide semiconductor layer can be increased.

For example, In—Zn oxide containing a slight amount of the element M can be used for the oxide semiconductor layer. Specifically, it is possible to use a metal oxide having an atomic ratio of In:Ga:Zn=4:0.1:1 or the neighborhood thereof, In:Ga:Zn=2:0.1:1 or the neighborhood thereof, or In:Ga:Zn=1:0.1:1 or the neighborhood thereof. It is also possible to use a metal oxide having an atomic ratio of In:Sn:Zn=4:0.1:1 or the neighborhood thereof, In:Sn:Zn=2:0.1:1 or the neighborhood thereof, or In:Sn:Zn=1:0.1:1 or the neighborhood thereof.

Moreover, In—Zn oxide containing the element M can be used for the oxide semiconductor layer. Specifically, it is possible to use a metal oxide having an atomic ratio of In:M:Zn=1:1:1 or the neighborhood thereof, In:M:Zn=1:1:1.2 or the neighborhood thereof, In:M:Zn=1:1:0.5 or the neighborhood thereof, In:M:Zn=1:1:2 or the neighborhood thereof, In:M:Zn=4:2:3 or the neighborhood thereof, In:M:Zn=1:3:2 or the neighborhood thereof, or In:M:Zn=1:3:4 or the neighborhood thereof.

Note that in the case where the metal oxide is formed by a sputtering method, the composition of the formed metal oxide may be different from that of a sputtering target. In particular, the zinc content percentage of the formed metal oxide may be reduced to approximately 50% of that of the sputtering target.

In the case where a metal oxide containing a plurality of kinds of metal elements, such as In—Ga—Zn oxide, is formed by an ALD method, the cycle ratio of precursors containing the metal elements can be set in accordance with a target composition. For example, to form an In—Ga—Zn oxide film having an atomic ratio of In:Ga:Zn=1:3:2, it is possible to perform one cycle of deposition using a precursor containing In and treatment with an oxidizer, three cycles of deposition using a precursor containing Ga and treatment with an oxidizer, and two cycles of deposition using a precursor containing Zn and treatment with an oxidizer. Note that the atomic ratio of the metal elements in the formed metal oxide film does not sometimes correspond with the cycle ratio of the precursors containing the metal elements.

Analysis of the composition of the metal oxide used for the oxide semiconductor layer can be performed by energy dispersive x-ray spectroscopy (EDX), XPS, inductively coupled plasma-mass spectrometry (ICP-MS), or inductively coupled plasma-atomic emission spectrometry (ICP-AES), for example. Alternatively, these methods may be combined to be employed for analysis. As for an element whose content percentage is low, the actual content percentage may be different from the content percentage obtained by analysis because of the influence of the analysis accuracy. For example, in the case where the content percentage of the element M is low, the content percentage of the element M obtained by analysis may be lower than the actual content percentage, quantification of the content percentage of the element M may become difficult, or the element M may be lower than the detection limit in some cases.

The oxide semiconductor layer of one embodiment of the present invention may have a stacked-layer structure of two or more layers. In the case where the oxide semiconductor layer has a two-layer structure of a first layer and a second layer over the first layer, the composition of the second layer is preferably different from that of the first layer. In the case where the oxide semiconductor layer has a three-layer structure of a first layer, a second layer over the first layer, and a third layer over the second layer, the composition of the second layer is preferably different from those of the first and third layers. Note that the composition of the first layer can be the same as that of the third layer. Alternatively, the first and third layers can have different compositions.

For each of the first to third layers, the above-described metal oxide can be used.

For the second layer, indium oxide, In—Zn oxide, In—Zn oxide containing a slight amount of the element M, or the like can be used, for example. Specifically, it is possible to use a metal oxide having an atomic ratio of In:Zn=1:1 or the neighborhood thereof, In:Zn=2:1 or the neighborhood thereof, or In:Zn=4:1 or the neighborhood thereof. For example, it is possible to use a metal oxide having an atomic ratio of In:Ga:Zn=4:0.1:1 or the neighborhood thereof, In:Ga:Zn=2:0.1:1 or the neighborhood thereof, or In:Ga:Zn=1:0.1:1 or the neighborhood thereof. As another example, it is possible to use a metal oxide having an atomic ratio of In:Sn:Zn=4:0.1:1 or the neighborhood thereof, In:Sn:Zn=2:0.1:1 or the neighborhood thereof, or In:Sn:Zn=1:0.1:1 or the neighborhood thereof. Increasing the content percentage of In in the second layer can increase the on-state current and improve the frequency characteristics.

The conduction band minimum of each of the first and third layers is preferably positioned closer to the vacuum level than the conduction band minimum of the second layer is. In other words, the energy of the conduction band minimum of each of the first and third layers is preferably lower than the energy of the conduction band minimum of the second layer. In this case, the second layer is sandwiched between the first layer and the third layer, each of which has a conduction band minimum positioned closer to the vacuum level, and can function mainly as a current path (channel).

When the second layer is sandwiched between the first layer and the third layer, carriers trapped at and near the interfaces between the second layer and each of the first and third layers can be reduced. Moreover, the channel can be distanced from the surface of a gate insulating layer, so that the influence of surface scattering can be reduced. Accordingly, a buried-channel transistor where a channel is distanced from the interface with an insulating layer can be achieved, whereby the field-effect mobility can be increased. Furthermore, the influence of interface states that may be formed on the back gate electrode side (or the back channel side) of the oxide semiconductor layer is reduced, so that light deterioration (e.g., light negative bias deterioration) of the transistor can be inhibited and the reliability of the transistor can be increased.

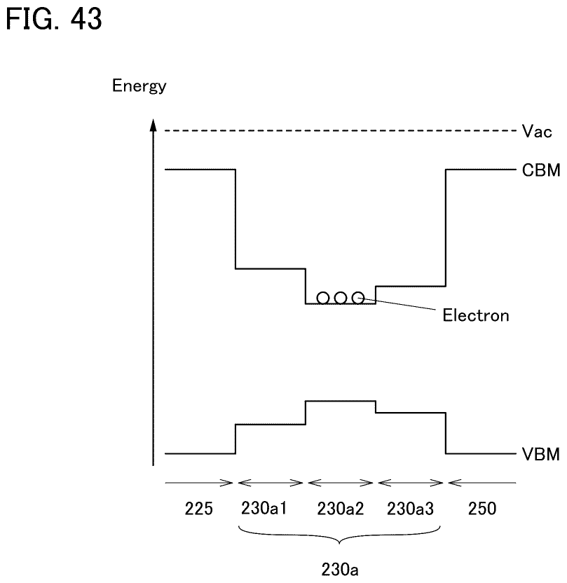

For example, a band diagram of the oxide semiconductor layer 230 including the oxide semiconductor layers 230a1 to 230a3 and its vicinity illustrated in FIG. 14B is as shown in FIG. 43. In FIG. 43, the vertical axis represents energy and the horizontal direction represents the thickness direction of a center portion of a channel formation region. FIG. 43 shows a valence band maximum (VBM) and a conduction band minimum (CBM) of each of the oxide semiconductor layers 230a1 to 230a3 and the insulating layers 225 and 250 in a state where no voltage is applied between the gate and the source. In FIG. 43, a vacuum level Vac is denoted by a dashed line.

Note that energy of the valence band maximum and energy of the conduction band minimum change depending on constituent elements and compositions of the oxide semiconductor layers 230a1 to 230a3 and the insulating layers 225 and 250; thus, the relation between energy levels of the valence band maximum and the relation between energy levels of the conduction band minimum are mainly described with reference to the band diagram in FIG. 43.

With certain constituent elements and compositions of the oxide semiconductor layers 230a1 to 230a3, the oxide semiconductor layer 230a2 is sandwiched between the oxide semiconductor layers 230a1 and 230a3 each of which has a conduction band minimum that is positioned closer to the vacuum level than that of the oxide semiconductor layer 230a2 is, as shown in FIG. 43. This structure enables a buried channel. That is, in this structure, a path through which a larger amount of current (electrons are shown as carriers in FIG. 43) flows is formed in the oxide semiconductor layer 230a2. Accordingly, the on-state current or reliability can be increased. for example.

In the case where a buried channel is formed using the first to third layers, a metal oxide having a higher Ga content percentage than that for the second layer can be used for the first and third layers, for example. Specifically, for each of the first and third layers, it is possible to use a metal oxide having an atomic ratio of In:Ga:Zn=1:1:1 or the neighborhood thereof, In:Ga:Zn=1:3:2 or the neighborhood thereof, or In:Ga:Zn=1:3:4 or the neighborhood thereof. Alternatively, Ga—Zn oxide or gallium oxide can be used. When the Ga content percentage in the first and third layers is increased, the conduction band minimum of each of the first and third layers is sometimes positioned closer to the vacuum level than the conduction band minimum of the second layer is.

Increasing the Ga content percentage in the first and third layers can improve the barrier property against hydrogen in the first and third layers. Thus, diffusion of hydrogen into the second layer from below the first layer or above the third layer can be inhibited. In addition, increasing the Ga content percentage in the first and third layers enables impurities such as hydrogen or water contained in the oxide semiconductor layer to be reduced by heat or the like applied after formation of the oxide semiconductor layer. Note that when a metal oxide having a lower In content percentage than that for the second layer is used for the first and third layers, a similar effect can be obtained in some cases.

For the third layer, it is preferable to use a metal oxide having an atomic ratio of In:Ga:Zn =1:1:1 or the neighborhood thereof, In:Ga:Zn=1:3:2 or the neighborhood thereof, or In:Ga:Zn=1:3:4 or the neighborhood thereof, for example. In this case, the third layer contains indium and gallium.

Increasing the Ga content percentage in the first and third layers can improve the barrier property against oxygen of the first and third layers. Thus, release of oxygen from the second layer where the channel is formed is inhibited, thereby inhibiting formation of oxygen vacancies in the second layer or an increase in the amount of oxygen vacancies in the second layer. Accordingly, the transistor can have favorable electrical characteristics.

When the Ga content percentage in the first layer is increased, the resistivity of the first layer can be higher than that of the second layer in some cases. In the case where the first layer is provided on the back channel side, providing a layer having high resistivity as the first layer can inhibit a negative shift of the threshold voltage or a decrease in the on-state current. Accordingly, the threshold voltage of the transistor shifts positively, so that the transistor can have normally-off characteristics. In the above-described manner, the electrical characteristics and reliability of the transistor can be improved.

The band gap of the metal oxide can be evaluated using optical evaluation with a spectrophotometer, spectroscopic ellipsometry, a photoluminescence method, X-ray photoelectron spectroscopy, or an X-ray absorption fine structure (XAFS). Alternatively, these methods can be combined as appropriate for analysis. The electron affinity or the conduction band minimum can be obtained from a band gap and an ionization potential, which is a difference in energy between the vacuum level and the valence band maximum. The ionization potential can be evaluated by ultraviolet photoelectron spectroscopy (UPS), for example.

Moreover, a metal oxide having a higher In content percentage than that for the second layer may be used for the first and third layers. Alternatively, a metal oxide having a higher In content percentage than that for the second layer may be used for one of the first and third layers, and a metal oxide having a higher Ga content percentage than that for the second layer may be used for the other.

Each of the first to third layers may include a stack of a plurality of layers each having the above-described composition. For example, the first layer may have a structure where a metal oxide with a high In content percentage is stacked over a metal oxide with a high Ga content percentage. As another example, the third layer may have a structure where a metal oxide with a high Ga content percentage is stacked over a metal oxide with a high In content percentage.

### [Formation Method of Oxide Semiconductor Layer]

The oxide semiconductor layer of one embodiment of the present invention can be formed by a sputtering method, a chemical vapor deposition (CVD) method, a vacuum evaporation method, a molecular beam epitaxy (MBE) method, a pulsed laser deposition (PLD) method, an ALD method, or the like.

The oxide semiconductor layer of one embodiment of the present invention can be formed by forming metal oxides using two kinds of formation methods. For example, the oxide semiconductor layer of one embodiment of the present invention can be formed by forming metal oxides using a first formation method and a second formation method.

The oxide semiconductor layer of one embodiment of the present invention can have a two-layer structure of a first layer and a second layer over the first layer. In the case where the oxide semiconductor layer has a two-layer structure, the oxide semiconductor layer can be formed in the following manner: the first layer is formed over a formation surface by a first formation method, and then the second layer is formed over the first layer by a second formation method.

As the first formation method, a formation method that causes less damage to the formation surface than the second formation method is preferably used. Accordingly, formation of a mixed layer at the interface between the oxide semiconductor layer and a layer over which the oxide semiconductor layer is formed (the formation surface of the oxide semiconductor layer) can be inhibited. Moreover, entry of impurities such as silicon into the second layer formed over the first layer can be inhibited, so that the crystallinity of the oxide semiconductor layer can be further increased in some cases.

Examples of the first formation method include an ALD method, a CVD method, and an MBE method. Examples of a CVD method include a plasma enhanced CVD (PECVD) method, a thermal CVD method, a photo CVD method, and an MOCVD method. An MBE method is a film formation method by which a thin film having a crystal structure reflecting a crystal system of a substrate is grown, and is one of film formation methods that cause less damage to a formation surface. A wet method can be used as the first formation method. A wet method is one of film formation methods that cause less damage to a formation surface. An example of a wet method is a spray coating method.

As the second formation method, a method that enables formation of a metal oxide having crystallinity is preferably used. The metal oxide formed at this time particularly preferably has the CAAC structure. Examples of the second formation method include a sputtering method and a PLD method. A metal oxide formed by a sputtering method is likely to have crystallinity; thus, a sputtering method is suitable as the second formation method.

When a metal oxide is formed over the formation surface by the second formation method, damage to the formation surface might cause alloying of a component contained in the metal oxide with a component contained in the layer serving as the formation surface. When alloying occurs, a mixed layer is sometimes formed at the interface between the metal oxide and the layer serving as the formation surface. The mixed layer can also be referred to as an alloyed region. The formation of the mixed layer can also be referred to as alloying.

For example, in the case where a sputtering method is used as the second formation method, a mixed layer is sometimes formed owing to particles ejected from a target or the like (also referred to as sputtered particles) or energy applied to the substrate side by sputtered particles or the like, for example. Specifically, in the case where a metal oxide is formed over an insulating layer containing silicon, e.g., a silicon oxide film as the formation surface by the second formation method, silicon might enter the metal oxide. There is a concern that the entry of impurities such as silicon into the metal oxide may hinder crystallization of the metal oxide. When an oxide semiconductor layer into which impurities enter is used for a transistor, the initial characteristics or reliability of the transistor may be adversely affected. It is difficult to increase the crystallinity of an alloyed region even when heat treatment described later is performed.

Accordingly, forming the metal oxide by the first formation method before forming the metal oxide by the second formation method as described above can inhibit entry of impurities into the oxide semiconductor layer. In addition, alloying with the layer serving as the formation surface can be inhibited. Thus, the initial characteristics and reliability of the transistor can be improved. Moreover, the crystallinity of the oxide semiconductor layer can be further increased.

In addition, a mixed layer is sometimes formed at the interface between the first layer and the second layer. The mixed layer includes a component contained in the first layer and a component contained in the second layer. For example, in the case where gallium oxide is used for the first layer and a metal oxide containing indium is used for the second layer, the mixed layer includes gallium and indium. For example, in the case where the indium content percentage of the second layer is higher than that of the first layer, the indium content percentage of the mixed layer is higher than or equal to that of the first layer and lower than or equal to that of the second layer.

An ALD method is suitable as the first formation method because damage to the formation surface can be inhibited as compared with a sputtering method. An ALD method is a film formation method that gives higher coverage than a sputtering method, and the use of an ALD method as the formation method of the first layer can increase the coverage with the oxide semiconductor layer. Thus, the oxide semiconductor layer can suitably cover a step, an opening portion, or the like having a high aspect ratio.

As the first layer, a metal oxide having a microcrystalline structure or an amorphous structure that has lower crystallinity than the CAAC structure is formed in some cases, for example. Forming the second layer having high crystallinity on the first layer having low crystallinity or performing heat treatment after formation of the second layer can increase the crystallinity of the first layer with the second layer as a nucleus in some cases. Accordingly, in some cases, the crystallinity can be increased in the whole oxide semiconductor layer including the vicinity of the interface with the formation surface.

The layer serving as the formation surface is an insulating film such as a silicon oxide film, a silicon oxynitride film, a silicon nitride film, a silicon nitride oxide film, an aluminum oxide film, or a hafnium oxide film, for example. In addition, the layer serving as the formation surface may be a conductive film such as a titanium nitride film, a tungsten film, or an ITSO film in some transistor structures. The layer serving as the formation surface does not necessarily have crystallinity. In the case of having crystallinity, the layer serving as the formation surface may have a crystal structure with low lattice matching with the metal oxide included in the oxide semiconductor layer.

The first layer is preferably formed by an ALD method. Here, a method for forming In-M-Zn oxide for the first layer by an ALD method is described.

First, a source gas that contains a precursor containing indium is introduced into a reaction chamber (also referred to as a chamber) so that the precursor is adsorbed on the formation surface. Then, an oxidizer is introduced as a reactant into the reaction chamber to react with the adsorbed precursor, and components other than indium are released while indium is adsorbed on the substrate, whereby a layer in which indium and oxygen are bonded to each other is formed.

Subsequently, a source gas that contains a precursor containing the element M is introduced into the reaction chamber, and the precursor is adsorbed on the layer in which indium and oxygen are bonded to each other. Then, an oxidizer is introduced as a reactant into the reaction chamber to react with the adsorbed precursor, and components other than the element M are released while the element M is adsorbed on the substrate, whereby a layer in which the element M and oxygen are bonded to each other is formed.

Next, a source gas that contains a precursor containing zinc is introduced into the reaction chamber, and the precursor is adsorbed on the layer in which the element M and oxygen are bonded to each other. Then, an oxidizer is introduced as a reactant into the reaction chamber to react with the adsorbed precursor, and components other than zinc are released while zinc is adsorbed on the substrate, whereby a layer in which zinc and oxygen are bonded to each other is formed.

By repeating the above steps, In-M-Zn oxide can be formed by an ALD method as the oxide semiconductor layer over the layer serving as the formation surface.

When the oxide semiconductor layer is formed by an ALD method, ozone (O₃), oxygen (O₂), water (H₂O), or the like can be used as the oxidizer. The use of an oxidizer without hydrogen, such as ozone (O₃) or oxygen (O₂), can reduce the amount of hydrogen entering the oxide semiconductor layer.

It is preferable that after the precursor is adsorbed in the above steps, introduction of the source gas containing the precursor be stopped and the reaction chamber be purged so that an excess precursor, a reaction product, and the like are removed from the reaction chamber. Moreover, it is preferable that after the adsorbed precursor reacts with the oxidizer in the above steps, introduction of the oxidizer be stopped and the reaction chamber be purged so that an excess reactant, a reaction product, and the like are removed from the reaction chamber.

In the description of this specification and the like, ozone, oxygen, and water that can be used as a reactant or an oxidizer include not only those in gas or molecular states but also those in plasma, radical, and ion states, unless otherwise specified.

The second layer is preferably formed by a sputtering method.

As a target used in a sputtering method, In-M-Zn oxide can be used. In the case where a metal oxide is formed by a sputtering method, oxygen or a mixed gas of oxygen and a noble gas can be used as a sputtering gas. An increase in the proportion of oxygen in the sputtering gas can increase the amount of excess oxygen in the oxide film to be formed.

A higher proportion of the flow rate of an oxygen gas to the flow rate of the whole film formation gas (also referred to as oxygen flow rate ratio) used at the time of forming the metal oxide enables the formed metal oxide to have higher crystallinity in some cases.

When the metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess metal oxide in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including an oxygen-deficient metal oxide in a channel formation region can have relatively high field-effect mobility.

In the formation of the metal oxide by a sputtering method, substrate heating is preferably performed. Increasing the substrate temperature (e.g., stage temperature) at the time of forming the metal oxide enables a metal oxide with high crystallinity to be formed in some cases. In the formation of the metal oxide by a sputtering method, the substrate heating temperature is preferably higher than or equal to 100° C. and lower than or equal to 400° C., further preferably higher than or equal to 200° C. and lower than or equal to 300° C., for example.

With the above-described formation method, the thickness of the mixed layer formed at the interface between the layer serving as the formation surface and the metal oxide can be reduced or the thickness of the alloyed region formed at the interface between the layer serving as the formation surface and the metal oxide can be thin enough to be unobserved. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm.

The thickness of the alloyed region can sometimes be calculated by performing SIMS or composition line analysis by EDX on the region and its vicinity.

For example, EDX line analysis is performed on the alloyed region and its vicinity with the direction perpendicular to the formation surface of the first layer regarded as the depth direction. Next, in the profile of quantitative values of the elements in the depth direction, which is obtained from the analysis, the depth at which the quantitative value of a metal (In when the first layer contains In) that is the main component of the first layer and that is not the main component of the layer serving as the formation surface becomes half is defined as the depth (position) of the interface between the region and the first layer. The depth at which the quantitative value of an element (e.g., Si) that is a main component of the layer serving as the formation surface and that is not a main component of the first layer becomes half is defined as the depth (position) of the interface between the region and the layer serving as the formation surface. In the above-described manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, when SIMS analysis is performed on the oxide semiconductor layer formed over a silicon oxide film serving as the formation surface, the depth at which the silicon concentration is 50% of the maximum value of the silicon concentration in the silicon oxide film is defined as an interface, and the distance between the interface and the depth at which the silicon concentration decreases to 1.0×10²¹ atoms/cm³, preferably 5.0×10²′ atoms/cm³, further preferably 1.0×10²¹ atoms/cm³ is defined as a thickness t. The thickness t is preferably less than or equal to 3 nm, further preferably less than or equal to 2 nm.

When the thickness of the alloyed region is reduced, the thickness t can be a value within the above-described range.

When the thickness of the alloyed region is reduced, the CAAC structure can be formed in the vicinity of the formation surface. Here, the vicinity of the formation surface refers to, for example, a region ranging from the formation surface of the oxide semiconductor layer to greater than 0 nm and less than or equal to 3 nm, preferably greater than 0 nm and less than or equal to 2 nm, further preferably greater than or equal to 1 nm and less than or equal to 2 nm in the direction substantially perpendicular to the formation surface.

Note that the CAAC structure in the vicinity of the formation surface can be confirmed in TEM observation in some cases. For example, in high-resolution TEM cross-sectional observation of the oxide semiconductor layer, bright spots arranged in a layered manner in the direction parallel to the formation surface are observed in the vicinity of the formation surface.

The oxide semiconductor layer of one embodiment of the present invention can have a three-layer structure of a first layer, a second layer over the first layer, and a third layer over the second layer.

In the case where the oxide semiconductor layer has a three-layer structure, the oxide semiconductor layer can be formed in the following manner: the first layer is formed over a formation surface by a first formation method, the second layer is formed by a second formation method, and then the third layer is formed by the first formation method.

Even when the first and third layers in the oxide semiconductor layer have a composition that is less likely to form the CAAC structure in the case of a single layer, crystal growth occurring with the second layer as a nucleus enables the whole oxide semiconductor layer including the first and third layers to have the CAAC structure. Alternatively, the oxide semiconductor layer can have the CAAC structure in a region that includes the second layer and at least part of each of the first and third layers.

In particular, even with a composition where the first and third layers have a high In content percentage, crystallinity suitable for a semiconductor layer of a transistor can be obtained. The oxide semiconductor layer of one embodiment of the present invention can achieve both high on-state characteristics owing to the increase in the In content percentage and high reliability of the transistor owing to the CAAC structure with high crystallinity.

The first and third layers may employ a metal oxide having the same composition as the second layer. By using the same composition, the oxide semiconductor layer may easily have the CAAC structure after heat treatment.

Since the second layer has high crystallinity, the crystal growth of the third layer can be achieved with the use of the crystal of the second layer as a nucleus or a seed. Thus, the third layer can be crystallized even when a film formation method that easily gives crystallinity is not employed as the formation method of the third layer. Here, for example, when a film formation method that gives higher coverage than that of the second layer is used to form the third layer, the whole oxide semiconductor layer can have both high crystallinity and high coverage.

When influence of the formation surface on the second layer is reduced by provision of the first layer, the crystallinity of the second layer is increased to an extremely high level. Thus, the third layer whose crystal is grown with the second layer as a nucleus or a seed is also expected to have extremely excellent crystallinity.

In addition, in the case where an oxide semiconductor layer is used as a semiconductor layer of a transistor, the third layer, which is the uppermost layer of the oxide semiconductor layer, is in contact with a gate insulating layer in some cases. Increasing the crystallinity of the layer in contact with the gate insulating layer can increase the carrier mobility in an on state of the transistor.

The crystallinity of the first and third layers is increased with the use of the second layer having high crystallinity as a nucleus or a seed. Specifically, the crystallinity of the first layer may be increased at the time of formation of the second layer or by heat treatment after formation of the third layer. The crystallinity of the third layer may be increased at the time of formation of the third layer or by heat treatment after the formation of the third layer. The heat treatments have a function of assisting in increasing the crystallinity.

As described above, in the method for forming the oxide semiconductor layer of one embodiment of the present invention, with the use of the second layer including a metal oxide with high crystallinity, (i.e., CAAC), as a nucleus or a seed, the crystallinity of the metal oxides above and below the second layer (here, the first and third layers) can be increased. Accordingly, the crystallinity of the whole oxide semiconductor layer can be increased. In other words, the second layer serves as a nucleus or a seed to cause solid-phase growth of the metal oxides above and below the second layer, so that the oxide semiconductor layer with high crystallinity can be formed. An oxide semiconductor layer formed by such a formation method, here, a CAAC film, can be referred to as an axial growth CAAC (AG CAAC).

A region having the CAAC structure preferably spreads in the whole the oxide semiconductor layer. Crystals in the region having the CAAC structure in the first layer are connected to crystals in the region having the CAAC structure in the second layer. Crystals in the region having the CAAC structure in the third layer are connected to crystals in the region having the CAAC structure in the second layer. Accordingly, a boundary between the first layer and the second layer is not observed in some cases. In addition, a boundary between the second layer and the third layer is not observed in some cases. The oxide semiconductor layer may be expressed as one layer where interfaces are not clearly observed. The oxide semiconductor layer may be expressed as a single layer.

In the region having the CAAC structure in each of the first to third layers, bright spots arranged parallel or substantially parallel to the formation surface are observed in a high-resolution cross-sectional TEM image, for example. The c-axis of the CAAC structure included in each of the first to third layers is preferably parallel or substantially parallel to the normal direction of the formation surface or the surface of the oxide semiconductor layer.

Part of the first layer or the third layer is not crystallized in some cases.

In the case where the oxide semiconductor layer has a three-layer structure, the oxide semiconductor layer can also be formed in the following manner: a first layer is formed over a formation surface by a first formation method, a second layer is formed by the first formation method, and then a third layer is formed by a second formation method.

As described above, when a metal oxide with a high In content percentage is used for a transistor, the field-effect mobility of the transistor can be increased. On the other hand, a metal oxide with a high In content percentage tends to have a cubic crystal structure. Thus, when a metal oxide with a high In content percentage is used for the second layer in contact with the third layer, crystals reflecting the orientation of crystals included in the third layer can be formed.

The lattice mismatch between the crystals included in the third layer and the crystals included in the second layer is preferably small. Thus, crystals reflecting the orientation of the crystals included in the third layer can be formed in the second layer. At this time, for example, in high-resolution cross-sectional TEM observation of the oxide semiconductor layer, bright spots arranged in a layered manner in the direction parallel to the formation surface are observed in the second layer.

There is no particular limitation on the crystal structure of the second layer as long as the crystals included in the third layer have a small lattice mismatch with the crystals included in the second layer. The crystal structure of the second layer may be any of a cubic crystal structure, a tetragonal crystal structure, an orthorhombic crystal structure, a hexagonal crystal structure, a monoclinic crystal structure, and a trigonal crystal structure.

In the above-described structure, typically, the first layer can be a layer including a metal oxide having an atomic ratio of In:Ga:Zn=1:3:2 or in the neighborhood thereof or a layer including gallium oxide, the second layer can be a layer including a metal oxide containing a slight amount of the element M or a layer including indium oxide, and the third layer can be a layer including a metal oxide having an atomic ratio of In:Ga:Zn=1:1:1 or in the neighborhood thereof. In this case, the first layer contains gallium. In the case where the first layer includes a metal oxide having an atomic ratio of In:Ga:Zn=1:3:2 or in the neighborhood thereof, the indium content percentage is lower than the gallium content percentage in the first layer. The indium content percentage in the second layer is higher than the indium content percentage in the third layer.

In the case where the first layer and the second layer are formed by the first formation method, the first layer and the second layer are preferably formed successively without exposure to the air. Forming the first layer and the second layer successively without exposure to the air can increase the productivity. Furthermore, impurities (typically, moisture or the like) taken into the interface between the first layer and the second layer and the vicinity thereof can be reduced.

One or more of the first to third layers may include a stack of a plurality of layers with different compositions. For example, the first layer may be formed in the following manner: a layer including a metal oxide with a high Ga content percentage is formed by the first formation method, and then a layer including a metal oxide with a higher In content percentage than the layer is formed by the first formation method.

After formation of the layers by the first formation method, microwave plasma treatment is preferably performed.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

By performing microwave plasma treatment in an oxygen-containing atmosphere, the impurity concentration in the oxide semiconductor layer 230 can be reduced. Specific examples of impurities include hydrogen and carbon. Although the microwave plasma treatment in an oxygen-containing atmosphere is performed on the metal oxide in the above-described example, one embodiment of the present invention is not limited thereto. For example, microwave plasma treatment in an oxygen-containing atmosphere may be performed on an insulating film, specifically a silicon oxide film, which is provided in the vicinity of the metal oxide. Furthermore, the crystallinity of the oxide semiconductor layer is sometimes increased by heat in the microwave plasma treatment.

The microwave plasma treatment is preferably performed under a reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

In the microwave plasma treatment, substrate heating may be performed. The substrate heating temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C. For example, the substrate heating temperature is preferably higher than or equal to room temperature and lower than or equal to 500° C., further preferably higher than or equal to 100° C. and lower than or equal to 450° C., still further preferably higher than or equal to 200° C. and lower than or equal to 450° C., yet still further preferably higher than or equal to 300° C. and lower than or equal to 450° C., yet still further preferably higher than or equal to 400° C. and lower than or equal to 450° C.

The microwave plasma treatment can be performed using an oxygen gas and an argon gas, for example. In the microwave plasma treatment using an oxygen gas and an argon gas, oxygen radicals can be mainly in three states: triplet oxygen (O(³Pⱼ)), singlet oxygen (O(¹D₂)), and an oxygen ion (O₂⁺). The oxygen ion effectively acts for reducing the hydrogen concentration in an oxide film by the microwave plasma treatment. The amount of oxygen radicals in each state changes depending on the oxygen flow rate ratio or a pressure in the microwave plasma treatment. For example, the amount of oxygen ions tends to increase under a condition with a low oxygen flow rate ratio and a low pressure. Meanwhile, an extremely low oxygen flow rate ratio or pressure might destabilize the control of the oxygen flow rate, thereby making stable discharging difficult or causing etching of an oxide film, for example. Therefore, for example, the oxygen flow rate ratio (O₂/(02+Ar)) in the microwave plasma treatment is preferably higher than 0% and lower than or equal to 10%, further preferably higher than or equal to 0.5% and lower than or equal to 5%, still further preferably higher than or equal to 0.5% and lower than or equal to 3%, and is typically preferably 1%.

As the microwave plasma treatment time is shorter, oxidation of the conductive layer 220, the conductive layer 240, or the like can be inhibited more. In addition, the productivity is improved. In view of this, the microwave plasma treatment time is preferably longer than or equal to 1 minute and shorter than or equal to 60 minutes, further preferably longer than or equal to 1 minute and shorter than or equal to 30 minutes, still further preferably longer than or equal to 1 minute and shorter than or equal to 10 minutes.

The microwave plasma treatment in an oxygen-containing atmosphere can convert an oxygen gas into plasma by using a high-frequency wave such as a microwave or an RF, and apply, to the oxide semiconductor layer, oxygen radicals that are generated by conversion of the oxygen gas into plasma. By the effects of plasma, a microwave, oxygen radicals, and the like, a defect in which hydrogen enters an oxygen vacancy (also referred to as V_{O}H in some cases) in the oxide semiconductor layer can be divided into an oxygen vacancy and hydrogen, and hydrogen which is an impurity can be removed from the oxide semiconductor layer. In this manner, V_{O}H contained in the oxide semiconductor layer can be reduced. At this time, carbon bonded to oxygen, hydrogen, or the like can also be removed in some cases. Performing the microwave plasma treatment in such a manner can reduce impurities such as carbon and hydrogen. Supplying the oxygen radicals to oxygen vacancies formed in the oxide semiconductor layer can further reduce oxygen vacancies in the oxide semiconductor layer.

The microwave plasma treatment can increase the crystallinity of the layers formed by the first formation method. Here, the principles of improving the crystallinity of the oxide semiconductor layer by the microwave plasma treatment will be described. First, active species excited by a microwave, such as oxygen radicals, reach the surface of the oxide semiconductor layer, and a substitution reaction between the active species and oxygen in the oxide semiconductor layer occurs. At this time, a nucleus or a seed is formed. In addition, lateral growth of the nucleus or the seed is caused. In addition, the active species excited by the microwave preferably contain oxygen (typically, oxygen ions) that is likely to be adsorbed onto a side surface of the nucleus or the seed, in which case the lateral growth is promoted. The microwave plasma treatment causes formation of a nucleus or a seed and lateral growth of the nucleus or the seed, so that the crystallinity of the oxide semiconductor layer is improved.

Meanwhile, when part of oxygen that is present in the oxide semiconductor layer before the microwave plasma treatment reacts with hydrogen in the oxide semiconductor layer, i.e., a reaction of “2H+O→H₂O ↑” occurs, the hydrogen can be removed as H₂O (i.e., dehydration or dehydrogenation). H₂O is a limiting factor in improving crystallinity and thus is preferably removed from the oxide semiconductor layer. Hydrogen in the oxide semiconductor layer is removed as H₂O to reduce the hydrogen concentration in the oxide semiconductor layer, whereby an improvement in crystallinity can be promoted. When the temperature of the microwave plasma treatment is increased, the hydrogen concentration in the oxide semiconductor layer can be further reduced.

In addition, the microwave plasma treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

Note that the crystallinity can also be improved by performing plasma treatment using an oxygen gas, instead of the microwave plasma treatment.

The increase in the crystallinity of the layer formed by the first formation method can further increase the crystallinity of a layer formed over the layer. Thus, the crystallinity of the whole oxide semiconductor layer can be increased.

Oxygen supplied to the oxide semiconductor layer is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Oxygen injected into the oxide semiconductor layer preferably has one or more of the above-described forms. An oxygen radical is particularly preferable.

Heat treatment is preferably performed after formation of the oxide semiconductor layer. By performing the heat treatment, the crystallinity of the oxide semiconductor layer can be increased. The heat treatment here is not limited to heating. For example, the heat treatment may be performed with heat applied in the manufacturing process.

The heat treatment temperature can be higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature can be 400° C.±25° C. (higher than or equal to 375° C. and lower than or equal to 425° C.). The treatment time can be shorter than or equal to 10 hours and can be, for example, longer than or equal to 1 minute and shorter than or equal to 5 hours, or longer than or equal to 1 minute and shorter than or equal to 2 hours. In the case of using an RTA apparatus, the treatment time can be longer than or equal to 1 second and shorter than or equal to 5 minutes, for example. By the heat treatment, the third layer formed by the first formation method (in other words, crystal molecules deposited by an ALD method) is expected to fill an atomic-level space between crystal parts of the CAAC structure of the second layer formed by the second formation method.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

By the heat treatment step, the crystallinity of the region having the CAAC structure may be increased in the third layer formed by the first formation method. In the case where the region is formed only in the lower portion of the third layer after the deposition by an ALD method, the region may be extended upward by the heat treatment step. That is, by the heat treatment, the region having the CAAC structure may be formed in the whole third layer.

As described above, in the case where the oxide semiconductor layer has a three-layer structure, the first layer is formed over a formation surface by the first formation method, the second layer is formed by the first formation method, and then the third layer is formed by the second formation method, whereby the oxide semiconductor layer can be formed. In this case, by heat treatment step after the formation of the oxide semiconductor layer, at least part of the first layer or the second layer formed by the first formation method preferably has the CAAC structure. The CAAC structure is expected to be easily generated when a mixed layer formed in the first layer or the second layer serves as a nucleus or a seed. The CAAC region in the first layer or the second layer is preferably large, and the CAAC region preferably extends to the vicinity of the formation surface.

Since the CAAC region extends from the upper portion to the lower portion of the first layer or the second layer, the CAAC region can extend to the vicinity of the layer serving as the formation surface, regardless of the material and crystallinity of the layer serving as the formation surface. For example, even when the layer serving as the formation surface has an amorphous structure, the crystallinity of the first layer or the second layer can be increased. Thus, the method for forming the oxide semiconductor layer of one embodiment of the present invention is suitable particularly for the case where the layer serving as the formation surface has an amorphous structure.

When one or both of the microwave plasma treatment and the heat treatment are performed as described above, the crystallinity of the whole oxide semiconductor layer can be increased. Moreover, impurities in the oxide semiconductor layer can be reduced. Crystal growth of the oxide semiconductor layer with a low impurity concentration can further make crystallinity higher.

Increasing the crystallinity of the oxide semiconductor layer can inhibit an increase in the electric resistance of the semiconductor layer of a transistor including the oxide semiconductor layer or improve the initial characteristics (in particular, the on-state current) of the transistor, and thus a transistor suitable for high-speed operation can be expected. In addition, the reliability and on-state current of the transistor can be increased.

Note that one or both of the microwave plasma treatment and the heat treatment may be performed directly on the oxide semiconductor layer or performed after an insulating film or the like is formed over the oxide semiconductor layer.

Before formation of the first layer or after formation of the first layer or the second layer by the first formation method, oxygen may be supplied to the first layer or the second layer. Accordingly, oxygen can be supplied to the oxide semiconductor layer by heat or the like applied after this treatment.

Examples of the treatment for supplying oxygen include heat treatment in an oxygen-containing atmosphere and plasma treatment (including microwave plasma treatment) in an oxygen-containing atmosphere. Moreover, an oxide film (preferably a metal oxide film) may be formed in an oxygen-containing atmosphere by a sputtering method, thereby supplying oxygen to the first layer or the second layer formed by the first formation method. The formed oxide film may be removed immediately or left as it is. In the case where the formed oxide film is left as it is, the oxide film can be used as the layer provided over the first layer or the second layer (i.e., used as the second layer or the third layer). An oxygen-containing atmosphere can include not only an oxygen gas (O₂) but also a gas of an oxygen-containing compound such as ozone (O₃) or dinitrogen monoxide (N₂O). The substrate temperature in the plasma treatment is higher than or equal to room temperature (25° C.) and lower than or equal to 450° C.

The oxide semiconductor layer of one embodiment of the present invention has high crystallinity throughout the whole layer. Thus, in the oxide semiconductor layer, boundaries between the stacked first to third layers are not observed in some cases. The boundaries between the stacked layers may be difficult to observe particularly after heat treatment is performed. Whether the boundaries between the stacked layers are present can be checked in cross-sectional observation with a TEM or a scanning transmission electron microscope (STEM), for example.

The oxide semiconductor layer that is formed by the above-described two kinds of formation methods and has the CAAC structure sometimes has one or more of a higher relative permittivity, a higher film density, and higher film hardness than an oxide semiconductor layer that is formed by one kind of formation method and has the CAAC structure.

When the oxide semiconductor layer that is formed by the above-described two kinds of formation methods and has the CAAC structure is used for a channel formation region of a transistor, the transistor can have excellent characteristics (e.g., a high on-state current, high field-effect mobility, a low S value, high frequency characteristics (also referred to as f characteristics), or high reliability).

The oxide semiconductor layer of one embodiment of the present invention can sometimes be formed by using the first formation method and one or both of microwave plasma treatment and heat treatment. In other words, the oxide semiconductor layer of one embodiment of the present invention can be formed without using the second formation method in some cases. For example, after the first layer is formed by the first formation method, one or both of microwave plasma treatment and heat treatment are performed, whereby the crystallinity of the first layer can be increased. Thus, the crystallinity of the second layer that is formed over the first layer by the first formation method can be increased using the first layer as a nucleus or a seed. When one or both of microwave plasma treatment and heat treatment are performed after formation of the second layer, the crystallinity of the oxide semiconductor layer can be increased. Accordingly, the CAAC structure can be formed in the oxide semiconductor layer.

As described above, even in the formation method not using the second formation method, the use of the first layer formed by the first formation method as a nucleus or a seed enables solid-phase growth of the layer above the first layer, whereby an oxide semiconductor with high crystallinity can be formed. An oxide semiconductor formed by such a formation method can also be referred to as an AG CAAC.

In the case where the oxide semiconductor layer has a stacked-layer structure of two or more layers, the oxide semiconductor layer can also be formed by forming metal oxides by one kind of formation method. In the case where the oxide semiconductor layer has a two-layer structure of a first layer and a second layer over the first layer, the oxide semiconductor layer can be formed by forming the first layer and the second layer in this order by a sputtering method, for example. A sputtering method, which achieves a higher deposition rate than an ALD method, can increase the productivity. As another example, in the case where the oxide semiconductor layer has a three-layer structure of a first layer, a second layer over the first layer, and a third layer over the second layer, the first to third layers can be formed by a sputtering method. Furthermore, some of the first to third layers can be formed by an ALD method. For example, one or both of the second layer and the third layer may be formed by an ALD method.

### [Oxide Semiconductor Layer of Transistor]

The oxide semiconductor layer of this embodiment can be used as a semiconductor layer of a transistor.

The oxide semiconductor layer of this embodiment can be used as the oxide semiconductor layer 230 or the like included in the transistors described in Embodiment 1. The layer serving as the formation surface corresponds to the insulating layer 225 or the like described in e.g., Embodiment 1. For example, the first layer can be used as the oxide semiconductor layer 230a1 and the oxide semiconductor layer 230b1 illustrated in FIGS. 14A and 14B, the second layer can be used as the oxide semiconductor layer 230a2 and the oxide semiconductor layer 230b2 illustrated in FIGS. 14A and 14B. Furthermore, the third layer can be used as the oxide semiconductor layer 230a3 and the oxide semiconductor layer 230b3 illustrated in FIG. 14B.

The oxide semiconductor layer of this embodiment preferably has the CAAC structure. In the oxide semiconductor layer having the CAAC structure, metal atoms are arranged in a crystal part in a layered manner in the direction parallel or substantially parallel to the formation surface.

The oxide semiconductor layer having the CAAC structure is presumed to exhibit current anisotropy. For example, in an IGZO crystal, current flows more easily in the a-axis direction than in the c-axis direction. That is, in the oxide semiconductor layer having the CAAC structure, current is presumed to flow easily in the lateral direction rather than in the vertical direction.

In the oxide semiconductor layer 230 of the semiconductor device described in the foregoing embodiment, metal atoms are arranged in a layered manner in the direction parallel or substantially parallel to the formation surface. This can also be expressed that “the a-b plane of the CAAC structure is provided to be parallel or substantially parallel to the formation surface”. With such a structure, the a-b plane of the CAAC structure can be provided along a current flow direction in a channel of the transistor. Accordingly, the transistor can have a high on-state current.

In the case where the oxide semiconductor layer of this embodiment is used as a semiconductor layer of a transistor, the thickness of the oxide semiconductor layer is preferably greater than or equal to 3 nm and less than or equal to 200 nm, further preferably greater than or equal to 3 nm and less than or equal to 100 nm, further preferably greater than or equal to 5 nm and less than or equal to 100 nm, still further preferably greater than or equal to 10 nm and less than or equal to 100 nm, still further preferably greater than or equal to 10 nm and less than or equal to 70 nm, yet further preferably greater than or equal to 15 nm and less than or equal to 70 nm, yet further preferably greater than or equal to 15 nm and less than or equal to 50 nm, yet still further preferably greater than or equal to 20 nm and less than or equal to 50 nm, for example. In a transistor used for a further downsized semiconductor device, the thickness of the oxide semiconductor layer 230 is preferably greater than or equal to 1 nm and less than or equal to 20 nm, further preferably greater than or equal to 3 nm and less than or equal to 15 nm, still further preferably greater than or equal to 5 nm and less than or equal to 12 nm, yet further preferably greater than or equal to 5 nm and less than or equal to 10 nm. The average thickness of the oxide semiconductor layer in a channel formation region of the transistor is particularly preferably greater than or equal to 2 nm and less than or equal to 15 nm, for example.

The thickness of the first layer is preferably greater than or equal to 0.5 nm and less than or equal to 50 nm, further preferably greater than or equal to 0.5 nm and less than or equal to 30 nm, further preferably greater than or equal to 0.5 nm and less than or equal to 20 nm, still further preferably greater than or equal to 1 nm and less than or equal to 50 nm, still further preferably greater than or equal to 1 nm and less than or equal to 30 nm, yet further preferably greater than or equal to 1 nm and less than or equal to 20 nm, yet still further preferably greater than or equal to 2 nm and less than or equal to 20 nm, for example. The thickness of the first layer is further preferably greater than or equal to 0.5 nm and less than or equal to 3.0 nm.

The first layer preferably includes a region with a thickness greater than or equal to 0.1 nm and less than or equal to 3 nm, and further preferably includes a region with a thickness greater than or equal to 0.1 nm and less than or equal to 2 nm. Alternatively, the first layer preferably includes a region with a thickness greater than or equal to 0.5 nm and less than or equal to 3 nm, and further preferably includes a region with a thickness greater than or equal to 0.5 nm and less than or equal to 2 nm.

The thickness of the second layer is preferably less than 200 nm, for example. In the case where the second layer is in the form of layer, the thickness of the second layer is preferably greater than or equal to 1 nm and less than 200 nm, further preferably greater than or equal to 1 nm and less than or equal to 100 nm, still further preferably greater than or equal to 2 nm and less than or equal to 100 nm, for example.

Alternatively, in some cases, the second layer is not in the form of layer but is an aggregate of island-shaped regions as long as the second layer can function as a crystal nucleus. In such a case, the island-shaped regions of the second layer are discretely present, for example.

The description of the thickness of the first layer can be referred to for the preferred range of the thickness of the third layer.

### [Impurities in Oxide Semiconductor Layer]

The influence of impurities in the oxide semiconductor layer is described here.

As has been described in the foregoing embodiment, in a transistor using the oxide semiconductor as a semiconductor layer, the electrical characteristics may vary easily and the reliability may be decreased when oxygen vacancies (Vo) and impurities are present in a channel formation region in the oxide semiconductor layer. Accordingly, in order to obtain stable electrical characteristics of the OS transistor, reducing the impurity concentration in the oxide semiconductor layer is effective. In order to reduce the impurity concentration in the oxide semiconductor layer, it is preferable that the impurity concentration in an adjacent film be also reduced. Examples of impurities include hydrogen, carbon, and nitrogen. Note that impurities in an oxide semiconductor layer refer to, for example, elements other than the main components of an oxide semiconductor. For example, an element whose concentration is lower than 0.1 atomic % is an impurity.

When an oxide semiconductor contains silicon or carbon, which is a Group 14 element, defect states are formed in the oxide semiconductor. Accordingly, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

When the oxide semiconductor contains nitrogen, electrons serving as carriers are generated to increase the carrier concentration and thus the resistance is easily lowered. As a result, a transistor including, as a semiconductor, an oxide semiconductor that contains nitrogen tends to have normally-on characteristics. Alternatively, when the oxide semiconductor contains nitrogen, a trap state is sometimes formed. This may make the electrical characteristics of the transistor unstable. Accordingly, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus an oxygen vacancy is formed in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²¹ atoms/cm³, preferably lower than 5×10¹⁹ atoms/cm³, further preferably lower than 1×10¹⁹ atoms/cm³, still further preferably lower than 5×10¹⁸ atoms/cm³, still further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

This embodiment can be combined with any of the other embodiments as appropriate. In this specification, in the case where a plurality of structure examples are shown in one embodiment, the structure examples can be combined as appropriate.

### Embodiment 3

In this embodiment, a semiconductor device of one embodiment of the present invention will be described with reference to drawings. The semiconductor device of one embodiment of the present invention includes a memory cell. The memory cell includes a transistor and a capacitor.

### Structure Example 1 of Semiconductor Device

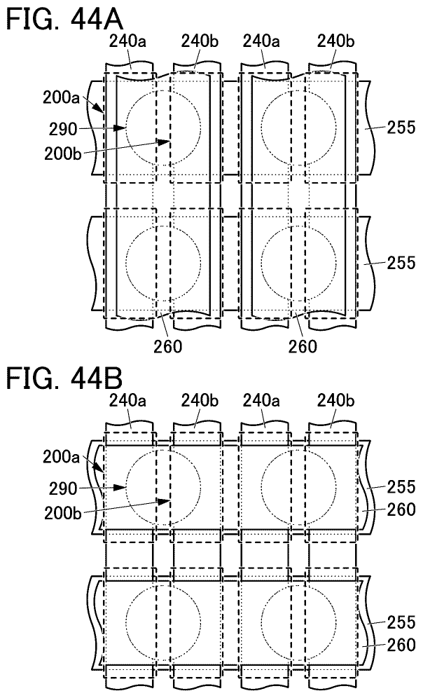

FIGS. 44A and 44B are plan views each illustrating a structure example of the semiconductor device. FIG. 44A illustrates a region including 2×2 memory cells 150a and 2×2 memory cells 150b. In addition, the conductive layer 255 functioning as the wiring WOL, the conductive layer 260 functioning as the wiring BGL, the conductive layer 240a functioning as the wiring BILa, the conductive layer 240b functioning as the wiring BILb, and the opening portion 290 are illustrated.

As illustrated in FIG. 44A, the memory cell 150a is provided at an intersection of the conductive layer 255 extending in the X direction and the conductive layer 240a extending in the Y direction. The memory cell 150b is provided at an intersection of the conductive layer 255 extending in the X direction and the conductive layer 240b extending in the Y direction. As illustrated in FIG. 44A, the width of the opening portion 290 can be smaller than the width of the short side of the conductive layer 255. Thus, it can be said that the memory cell 150 can be highly integrated and miniaturized.

Although FIG. 44A illustrates a structure in which the conductive layer 260 is provided to extend in the Y direction, the present invention is not limited to the structure. For example, as illustrated in FIG. 44B, the conductive layer 260 may be provided to extend in the X direction. Thus, the conductive layer 260 intersects with the conductive layer 240a or 240b, so that the conductive layer 260 can function as the wiring WOL. In this case, the conductive layer 255 functions as the wiring BGL.

Note that in the structure illustrated in FIG. 44B, the conductive layer 255 may be provided to extend in the Y direction.

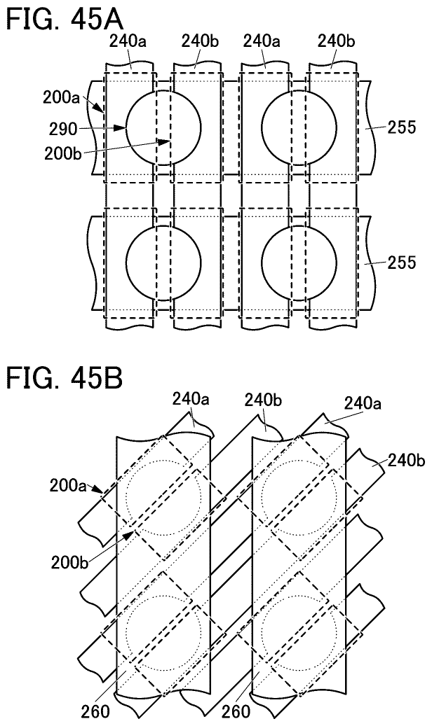

FIG. 45A is a plan view illustrating a structure example of a semiconductor device of the case where the transistor 200C described in Embodiment 1 is used as the transistor included in the memory cell 150. FIG. 45A illustrates a region including 2×2 memory cells 150a and 2×2 memory cells 150b. In addition, the conductive layer 255 functioning as the wiring WOL, the conductive layer 240a functioning as the wiring BILa, the conductive layer 240b functioning as the wiring BILb, and the opening portion 290 are illustrated.

As illustrated in FIG. 45A, the memory cell 150a is provided at an intersection of the conductive layer 255 extending in the X direction and the conductive layer 240a extending in the Y direction. The memory cell 150b is provided at an intersection of the conductive layer 255 extending in the X direction and the conductive layer 240b extending in the Y direction. As illustrated in FIG. 45A, the width of the opening portion 290 can be smaller than the width of the short side of the conductive layer 255. Thus, it can be said that the memory cell 150 can be highly integrated and miniaturized.

FIG. 45B is a plan view illustrating a structure example of a semiconductor device of the case where the transistor 200D described in Embodiment 1 is used as the transistor included in the memory cell 150. FIG. 45B illustrates a region including 2×2 memory cells 150a and 2×2 memory cells 150b. In addition, the conductive layer 260 functioning as the wiring WOL, the conductive layer 240a functioning as the wiring BILa, the conductive layer 240b functioning as the wiring BILb, and the opening portion 290 are illustrated.

As illustrated in FIG. 45B, the conductive layers 240a and 240b are provided such that the extending directions thereof are inclined with respect to the Y direction. The memory cell 150a is provided at an intersection of the conductive layer 240a and the conductive layer 260 extending in the Y direction. The memory cell 150b is provided at an intersection of the conductive layer 260 extending in the Y direction and the conductive layer 240b. As illustrated in FIG. 45B, the width of the opening portion 290 can be smaller than the width of the short side of the conductive layer 260. Thus, it can be said that the memory cell 150 can be highly integrated and miniaturized.

### Structure Example 2 of Semiconductor Device

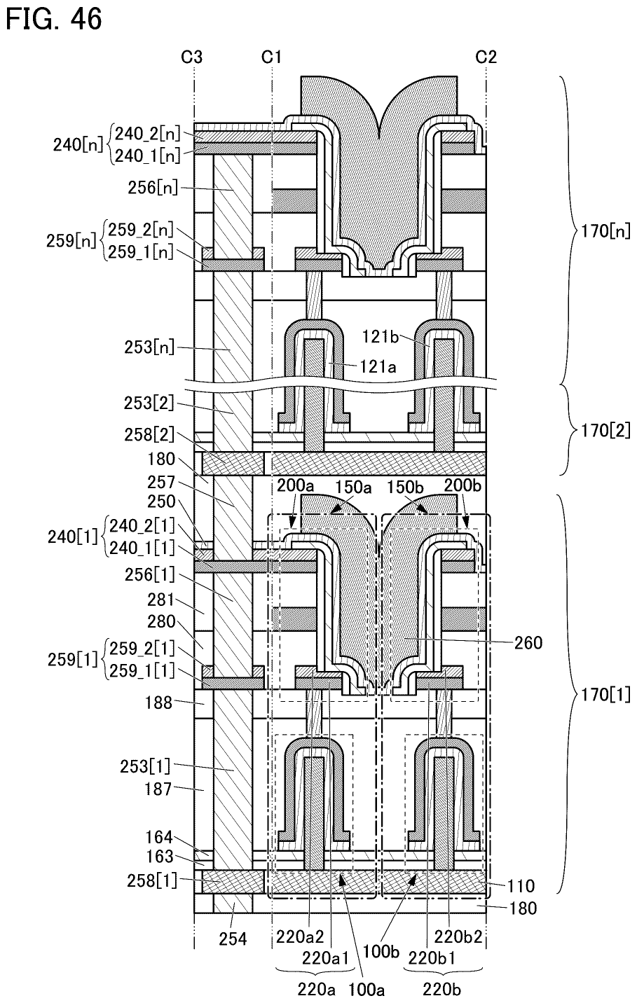

In a semiconductor device of one embodiment of the present invention, a plurality of transistors can be stacked, for example. FIG. 46 illustrates an example in which n layers (n is an integer greater than or equal to 3) of the capacitors 100 and the transistors 200 illustrated in FIG. 2A are stacked in the Z direction. The memory cells 150 are provided in a region between the dashed triplicate-dotted lines C1 and C2 in FIG. 46. Furthermore, a region between the dashed triplicate-dotted lines C1 and C3 includes a region where the conductive layer 240 extends.

The semiconductor device illustrated in FIG. 46 includes n memory layers 170. In FIG. 46, the n memory layers 170 are distinguishably shown with reference numerals 170[1] to 170[n].

Specifically, a memory layer 170[2] is provided over the memory layer 170[1], and (n−2) memory layers 170 are provided over the memory layer 170[2]. The memory layer 170[n] is provided as the uppermost layer. The memory cells 150 each including the capacitor 100 and the transistor 200 are provided in each memory layer 170. The insulating layer 180 is provided under each of the memory layers 170[1] to 170[n]. The insulating layers 180 other than the insulating layer 180 positioned under the memory layer 170[1] can each be provided to cover the conductive layer 260.

There is no particular limitation on the number of memory cells 150 included in one memory layer 170, and two or more memory cells 150 can be included. Through a conductive layer 254, a conductive layer 253, a conductive layer 256, a conductive layer 257, a conductive layer 258, a conductive layer 259, and the like, the memory cells 150 included in the n memory layers 170 are connected to a sense amplifier (not illustrated) provided below the n memory layers 170. In this case, the conductive layers 254, 253, 256, 257, 258, and 259 and the like function as part of the wiring BIL illustrated in FIG. 3C. Stacking the plurality of memory cells 150 in this manner can increase the memory capacity per unit area.

FIG. 46 illustrates an example in which the conductive layer 240 has a two-layer structure of a conductive layer 240_1 and a conductive layer 240_2. For the conductive layer 2401, the description of the conductive layers 240a1 and 240b1 in Embodiment 1 can be referred to. For the conductive layer 240_2, the description of the conductive layers 240a2 and 240b2 in Embodiment 1 can be referred to. In FIG. 46, the conductive layers 240_1 and the conductive layers 240_2 provided in the memory layers 170[1] to 170[n] are distinguishably shown with reference numerals 240_1[1] to 240_1[n] and 240_2[1] to 240_2[n], respectively. Note that the conductive layer 240_1 and the conductive layer 240_2 may be collectively referred to as a conductive layer 240. In FIG. 46, the conductive layers 240 provided in the memory layers 170[1] to 170[n] are distinguishably shown with reference numerals 240[1] to 240[n].

The conductive layers 253, the conductive layers 256, and the conductive layers 259 provided in the memory layers 170[1] to 170[n] are distinguishably shown with reference numerals 253[1] to 253[n], 256[1] to 256[n], and 259[1] to 259[n], respectively. Furthermore, the conductive layers 258 provided in the memory layers 170[1] and 170[2] are distinguishably shown with reference numerals 258[1] and 258[2].

Note that the conductive layers 254, 253, 256, 257, 258, 259, and the like may function as plugs or wirings for connecting the memory cell 150 to a circuit element such as a switch, a transistor, a capacitor, an inductor, a resistor, or a diode, a wiring, an electrode, or a terminal.

FIG. 46 illustrates an example in which the conductive layer 258 is provided on the same formation surface as the conductive layer 110. Furthermore, in the example illustrated in FIG. 46, the conductive layer 259 is provided on the same formation surface as the conductive layers 220a and 220b. The conductive layer 259 includes a conductive layer 2591 and a conductive layer 259_2 over the conductive layer 259_1. The conductive layer 259_1 is provided on the same formation surface as the conductive layers 220a1 and 220b1. The conductive layer 259_2 is provided on the same formation surface as the conductive layers 220a2 and 220b2. The conductive layer 258 can be formed in the same process as the conductive layer 110 and can include the same material as the conductive layer 110. The conductive layer 259_1 can be formed in the same process as the conductive layers 220a1 and 220b1 and can include the same material as the conductive layers 220a1 and 220b1. The conductive layer 259_2 can be formed in the same process as the conductive layers 220a2 and 220b2 and can include the same material as the conductive layers 220a2 and 220b2. Note that the conductive layers 259_1 and the conductive layers 259_2 included in the conductive layers 259[1] to 259[n] are distinguishably shown with reference numerals 259_1[1] to 259_1[n] and 259_2[1] to 259_2[n], respectively.

FIG. 46 illustrates an example in which the conductive layer 254 is provided in an opening portion of the insulating layer 180 under the memory layer 170[1]. In the illustrated example, the conductive layer 253 is provided in opening portions of the insulating layers 163, 164, 187, and 188. Moreover, the conductive layer 256 is provided in opening portions of the conductive layer 259_2, the insulating layer 280, and the insulating layer 281. Furthermore, the conductive layer 257 is provided in opening portions of the conductive layer 240_2, the insulating layer 250, and the insulating layer 180.

FIG. 46 illustrates an example in which the insulating layer 121a functioning as the dielectric of the capacitor 100a and the insulating layer 121b functioning as the dielectric of the capacitor 100b are not provided in the region between the dashed triplicate-dotted lines C1 and C3. This eliminates the need for formation of the opening portion in which the conductive layer 253 is provided in the insulating layer functioning as the dielectric and thus makes it possible to easily form the opening portion. Note that in the case where the insulating layer functioning as the dielectric can be processed under the same conditions as those for the insulating layer 187 or 164, for example, the insulating layer functioning as the dielectric may be provided in the region between the dashed triplicate-dotted lines C1 and C3. In that case, the insulating film functioning as the insulating layers 121a and 121b does not need to be processed before the formation of the insulating layer 187. Thus, the number of manufacturing steps of the semiconductor device can be reduced.

The conductive layer 254 can be in contact with the bottom surface of the conductive layer 258[1]. The conductive layer 253 can be in contact with the top surface of the conductive layer 258 and the bottom surface of the conductive layer 259_1. The conductive layer 256 can be in contact with the top surface of the conductive layer 259_1 and the bottom surface of the conductive layer 240_1. The conductive layer 257 can be in contact with the top surface of the conductive layer 240_1 and the bottom surface of the conductive layer 258. In the above-described manner, the conductive layers 240[1] to 240[n] can be connected to each other. Note that the conductive layers 253, 254, 256, and 257 can each be formed using a conductive material that is usable for the conductive layer 240, for example.

In the case where the contact resistance between the conductive layer 259_1 and the conductive layer 256 is lower than the contact resistance between the conductive layer 259_2 and the conductive layer 256, an opening portion in which the conductive layer 256 is provided is preferably provided also in the conductive layer 259_2 as illustrated in FIG. 46. In the case where the contact resistance between the conductive layer 240_1 and the conductive layer 257 is lower than the contact resistance between the conductive layer 240_2 and the conductive layer 257, an opening portion in which the conductive layer 257 is provided is preferably provided also in the conductive layer 240_2 as illustrated in FIG. 46.

When a plurality of memory cells 150 are stacked as illustrated in FIG. 46, the memory cells 150 can be provided in an integrated manner without increasing the area occupied by the memory cell array. That is, a 3D memory cell array can be formed. This results in an increase in the memory capacity per unit area.

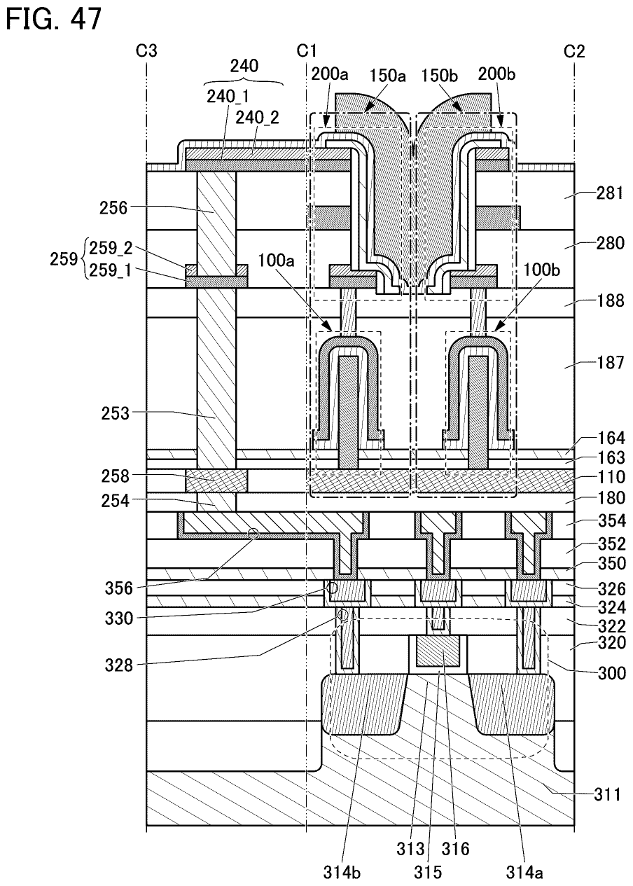

FIG. 47 illustrates a cross-sectional structure example of a semiconductor device in which a layer including the memory cells 150 is stacked over a layer in which a driver circuit including a sense amplifier is provided.

In FIG. 47, the memory cells 150 (the transistors 200 and the capacitors 100) are provided above a transistor 300.

The transistor 300 is one of the transistors included in the sense amplifier.

When the sense amplifier is provided to overlap with the memory cells 150 as illustrated in FIG. 47, the bit line can be shortened. Accordingly, the bit line capacitance can be reduced and the semiconductor device can be driven at high speed.

The semiconductor device illustrated in FIG. 47 can correspond to a semiconductor device 900 described in Embodiment 4. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 may be either a p-channel transistor or an n-channel transistor. The substrate 311 preferably includes a silicon-based semiconductor, specifically, single crystal silicon.

In the transistor 300 illustrated in FIG. 47, the semiconductor region 313 (part of the substrate 311) where a channel is formed has a projecting shape. Furthermore, the conductive layer 316 is provided to cover the side surface and top surface of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer functioning as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 47 is just an example and is not limited to having the structure illustrated therein; an appropriate transistor can be used in accordance with the circuit structure or the driving method.

A wiring layer including an interlayer film, a wiring, a plug, and the like may be provided between components. A plurality of wiring layers can be provided in accordance with the design. Here, a plurality of conductive layers functioning as plugs or wirings are collectively denoted by the same reference numeral in some cases. In this specification and the like, a wiring and a plug connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 300 in this order as interlayer films. A conductive layer 328 is embedded in the insulating layers 320 and 322, and a conductive layer 330 is embedded in the insulating layers 324 and 326. Note that the conductive layers 328 and 330 each function as a plug or a wiring.

The insulating layer functioning as an interlayer film may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. For example, in FIG. 47, an insulating layer 350, an insulating layer 352, and an insulating layer 354 are stacked sequentially. Furthermore, a conductive layer 356 is formed in the insulating layers 350, 352, and 354. The conductive layer 356 functions as a plug or a wiring.

As the insulating layers 352 and 354 and the like functioning as interlayer films, the above-described insulating layer that can be used for the semiconductor device can be used.

As each of the conductive layers functioning as plugs or wirings, such as the conductive layers 328, 330, and 356, a conductive material that can be used for the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 is connected to the low-resistance region 314b functioning as the source or drain region of the transistor 300 through the conductive layers 256, 259, 253, 258, 254, 356, 330, and 328. For the conductive layers 256, 259, 253, 258, and 254, the description of FIG. 46 can be referred to.

This embodiment can be combined with any of the other embodiments as appropriate. In this specification, in the case where a plurality of structure examples are shown in one embodiment, the structure examples can be combined as appropriate.

### Embodiment 4

In this embodiment, the semiconductor device 900 of one embodiment of the present invention will be described. The semiconductor device 900 can function as a memory device.

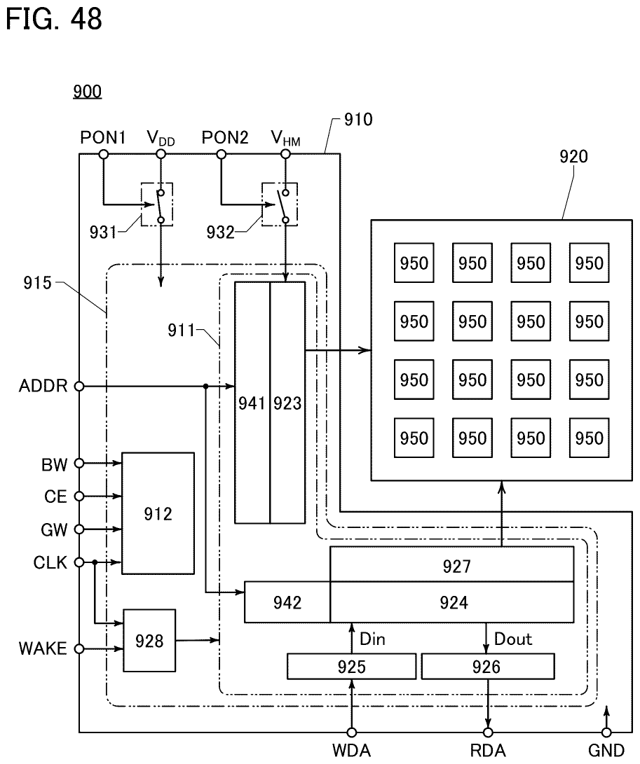

FIG. 48 is a block diagram illustrating a structure example of the semiconductor device 900. The semiconductor device 900 illustrated in FIG. 48 includes a driver circuit 910 and a memory array 920. The memory array 920 includes at least one memory cell 950. FIG. 48 illustrates an example where the memory array 920 includes a plurality of memory cells 950 arranged in a matrix.

The memory device (e.g., the memory device 150) described in Embodiment 3 can be used for the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. In addition, the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply potential is V_{DD} and a low power supply potential is a ground potential (GND). In addition, V_{HM} is a high power supply potential used for setting a word line at a high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 48 but can be more than one. In that case, a power switch can be provided for each power domain.

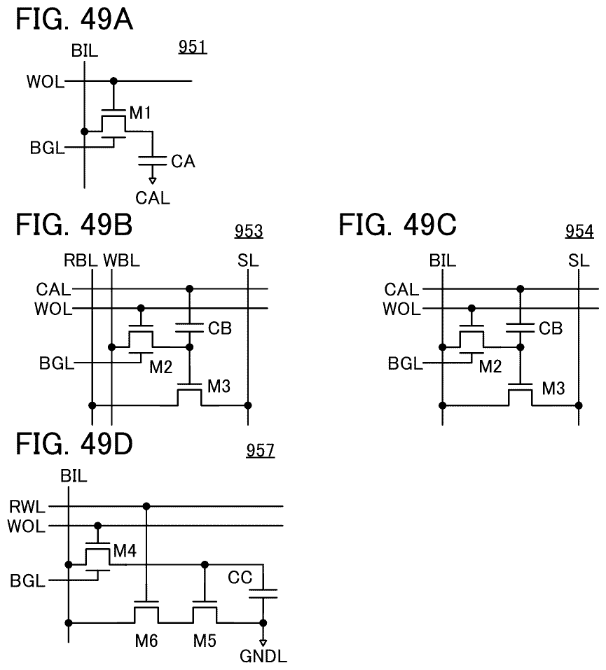

Structure examples of memory cells each of which can be used as the memory cell 950 are described with reference to FIGS. 49A to 49D.

### [DOSRAM]

FIG. 49A illustrates a circuit structure example of a memory cell for a DRAM. In this specification and the like, a DRAM using an OS transistor is referred to as a dynamic oxide semiconductor random access memory (DOSRAM). A memory cell 951 includes a transistor M1 and a capacitor CA.

The transistor M1 includes a gate (sometimes referred to as a top gate) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to the wiring BIL. A gate of the transistor M1 is connected to the wiring WOL, and the back gate of the transistor M1 is connected to the wiring BGL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and data reading, a low-level potential (sometimes referred to as a reference potential) is preferably applied to the wiring CAL. The wiring BGL functions as a wiring for applying a potential to the back gate of the transistor M1. The threshold voltage of the transistor M1 can be increased or decreased by applying a given potential to the wiring BGL.

Data writing and data reading are performed in such a manner that a high-level potential is applied to the wiring WOL to turn on the transistor M1 and establish electrical continuity between the wiring BIL and the first terminal of the capacitor CA (make a state where a current can flow therethrough).

The memory cell that can be used as the memory cell 950 is not limited to the memory cell 951, and the circuit structure can be changed. For example, in the memory cell 950, the back gate of the transistor M1 is connected to the wiring WOL instead of the wiring BGL. In another example of the memory cell 950, the transistor M1 may be a single-gate transistor, that is, a transistor without a back gate. For example, the memory cell 951 does not necessarily include the capacitor CA or the wiring CAL, and the first terminal of the transistor M1 may be in a floating state.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased or the refresh operation for the memory cell does not needed to be performed. In addition, owing to an extremely low leakage current, multilevel data or analog data can be retained in the memory cell 951.

### [NOSRAM]

FIG. 49B illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. A gate of the transistor M2 is connected to the wiring WOL and a back gate of the transistor M2 is connected to the wiring BGL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided in place of the wiring WBL and the wiring RBL. A circuit structure example of the memory cell is illustrated in FIG. 49C. In a memory cell 954, one wiring BIL is provided in place of the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

An OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased or the refresh operation for the memory cell does not needed to be performed. In addition, owing to an extremely low leakage current, multilevel data or analog data can be retained in the memory cells 953 and 954.

The memory cells 953 and 954 each using the OS transistor as the transistor M2 are embodiments of a NOSRAM.

In addition, a Si transistor may be used as the transistor M3. The Si transistor can have high field-effect mobility and can be formed as a p-channel transistor, so that circuit design flexibility can be increased.

When an OS transistor is used as the transistor M3, the memory cell can be configured with transistors having the same conductivity type.

FIG. 49D illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL and a back gate of the transistor M4 is connected to the wiring BGL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than an OS transistor depending on the crystal state of silicon used in a semiconductor layer, for example.

When OS transistors are used as the transistors M5 and M6, the memory cell can be configured with the transistors having the same conductivity type.

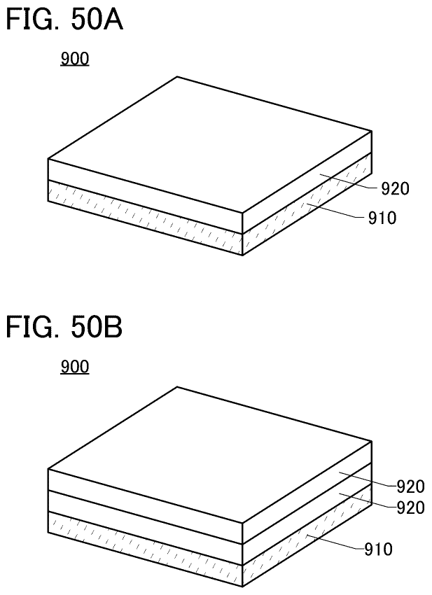

The driver circuit 910 and the memory array 920 included in the semiconductor device 900 may be provided on the same plane. Alternatively, as illustrated in FIG. 50A, the driver circuit 910 and the memory array 920 may be stacked. Stacking the driver circuit 910 and the memory array 920 can shorten a signal propagation distance. As illustrated in FIG. 50B, a plurality of memory arrays 920 may be stacked over the driver circuit 910.

Next, description is made on an example of an arithmetic processing device that can include the semiconductor device such as the memory device described above.

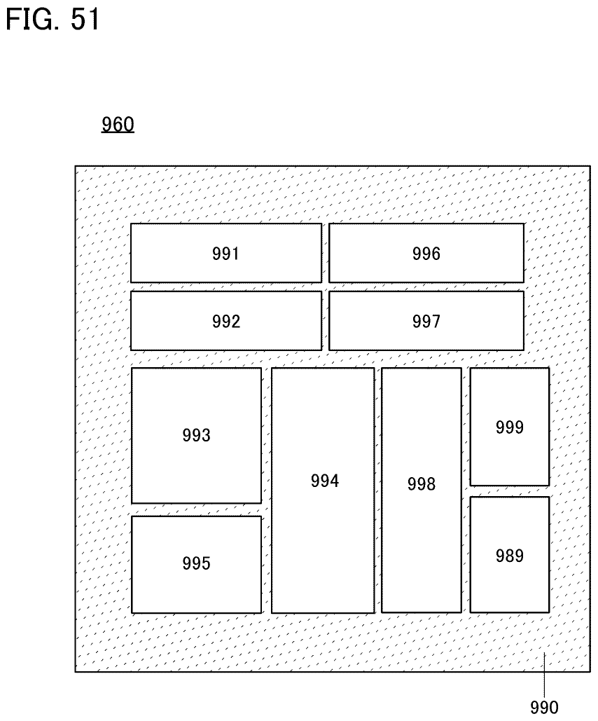

FIG. 51 is a block diagram of an arithmetic device 960. The arithmetic device 960 illustrated in FIG. 51 can be used as a CPU, for example. The arithmetic device 960 can also be used as a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 51 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

It is also possible that the cache 999 is not provided and only the memory array 920 is used as a cache.

The arithmetic device 960 illustrated in FIG. 51 is just an example with a simplified structure, and the actual arithmetic device 960 has a variety of structures depending on the application. For example, what is called a multicore structure is preferably employed where a plurality of cores each including the arithmetic device 960 in FIG. 51 operate in parallel. The larger number of cores can further enhance the arithmetic performance. The number of cores is preferably larger; for example, the number is preferably 2, further preferably 4, still further preferably 8, yet still further preferably 12, yet still further preferably 16 or larger. For application requiring extremely high arithmetic performance, e.g., a server, it is preferable to employ the multicore structure including 16 or more cores, preferably 32 or more cores, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above-described circuits.

In the arithmetic device 960 illustrated in FIG. 51, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply potential is supplied to the memory cell in the register 996. When data retention by the capacitor is selected, the data is rewritten into the capacitor, and supply of the power supply potential to the memory cell in the register 996 can be stopped.

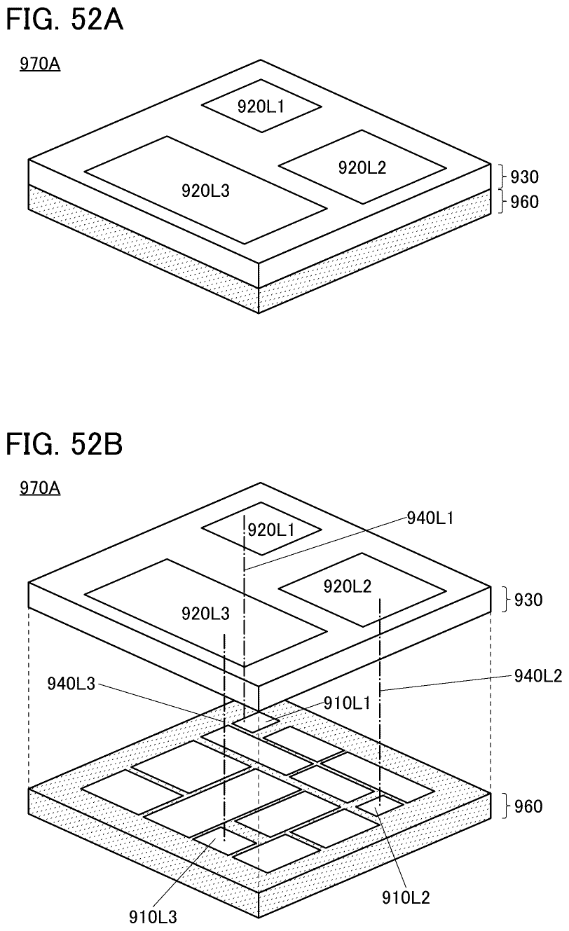

The memory array 920 and the arithmetic device 960 can be provided to overlap with each other. FIGS. 52A and 52B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 52B.

Stacking the arithmetic device 960 and the layer 930 provided with the memory arrays can shorten the connection distance therebetween. Accordingly, the communication speed therebetween can be increased. Moreover, the short connection distance leads to lower power consumption.

As a method for stacking the arithmetic device 960 and the layer 930 provided with the memory arrays, either of the following methods may be employed: a method in which the layer 930 provided with the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

In addition, in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 52B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although three memory arrays function as caches here, the number of memory arrays functioning as caches may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

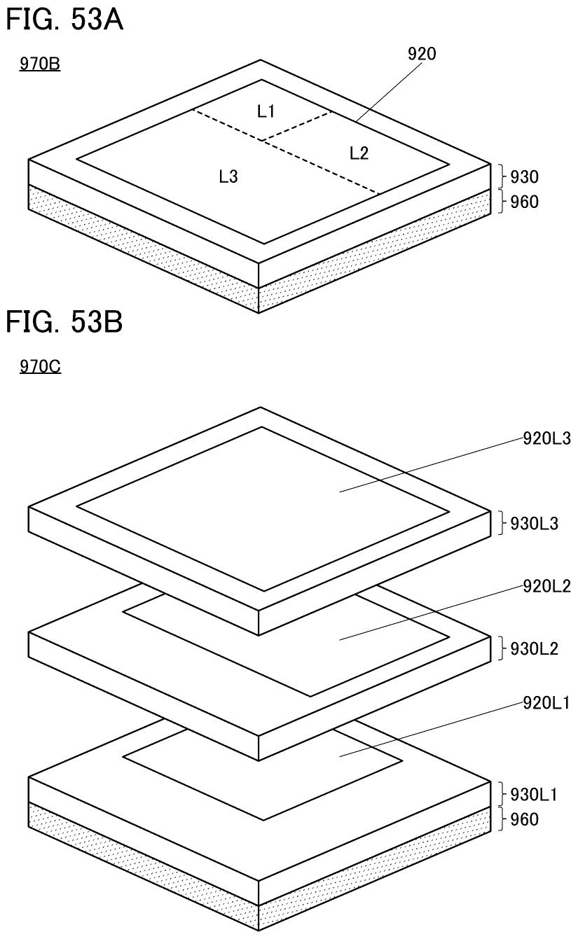

The layer 930 including one memory array 920 may be provided to overlap with the arithmetic device 960. FIG. 53A is a perspective view of a semiconductor device 970B.

In the semiconductor device 970B, one memory array 920 can be divided into a plurality of areas having different functions. FIG. 53A illustrates an example where a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 53B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate. In this specification, in the case where a plurality of structure examples are shown in one embodiment, the structure examples can be combined as appropriate.

### Embodiment 5

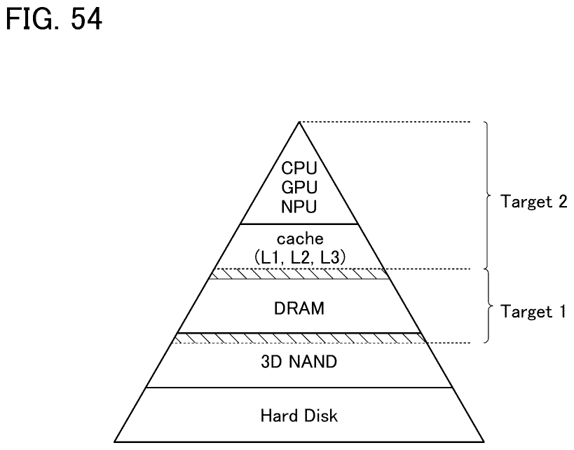

In this embodiment, an example of an application range of a semiconductor device of one embodiment of the present invention is described with reference to FIG. 54.

A variety of memory devices are used in semiconductor devices such as computers in accordance with the intended use. FIG. 54 is a conceptual diagram showing a hierarchy of memory devices used in semiconductor devices. In the conceptual diagram in FIG. 54, the hierarchy of memory devices is shown by a triangle; the memory devices at higher levels in the triangle require higher operation speed, and the memory devices at lower levels in the triangle require higher memory capacity and higher recording density.

In FIG. 54, memories included as registers in arithmetic processing devices such as a CPU, a GPU, and an NPU, cache memories (sometimes simply referred to as caches, typically L1, L2, and L3 caches), main memories typified by DRAMs, 3D NANDs, and storage memories typified by hard disks (also referred to as hard disk drives (HDDs)) are shown in this order from the highest level in the triangle.

A memory included as a register in an arithmetic processing device such as a CPU, a GPU, or an NPU is used for temporary storage of arithmetic operation results, for example, and thus is very frequently accessed by the arithmetic processing device. Accordingly, high operation speed is required rather than high memory capacity. The register also has a function of retaining settings of the arithmetic processing device, for example.

The cache memory has a function of duplicating and retaining part of data retained in the DRAM. Duplicating frequently used data and retaining the duplicated data in the cache memory facilitates rapid data access. The cache memory requires lower memory capacity but requires higher operation speed than the DRAM. Data that is rewritten in the cache memory is duplicated, and the duplicated data is supplied to the DRAM. Only L1 to L3 caches are shown as the cache memories in the example illustrated FIG. 54, but one embodiment of the present invention is not limited to the example. For example, a memory device including the oxide semiconductor of one embodiment of the present invention can be suitably used as the last level cache (LLC) or a final level cache (FLC) positioned at the lowest level among the caches.

The DRAM has a function of retaining a program, data, or the like read from the 3D NAND.

The 3D NAND has a function of retaining data that needs to be stored for a long time, a variety of programs used in an arithmetic device (e.g., a model of an artificial neural network), and the like. Therefore, the 3D NAND requires high memory capacity and high recording density rather than high operating speed.

The hard disk has high capacity and a nonvolatile function. Instead of the hard disk, a solid state drive (SSD) or the like can be used.

The memory device including the oxide semiconductor (OS memory) of one embodiment of the present invention can retain data for a long time. Thus, the memory device can be suitably used for devices in a region denoted as Target 1 in FIG. 54. As indicated by hatching with oblique lines in FIG. 54, Target 1 also includes part of the caches (L1, L2, and L3) and part of the 3D NAND. In other words, Target 1 includes a boundary region between the DRAM and the 3D NAND and a boundary region between the DRAM and the caches (L1, L2, and L3). The memory device including the oxide semiconductor of one embodiment of the present invention operates at high speed, and thus can achieve excellent writing operation and excellent reading operation. Thus, the memory device can be suitably used for a region denoted as Target 2 in FIG. 54.

For example, the DRAM shown in FIG. 54 is suitably replaced with the memory device including the oxide semiconductor of one embodiment of the present invention. Refresh operation is essential for the DRAM, and the DRAM is a destructive read memory device and thus consumes higher power than other memory devices. Therefore, power consumption can be reduced with a structure not using the DRAM. With this structure, power consumption can be reduced to one-hundredth or less or one-thousandth or less that of a structure using the DRAM. Thus, global expansion of information processing devices, such as supercomputers (also referred to as a high performance computers (HPCs)), computers, and servers, having such a structure will lead to global warming mitigation.

As described above, the memory device including the oxide semiconductor of one embodiment of the present invention can be applied to a wide range of memories covering from a memory included as a register in an arithmetic processing device such as a CPU, a GPU, or an NPU to a memory in the boundary region between a DRAM and a 3D NAND.

This embodiment can be combined with any of the other embodiments as appropriate. In this specification, in the case where a plurality of structure examples are shown in one embodiment, the structure examples can be combined as appropriate.

### Embodiment 6

In this embodiment, examples of a circuit structure including the OS transistor of one embodiment of the present invention and examples of electronic components using the semiconductor device of one embodiment of the present invention are described with reference to drawings.

### <Circuit Structure Example>

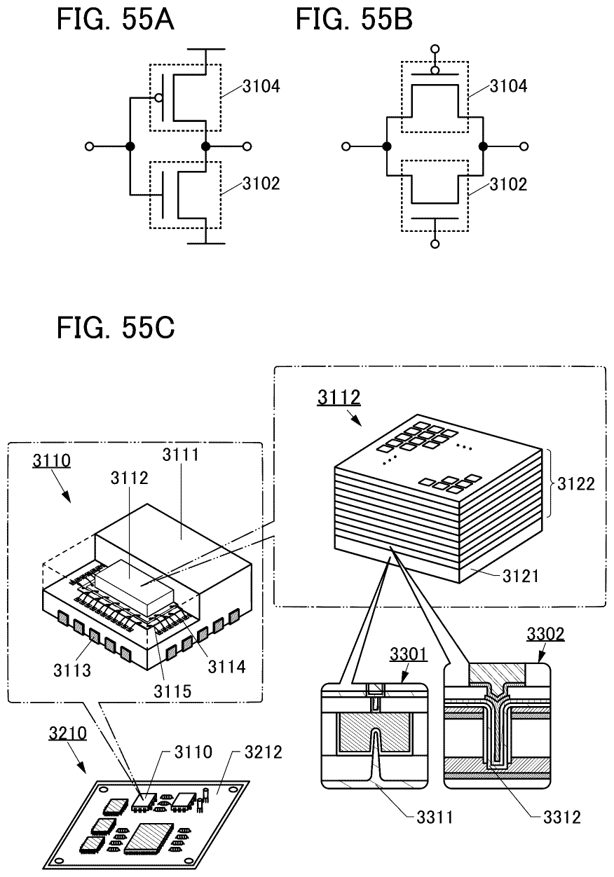

FIGS. 55A and 55B each illustrate an example of a circuit structure including the OS transistor of one embodiment of the present invention. The circuit diagram in FIG. 55A illustrates a structure of an inverter circuit formed of what is called a complementary metal oxide semiconductor (CMOS) circuit in which an n-channel transistor 3102 and a p-channel transistor 3104 are connected in series and their gates are connected. The circuit diagram in FIG. 55B illustrates a structure of a circuit that functions as what is called an analog switch, in which sources of the n-channel transistor 3102 and the p-channel transistor 3104 are connected to each other and drains of the n-channel transistor 3102 and the p-channel transistor 3104 are connected to each other.

### <Transistor Structure>

Any of various types of transistors can be used as the n-channel transistor 3102 and the p-channel transistor 3104 illustrated in FIGS. 55A and 55B. Specifically, a planar transistor, a vertical transistor, a Fin-type transistor, a gate all around (GAA) transistor, or the like can be used as the n-channel transistor 3102 and the p-channel transistor 3104. A complementary field effect transistor (CFET) in which the n-channel transistor 3102 and the p-channel transistor 3104 are combined may be used. Note that a transistor having the same structure as or a different structure from the structure of any of the transistors described in the above embodiments may be used as the vertical transistor.

In this specification and the like, a Fin-type transistor has a structure where two or more surfaces of a channel are covered with a gate electrode with a gate insulating film therebetween in a cross-sectional view in the channel width direction. In particular, the channel height (H) is preferably larger than the channel width (W) in the cross-sectional view in the channel width direction, in which case the channel width per unit area can be increased. In this specification and the like, a GAA transistor has a structure where a gate electrode covers four surfaces of a channel with a gate insulating film therebetween in a cross-sectional view in the channel width direction.

### <N-Channel Transistor>

An OS transistor of one embodiment of the present invention can be used as the n-channel transistor 3102 illustrated in FIGS. 55A and 55B. The OS transistor has an extremely low off-state current, and thus the leakage current of the n-channel transistor 3102 can be extremely low. In the n-channel transistor 3102, a single element semiconductor such as silicon or germanium, a compound semiconductor such as gallium arsenide, a layered material functioning as a semiconductor, or the like can be used as a semiconductor material. In particular, a layered material functioning as a semiconductor is preferably used as a semiconductor material.

In this specification and the like, the layered material is a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

In this specification and the like, the above-described layered material is sometimes referred to as a two-dimensional material. Examples of a two-dimensional material that can be used for the n-channel transistor 3102 and the p-channel transistor 3104 in one embodiment of the present invention include graphene, silicene (a substance in which a carbon atom of graphene is replaced with a silicon atom), germanene (a substance in which a carbon atom of graphene is replaced with a germanium atom), transition metal chalcogenides or transition metal dichalcogenides (TMDs), boron nitride (BN), and black phosphorus. Using the above-described two-dimensional material can improve one or more physical properties of electron mobility, mechanical strength, and thermal conductivity, compared with the case of using a single element semiconductor such as silicon or germanium. The above-described two-dimensional material has excellent physical properties compared with a single element semiconductor such as silicon; thus, the two-dimensional material may be referred to as a new material channel (NMC).

Examples of the layered material include chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

As a material that can be used for the n-channel transistor 3102, a transition metal chalcogenide functioning as a semiconductor is preferably used, for example. Specific examples of the transition metal chalcogenide include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### <P-Channel Transistor>

In the p-channel transistor 3104 illustrated in FIGS. 55A and 55B, a single element semiconductor such as silicon or germanium, a compound semiconductor such as gallium arsenide, a layered material functioning as a semiconductor, or the like can be used as a semiconductor material. In particular, a layered material functioning as a semiconductor is preferably used as a semiconductor material.

As a material that can be used for the p-channel transistor 3104, a transition metal chalcogenide functioning as a semiconductor is preferably used, for example. Specific examples of the transition metal chalcogenide include molybdenum sulfide (typically MoS₂), molybdenum selenide (typically MoSe₂), tungsten sulfide (typically WS₂), and tungsten selenide (typically WSe₂).

As the material that can be used for the p-channel transistor 3104, other than the above-described two-dimensional material, a Group III-IV compound semiconductor (typically, a gallium-arsenic compound semiconductor, an indium-phosphorus compound semiconductor, an indium-gallium-arsenic compound semiconductor, an indium-arsenic compound semiconductor, or the like), a carbon nanotube (CNT), tin sulfide (typically, SnS), tin selenide (typically, SnSe), or the like can be used. In addition, a Group III-IV compound semiconductor may be used for the n-channel transistor 3102.

### <Electronic Component Example>

FIG. 55C illustrates an example of an electronic component including the semiconductor device of one embodiment of the present invention. An electronic component including the semiconductor device or the memory device of one embodiment of the present invention is effective in reducing power consumption and improving performance.

FIG. 55C is a perspective view of a substrate (a circuit board 3210) provided with an electronic component 3110. The electronic component 3110 illustrated in FIG. 55C includes a memory device 3112 in a mold 3111. FIG. 55C omits some components to show the inside of the electronic component 3110. The electronic component 3110 includes a land 3113 outside the mold 3111. The land 3113 is connected to an electrode pad 3114, and the electrode pad 3114 is connected to the memory device 3112 through a wire 3115. The electronic component 3110 is mounted on a printed wiring board 3212, for example. A plurality of such electronic components are combined and electrically connected to each other on the printed circuit board 3212, which results in formation of the circuit board 3210.

The memory device 3112 includes a layer 3121 including an arithmetic core and a layer 3122 including a memory. For example, the above-described n-channel transistor and p-channel transistor can be used in both the layer 3121 and the layer 3122. It is particularly preferable that a p-channel transistor be used in the layer 3121 and an n-channel transistor be used in the layer 3122 to form a CMOS circuit. However, one embodiment of the present invention is not limited thereto, and both an n-channel transistor and a p-channel transistor may be included in the layer 3121 and an n-channel transistor may be used in the layer 3122.

Specifically, it is preferable that the layer 3121 include a p-channel transistor 3301 and the layer 3122 include an n-channel transistor 3302. In FIG. 55C, when a semiconductor layer 3311 included in the transistor 3301 is p-channel silicon and a semiconductor layer 3312 included in the transistor 3302 is an n-channel oxide semiconductor, a stacked-layer structure of a Si transistor and an OS transistor can be obtained.

Alternatively, in FIG. 55C, when the semiconductor layer 3311 included in the transistor 3301 is a p-channel two-dimensional material (e.g., WS₂) and the semiconductor layer 3312 included in the transistor 3302 is an n-channel oxide semiconductor, a stacked-layer structure of a WS₂ transistor and an OS transistor can be obtained. With such a stacked-layer structure, a memory device with low power consumption and high performance can be provided.

Stacking the two kinds of transistors reduces the area occupied by the circuit, allowing a plurality of circuits to be arranged at high density. FIG. 55C illustrates a structure where the transistor 3301 is a Fin-type transistor and the transistor 3302 is a VFET as a non-limiting example, but a Fin-type transistor may be used as the transistor 3301 and a Fin-type transistor may be used as the transistor 3302. It is preferable that the transistor 3301 and the transistor 3302 have different structures, in which case characteristics according to the respective transistor structures can be obtained. It is also preferable that the transistor 3301 and the transistor 3302 have the same structure, in which case some manufacturing apparatuses can be used in common.

The layer 3122 including the memory has a structure where a plurality of memory cell arrays are stacked. The layer 3121 including the arithmetic core and the layer 3122 including the memory can be stacked monolithically. In the monolithic stacked-layer structure, layers can be connected to each other without using a through electrode technique such as a through silicon via (TSV) technique and a bonding technique such as Cu—Cu direct bonding. The monolithic stacked-layer structure of the layer 3121 including the arithmetic core and the layer 3122 including the memory enables, for example, what is called an on-chip memory structure where a memory is directly formed on a processor. The on-chip memory structure allows an interface portion between the processor and the memory to operate at high speed. In addition, part of the function (part of the arithmetic function) of the layer 3121 including the arithmetic core may be provided in part of the layer 3122 including the memory.

With the on-chip memory structure, the sizes of a connection wiring and the like can be smaller than those in the case where the through electrode technique such as TSV is employed; thus, the number of connection pins can be increased. The increase in the number of connection pins enables parallel operations, which can improve the bandwidth of the memory (also referred to as a memory bandwidth).

It is preferable that the plurality of memory cell arrays included in the layer 3122 including the memory be formed with OS transistors and be monolithically stacked. The monolithic stacked-layer structure of memory cell arrays can improve the bandwidth of the memory and/or the access latency of the memory. The bandwidth refers to the data transfer volume per unit time, and the access latency refers to a period of time from data access to the start of data transmission. In the case where the layer 3122 including the memory is formed with Si transistors, the monolithic stacked-layer structure is difficult to form as compared with the case where the layer 3122 including the memory is formed with OS transistors. Therefore, an OS transistor is superior to a Si transistor in the monolithic stacked-layer structure.

This embodiment can be combined with any of the other embodiments as appropriate. In this specification, in the case where a plurality of structure examples are shown in one embodiment, the structure examples can be combined as appropriate.

### Embodiment 7

In this embodiment, application examples of the semiconductor device or the memory device of one embodiment of the present invention are described with reference to drawings.

The semiconductor device or the memory device of one embodiment of the present invention can be used for an electronic component, a large computer, space equipment, a data center (also referred to as DC), and a variety of electronic devices, for example. With the use of the semiconductor device or the memory device of one embodiment of the present invention, an electronic component, a large computer, space equipment, a data center, and a variety of electronic devices can have lower power consumption and higher performance.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

Examples of such an electronic device include watch-type and bracelet-type information terminal devices (wearable devices) and wearable devices that can be worn on a head, such as a VR device like a head-mounted display, a glasses-type AR device, and an MR device.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

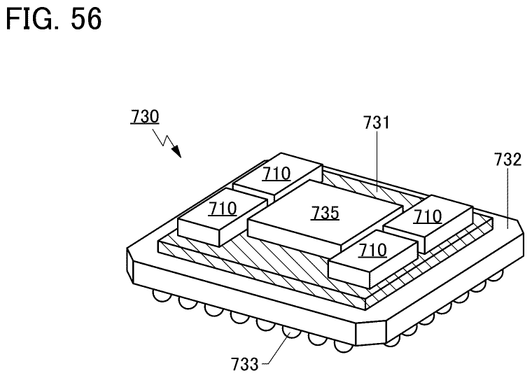

FIG. 56 is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The memory device 3112 described in Embodiment 6 can be used for the semiconductor device 710.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of connecting a plurality of integrated circuits with different terminal pitches. The plurality of wirings are provided in a single layer or multiple layers. In addition, the interposer 731 has a function of connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high flatness; thus, poor connection between the silicon interposer and an integrated circuit provided on the silicon interposer is less likely to occur. It is particularly preferable to use a silicon interposer for a 2.5D package (2.5-dimensional packaging) in which a plurality of integrated circuits are arranged side by side on the interposer.

In the case where a plurality of integrated circuits with different terminal pitches are connected with use of a silicon interposer, a TSV, and the like, a space for a width or the like of the terminal pitch is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure using OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 56 illustrates an example where the electrode 733 is formed of a solder ball. Solder balls are provided in a matrix on the bottom portion of the package substrate 732, so that ball grid array (BGA) packaging can be achieved. Alternatively, the electrode 733 may be formed of a conductive pin. When conductive pins are provided in a matrix on the bottom portion of the package substrate 732, pin grid array (PGA) packaging can be achieved.

The electronic component 730 can be mounted on another substrate by various packaging methods other than BGA and PGA. Examples of a packaging method include staggered pin grid array (SPGA), land grid array (LGA), quad flat package (QFP), quad flat J-leaded package (QFJ), and quad flat non-leaded package (QFN).

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

### [Large Computer]

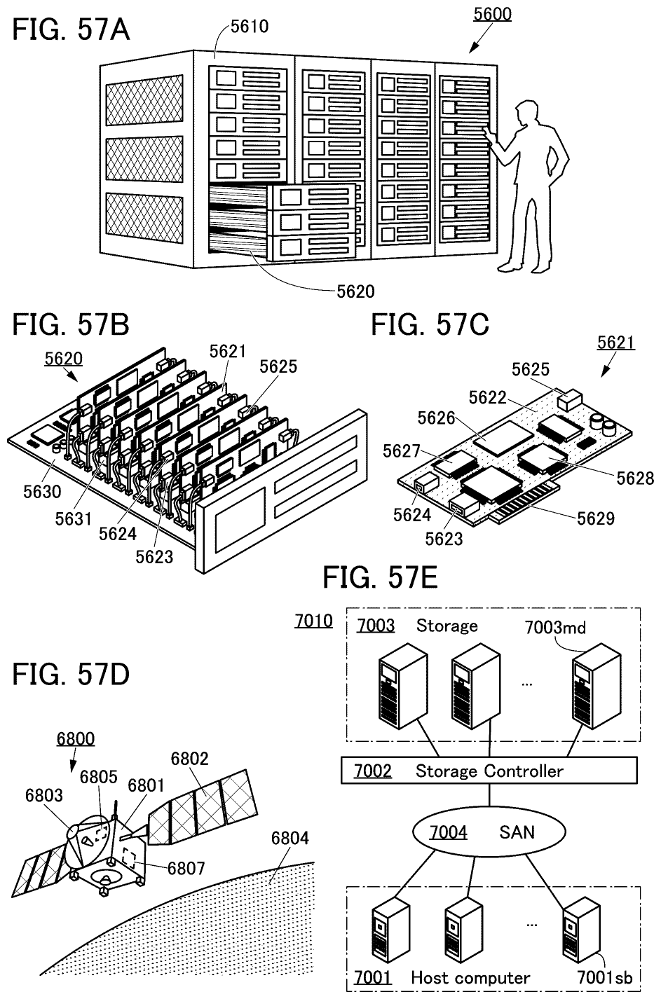

FIG. 57A is a perspective view of a large computer 5600. In the large computer 5600 illustrated in FIG. 57A, a plurality of rack mount computers 5620 are stored in a rack 5610. Note that the large computer 5600 may be referred to as a supercomputer.

The computer 5620 can have a structure illustrated in a perspective view in FIG. 57B, for example. In FIG. 57B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 57C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. FIG. 57C also illustrates semiconductor devices other than the semiconductor devices 5626, 5627, and 5628, and the following description of the semiconductor devices 5626, 5627, and 5628 can be referred to for the semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device or the like. As the semiconductor device 5628, the electronic component 3110 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device or the memory device of one embodiment of the present invention can be suitably used as space equipment.

The semiconductor device or the memory device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude of 100 km or higher, and outer space described in this specification can include one or more of thermosphere, mesosphere, and stratosphere.

FIG. 57D illustrates an artificial satellite 6800 as an example of space equipment. The artificial satellite 6800 includes a body 6801, a solar panel 6802, an antenna 6803, a secondary battery 6805, and a control device 6807. In FIG. 57D, a planet 6804 in outer space is illustrated as an example.

Although not illustrated in FIG. 57D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is illuminated with sunlight, electric power required for operation of the artificial satellite 6800 is generated. However, for example, in the situation where the solar panel is not illuminated with sunlight or the situation where the amount of sunlight with which the solar panel is illuminated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Incidentally, a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Moreover, the semiconductor device or the memory device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device or the memory device of one embodiment of the present invention can be suitably used for space equipment such as a spacecraft, a space capsule, or a space probe, for example.

As described above, the OS transistor has advantageous effects over the Si transistor, such as a wide memory bandwidth and high radiation resistance.

### [Data Center]

The semiconductor device or the memory device of one embodiment of the present invention can be suitably used for, for example, a storage system in a data center or the like. Long-term management of data, such as guarantee of data immutability, is required for the data center. The long-term management of data needs setting a storage and a server for storing a huge amount of data, stable power supply for retaining data, cooling equipment for retaining data, an increase in building size, and the like.

With use of the semiconductor device or the memory device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device or the memory device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device or the memory device of one embodiment of the present invention can achieve a data center that operates stably even in a high temperature environment. Thus, the reliability of the data center can be increased.

FIG. 57E illustrates a storage system that can be used in a data center. A storage system 7010 illustrated in FIG. 57E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected to each other via a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still much longer than the data access speed of a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure where an OS transistor is used as a transistor for storing data in the cache memory to retain a potential based on data, the frequency of refreshing can be decreased, so that power consumption can be reduced. Furthermore, downscaling is possible by stacking memory cell arrays.

### [Electronic Device]

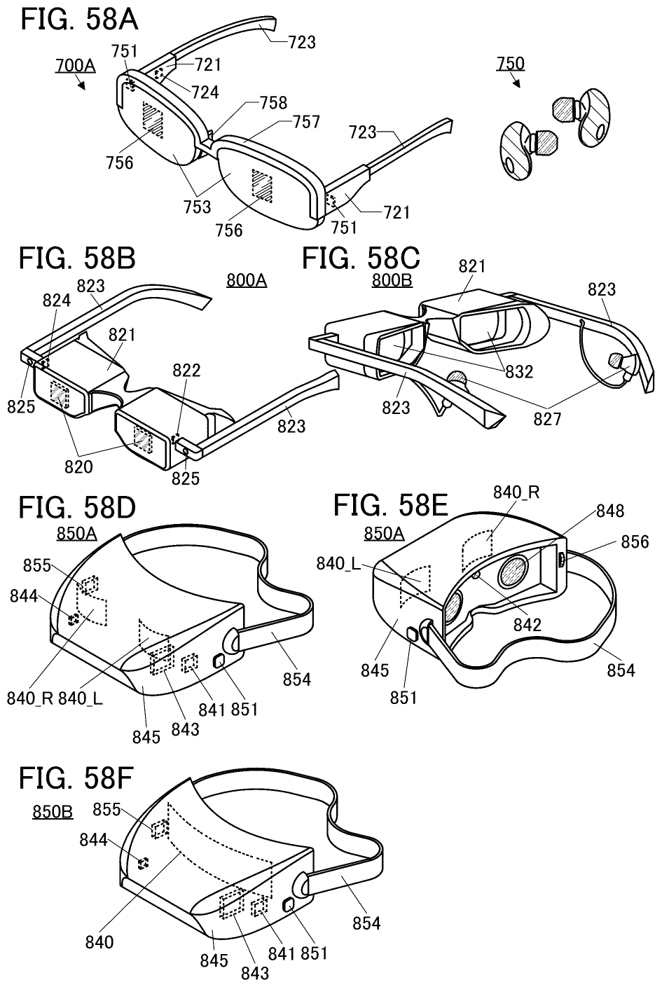

Examples of a wearable device that can be worn on a head are described with reference to FIGS. 58A to 58F. The wearable device has at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 58A includes a pair of display panels 751, a pair of housings 721, a communication portion (not illustrated), a pair of wearing portions 723, a control portion 724, an image capturing portion (not illustrated), a pair of optical members 753, a frame 757, and a pair of nose pads 758.

The semiconductor device or the memory device of one embodiment of the present invention can be used for the control portion 724. Thus, power consumption of the electronic device can be reduced.

The electronic device 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A is an electronic device capable of AR display.

In the electronic device 700A, a camera capable of capturing images of the front side may be provided as the image capturing portion. Furthermore, when the electronic device 700A is provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A is provided with a battery so that charging can be performed wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

An electronic device 800A illustrated in FIG. 58B and an electronic device 800B illustrated in FIG. 58C each include a pair of display portions 820, a housing 821, a communication portion 822, a pair of wearing portions 823, a control portion 824, a pair of image capturing portions 825, and a pair of lenses 832.

The semiconductor device or the memory device of one embodiment of the present invention can be used for the control portion 824. Thus, power consumption of the electronic device can be reduced.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user wearing the electronic device 800A or the electronic device 800B can see images displayed on the display portions 820 through the lenses 832.

The electronic devices 800A and 800B preferably include a mechanism for adjusting horizontally the positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 58B and the like illustrate an example where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

An example where the image capturing portions 825 are provided is shown here, but the image capturing portions 825 may be omitted when a range sensor (hereinafter also referred to as a sensing portion) capable of measuring a distance between the user and an object is provided. In other words, the image capturing portion 825 is one mode of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging the battery provided in the electronic device, or the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 58A has a function of transmitting information to the earphones 750 with the wireless communication function.

The electronic device may include an earphone portion. The electronic device 800B in FIG. 58C includes earphone portions 827. For example, the earphone portion 827 can be connected to the control portion 824 by wire. Part of a wiring that connects the earphone portion 827 and the control portion 824 may be positioned inside the housing 821 or the wearing portion 823. Additionally, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 58D and 58E are perspective views of a goggles-type electronic device 850A for VR. FIGS. 58D and 58E illustrate an example where a housing 845 includes a pair of curved display devices 840 (a display device 840_R and a display device 840_L). The electronic device 850A includes a motion detection portion 841, an eye-gaze detection portion 842, an arithmetic portion 843, a communication portion 844, lenses 848, an operation button 851, a wearing tool 854, a sensor 855, a dial 856, and the like.

When the two display devices 840 are provided, the user's eyes can see the respective display devices. This allows a high-resolution image to be displayed even when three-dimensional display using parallax or the like is performed. In addition, the display device 840 is curved around an arc with an approximate center at the user's eye. This keeps a certain distance between the user's eye and the display surface of the display device 840, enabling the user to see a more natural image. Even when having what is called viewing angle dependence where the luminance or chromaticity of light changes depending on a viewing angle, the display device 840 can have a structure where the user's eye is positioned in the normal direction of the display surface of the display device 840; accordingly, the influence of the viewing angle dependence particularly in the horizontal direction can be practically ignored, enabling display of a more realistic video.

As illustrated in FIG. 58E, the lenses 848 are positioned between the display devices 840 and the user's eyes. FIG. 58E illustrates an example where the dial 856 for changing the positions of the lenses for visibility adjustment is provided. In addition, in the case where the electronic device 850A has an autofocus function, the dial 856 for visibility adjustment is not necessarily provided.

FIG. 58F illustrates a goggles-type electronic device 850B including one display device 840. Such a structure can reduce the number of components.

The display device 840 can display an image for the right eye and an image for the left eye side by side on a right region and a left region, respectively. Thus, a three-dimensional image using binocular parallax can be displayed. Note that the display device 840 may display two different images side by side using parallax, or may display two same images side by side without using parallax.

One image which can be seen with both eyes may be displayed on the entire display device 840. Thus, a panorama image can be displayed from end to end of the field of view, which can provide a higher sense of reality.

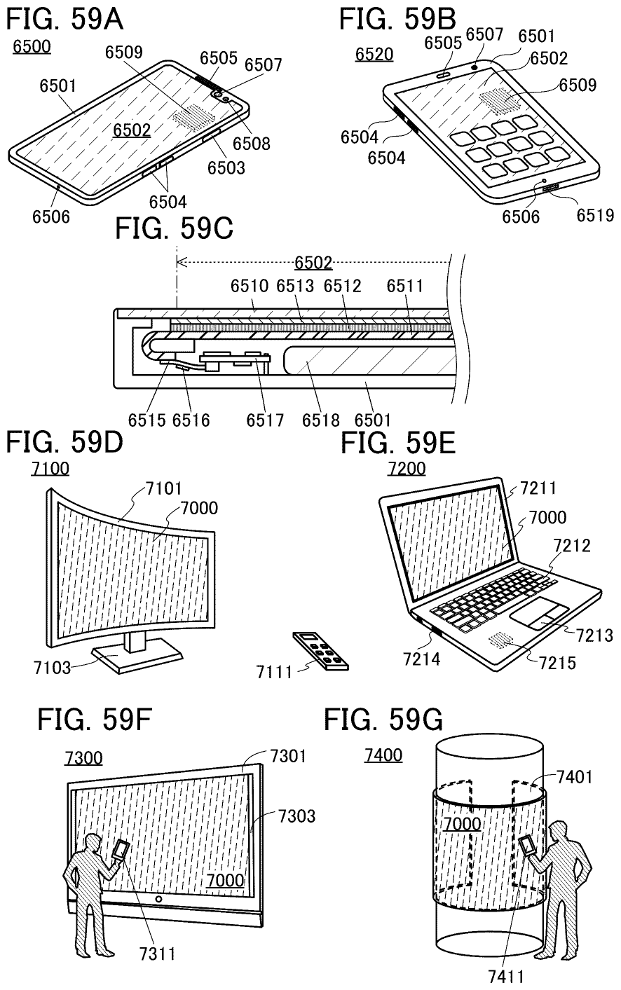

An electronic device 6500 illustrated in FIG. 59A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 illustrated in FIG. 59B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. Note that the control device 6509 includes, for example, one or more selected from a CPU, a GPU, and a memory device. The semiconductor device or the memory device of one embodiment of the present invention can be used for the control device 6509.

FIG. 59C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

FIG. 59D illustrates an example of a television device. In a television device 7100, a display portion 7000 is incorporated in a housing 7101. Here, the housing 7101 is supported by a stand 7103.

Operation of the television device 7100 illustrated in FIG. 59D can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 59E illustrates an example of a laptop personal computer. The laptop personal computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device or the memory device of one embodiment of the present invention can be used for the control device 7215.

FIGS. 59F and 59G illustrate examples of digital signage.

Digital signage 7300 illustrated in FIG. 59F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 59G is digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 59F and 59G, it is preferable that the digital signage 7300 or the digital signage 7400 can work with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device or the memory device of one embodiment of the present invention can be used around a driver's seat in a car, which is a vehicle.

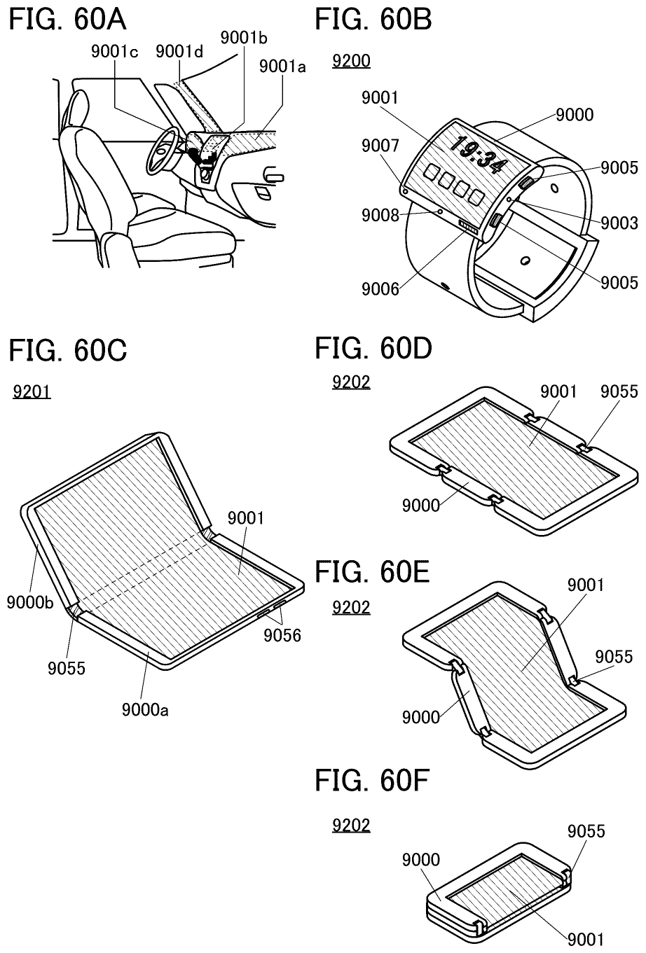

FIG. 60A illustrates the vicinity of a windshield inside a car. FIG. 60A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panel, their layout, and the like can be changed as appropriate to suit the user's preferences, resulting in more sophisticated design. The display panels 9001a to 9001c can also be used as lighting devices.

The display panel 9001d can complement a view hindered by the pillar (blind areas) by displaying an image taken by an imaging unit provided for the car body. That is, displaying an image taken by the imaging unit provided on the exterior of the car leads to elimination of blind areas and enhancement of safety. Moreover, showing an image to complement an area that a driver cannot see makes it possible for the driver to confirm safety more easily and comfortably. The display panel 9001d can also be used as a lighting device.

FIG. 60B is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 60B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

FIG. 60C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housing 9000a and the housing 9000b) joined together with the hinge 9055.

FIGS. 60D to 60F are perspective views illustrating a foldable portable information terminal 9202. FIG. 60D is a perspective view of an opened state of the portable information terminal 9202, FIG. 60F is a perspective view of a folded state thereof, and FIG. 60E is a perspective view of a state in the middle of change from one of FIG. 60D and FIG. 60F to the other. In this manner, the portable information terminal 9202 can be folded in three.

The display portion 9001 of the portable information terminal 9202 is supported by three housings 9000 joined together with the hinges 9055.

The portable information terminals 9201 and 9202 are highly portable when folded. When the portable information terminals 9201 and 9202 are opened, a seamless large display region is highly browsable.

The use of the semiconductor device or the memory device of one embodiment of the present invention for one or more selected from an electronic component, a large computer, space equipment, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device or the memory device of one embodiment of the present invention. Furthermore, the semiconductor device or the memory device of one embodiment of the present invention has low power consumption and thus is effective as a global warming countermeasure.

This embodiment can be combined with any of the other embodiments as appropriate. In this specification, in the case where a plurality of structure examples are shown in one embodiment, the structure examples can be combined as appropriate.

This application is based on Japanese Patent Application Serial No. 2024-029904 filed with Japan Patent Office on Feb. 29, 2024, the entire contents of which are hereby incorporated by reference.

What is claimed is:

1. A semiconductor device comprising:
a capacitor;
a transistor;
a first insulating layer; and
a second insulating layer,
wherein the capacitor comprises a first electrode having a pillar shape, a dielectric covering a side surface and a top surface of the first electrode, and a second electrode being over the dielectric and covering the side surface and the top surface of the first electrode,
wherein the first insulating layer is positioned over the second electrode,
wherein the second insulating layer is positioned over the first insulating layer,
wherein the second insulating layer comprises an opening portion,
wherein the transistor comprises an oxide semiconductor layer,
wherein the oxide semiconductor layer comprises a region along a sidewall of the opening portion,
wherein part of an end portion of the oxide semiconductor layer is positioned in the opening portion,
wherein the oxide semiconductor layer comprises a region overlapping with the second electrode, and
wherein one of a source electrode and a drain electrode of the transistor is electrically connected to the second electrode.

2. The semiconductor device according to claim 1,
wherein the second insulating layer is positioned over the one of the source electrode and the drain electrode of the transistor,
wherein the other of the source electrode and the drain electrode of the transistor is positioned over the second insulating layer, and
wherein the oxide semiconductor layer comprises a region in contact with a top surface of the one of the source electrode and the drain electrode of the transistor and a region in contact with a top surface of the other of the source electrode and the drain electrode of the transistor.

3. A semiconductor device comprising:
a first capacitor;
a second capacitor;
a first transistor;
a second transistor;
a first insulating layer; and
a second insulating layer,
wherein the first capacitor comprises a first electrode having a pillar shape, a first dielectric covering a side surface and a top surface of the first electrode, and a second electrode being over the first dielectric and covering the side surface and the top surface of the first electrode,
wherein the second capacitor comprises a third electrode having a pillar shape, a second dielectric covering a side surface and a top surface of the third electrode, and a fourth electrode being over the second dielectric and covering the side surface and the top surface of the third electrode,
wherein the first insulating layer is positioned over the second electrode and the fourth electrode,
wherein the second insulating layer is positioned over the first insulating layer,
wherein the second insulating layer comprises a first opening portion at least partly overlapping with a region positioned between the first capacitor and the second capacitor,
wherein the first transistor comprises a first oxide semiconductor layer,
wherein the second transistor comprises a second oxide semiconductor layer,
wherein each of the first oxide semiconductor layer and the second oxide semiconductor layer comprises a region along a sidewall of the first opening portion,
wherein one of a source electrode and a drain electrode of the first transistor is electrically connected to the second electrode, and
wherein one of a source electrode and a drain electrode of the second transistor is electrically connected to the fourth electrode.

4. The semiconductor device according to claim 3, further comprising a third insulating layer,
wherein the first dielectric and the second dielectric are positioned over the third insulating layer,
wherein the third insulating layer comprises a second opening portion, and
wherein the first electrode comprises a region in contact with a side surface of the third insulating layer in the second opening portion and a region in contact with the first dielectric.

5. The semiconductor device according to claim 3,
wherein a height from a bottom surface of the second electrode to the top surface of the first electrode is greater than or equal to a width of the first electrode.

6. The semiconductor device according to claim 3, further comprising a conductive layer,
wherein the first insulating layer comprises a third opening portion reaching the second electrode,
wherein the conductive layer is positioned in the third opening portion, and
wherein the one of the source electrode and the drain electrode of the first transistor comprises a region in contact with a top surface of the conductive layer.

7. The semiconductor device according to claim 6,
wherein the second insulating layer is positioned over the one of the source electrode and the drain electrode of the first transistor and the one of the source electrode and the drain electrode of the second transistor, and
wherein the other of the source electrode and the drain electrode of the first transistor and the other of the source electrode and the drain electrode of the second transistor are positioned over the second insulating layer.

8. A semiconductor device comprising:
a first capacitor;
a second capacitor;
a first transistor;
a second transistor;
a first insulating layer;
a second insulating layer; and
a third insulating layer,
wherein the first capacitor comprises a first conductive layer, a second conductive layer, and a fourth insulating layer,
wherein the second capacitor comprises a third conductive layer, a fourth conductive layer, and a fifth insulating layer,
wherein the first transistor comprises a first oxide semiconductor layer, a fifth conductive layer, a sixth conductive layer, a seventh conductive layer, and a sixth insulating layer,
wherein the second transistor comprises a second oxide semiconductor layer, the sixth conductive layer, an eighth conductive layer, a ninth conductive layer, and the sixth insulating layer,
wherein each of the first conductive layer and the third conductive layer has a pillar shape,
wherein the fourth insulating layer covers a side surface and a top surface of the first conductive layer,
wherein the fifth insulating layer covers a side surface and a top surface of the third conductive layer,
wherein the second conductive layer is positioned over the fourth insulating layer and covers the side surface and the top surface of the first conductive layer,
wherein the fourth conductive layer is positioned over the fifth insulating layer and covers the side surface and the top surface of the third conductive layer,
wherein the first insulating layer is positioned over the second conductive layer and the fourth conductive layer,
wherein the fifth conductive layer and the eighth conductive layer are positioned over the first insulating layer,
wherein the fifth conductive layer is electrically connected to the second conductive layer,
wherein the eighth conductive layer is electrically connected to the fourth conductive layer,
wherein the second insulating layer is positioned over the fifth conductive layer and the eighth conductive layer,
wherein the sixth conductive layer is positioned over the second insulating layer,
wherein the third insulating layer is positioned over the sixth conductive layer and the second insulating layer,
wherein the seventh conductive layer and the ninth conductive layer are positioned over the third insulating layer,
wherein the third insulating layer, the sixth conductive layer, and the second insulating layer comprise a first opening portion,
wherein the first opening portion comprises a portion overlapping with the fifth conductive layer, a portion overlapping with the eighth conductive layer, and a portion overlapping with the first insulating layer and positioned between the fifth conductive layer and the eighth conductive layer,
wherein the sixth insulating layer covers a sidewall of the first opening portion,
wherein the first oxide semiconductor layer comprises a region facing the sixth conductive layer with the sixth insulating layer therebetween in the first opening portion and a region in contact with the fifth conductive layer in the first opening portion, and a region in contact with the seventh conductive layer outside the first opening portion, and
wherein the second oxide semiconductor layer comprises a region facing the sixth conductive layer with the sixth insulating layer therebetween in the first opening portion, a region in contact with the eighth conductive layer in the first opening portion, and a region in contact with the ninth conductive layer outside the first opening portion.

9. The semiconductor device according to claim 8, further comprising a seventh insulating layer,
wherein the fourth insulating layer and the fifth insulating layer are positioned over the seventh insulating layer,
wherein the seventh insulating layer comprises a second opening portion, and
wherein the first conductive layer comprises a region in contact with a side surface of the seventh insulating layer in the second opening portion and a region in contact with the fourth insulating layer.

10. The semiconductor device according to claim 8,
wherein a height from a bottom surface of the second conductive layer to the top surface of the first conductive layer is greater than or equal to a width of the first conductive layer.

11. The semiconductor device according to claim 8, further comprising a tenth conductive layer,
wherein the first insulating layer comprises a third opening portion reaching the second conductive layer,
wherein the tenth conductive layer is positioned in the third opening portion, and
wherein the fifth conductive layer comprises a region in contact with a top surface of the tenth conductive layer.

12. The semiconductor device according to claim 8,
wherein the sixth insulating layer in the first opening portion has an annular shape in a plan view, and
wherein each of the first oxide semiconductor layer and the second oxide semiconductor layer in the first opening portion has an arc shape in a plan view.

13. The semiconductor device according to claim 8,
wherein the fifth conductive layer comprises a depressed portion at a position overlapping with the first opening portion,
wherein the sixth insulating layer is in contact with a sidewall of the depressed portion, and
wherein the first oxide semiconductor layer is in contact with at least part of a bottom portion of the depressed portion.

14. The semiconductor device according to claim 13,
wherein the fifth conductive layer comprises a first layer and a second layer over the first layer, and
wherein the second layer comprises the depressed portion.

15. The semiconductor device according to claim 8,
wherein the sixth insulating layer is in contact with part of a side surface on the first opening portion side of the seventh conductive layer, and
wherein the first oxide semiconductor layer is in contact with another part of the side surface on the first opening portion side of the seventh conductive layer.

16. The semiconductor device according to claim 15,
wherein the sixth insulating layer is in contact with part of a side surface on the first opening portion side of the fifth conductive layer, and
wherein the first oxide semiconductor layer is in contact with another part of the side surface on the first opening portion side of the fifth conductive layer.

17. The semiconductor device according to claim 8,
wherein an end portion of the first oxide semiconductor layer outside the first opening portion is closer to the first opening portion than an end portion of the seventh conductive layer on an opposite side to the first opening portion is in a plan view.

18. The semiconductor device according to claim 8, further comprising an eighth insulating layer and an eleventh conductive layer,
wherein the eighth insulating layer is positioned over the first oxide semiconductor layer and the second oxide semiconductor layer, and
wherein the eleventh conductive layer comprises, in the first opening portion, a region facing the sixth conductive layer with the eighth insulating layer, the first oxide semiconductor layer, and the sixth insulating layer therebetween and a region facing the sixth conductive layer with the eighth insulating layer, the second oxide semiconductor layer, and the sixth insulating layer therebetween.

19. The semiconductor device according to claim 18,
wherein a height of a bottom surface of a portion that is of the eleventh conductive layer and positioned between the fifth conductive layer and the eighth conductive layer is lower than a height of a top surface of a portion that is of the fifth conductive layer and does not overlap with the first opening portion.

20. The semiconductor device according to claim 18, further comprising a ninth insulating layer and a twelfth conductive layer,
wherein the ninth insulating layer is positioned over the eighth insulating layer and comprises a fifth opening portion at a position overlapping with the first opening portion, and
wherein the twelfth conductive layer is positioned over the ninth insulating layer and comprises a region in contact with the eleventh conductive layer.
